(19) United States
(12) Patent Application Publication
(10) Pub. No.: US 2015/0287953 A1
(43) Pub. Date: Oct. 8, 2015

(54) TRANSPARENT ELECTRODE, ELECTRONIC DEVICE, AND ORGANIC ELECTROLUMINESCENT ELEMENT

(71) Applicant: KONICA MINOLTA, INC., Tokyo (JP)

(72) Inventors: Hidekane Ozeki, Hachioji-shi (JP); Takayuki Iijima, Hino-shi (JP); Kazuhiro Yoshida, Tachikawa-shi (JP); Takeshi Hakii, Sagamihara-shi (JP)

(21) Appl. No.: 14/436,260

(22) PCT Filed: Oct. 21, 2013
(86) PCT No.: PCT/JP2013/078427

§ 371 Date: Apr. 16, 2015

(30) Foreign Application Priority Data
Oct. 23, 2012 (JP) 2012-233664

(51) Int. Cl. H01L 51/52

(52) U.S. Cl. CPC H01L 51/5215; H01L 51/005

(57) ABSTRACT

A transparent electrode includes a conductive layer and an intermediate layer disposed adjacent to the conductive layer. The transparent electrode has a light transmittance of 50% or more at a wavelength of 550 nm and a sheet resistance of 20Ω/□ or less. The intermediate layer contains an organic compound containing a sulfur atom having an unshared electron pair. The conductive layer is composed of silver as a main component.

### TECHNICAL FIELD

The present invention relates to a transparent electrode, an electronic device and an organic electroluminescent element, particularly a transparent electrode having high optical transparency, low sheet resistance and small sheet resistance variation in high temperature storage, and an electronic device and an organic electroluminescent element each provided with the transparent electrode and having excellent optical transparency, low driving voltage and small voltage variation under constant current.

### BACKGROUND ART

An organic electroluminescent element (also called an “organic EL element” or an “organic-field light-emitting element”), which utilizes electroluminescence (hereinafter abbreviated to “EL”) of an organic material, is a thin-film type completely-solid state element capable of light emission at a low voltage of about several volts to several ten volts and having many excellent characteristics; for example, high luminescence, high efficiency of light emission, thin and light, and therefore recently has attracted attention as a surface emitting body for backlights of various displays, display boards such as signboards and emergency lights, and light sources of lights.

The organic EL element is configured in such a way that a luminescent layer composed of an organic material is interposed between two electrodes, and emission light generated in the luminescent layer passes through the electrode(s) and is extracted to the outside. For that, at least one of the two electrodes is configured as a transparent electrode.

For the transparent electrode, oxide semiconductor materials, such as indium tin oxide (SnO₂—In₂O₃ or ITO), are used in general, but a material composed of ITO and silver stacked to reduce resistance has been investigated. (Refer to, for example, Patent Documents 1 and 2.) However, because ITO uses a rare metal, indium, material costs are high, and also annealing at about 300° C. is needed after its deposition in order to reduce resistance.

Then, there have been proposed: an art to make a thin film with an alloy of silver, which has high electrical conductivity, and Mg to achieve both transmittance and conductivity; and an art to make a thin film with a material such as Zn or Sn, which is available at low costs, as a starting material. (Refer to, for example, Patent Documents 3 and 4.)

However, the art to make a thin film with an alloy of silver and Mg has problems, for example, that resistance of the obtained thin film is about 100Ω/□, which is insufficient, and that deterioration over time is significant because Mg is easily oxidized. Further, the art to make a thin film with Zn or Sn as a starting material has problems, for example, that a sufficient resistance cannot be obtained, that a ZnO thin film containing Zn reacts with water, whereby its properties easily change, and that an SnO₂ thin film containing Sn is difficult to process by etching.

Further, there has been reported a transparent organic light-emitting diode (OLED) in which silver is deposited to be 15 nm thick as a cathode. (Refer to, for example, Patent Document 5.)

However, in the case of Patent Document 5, because the deposited layer of silver is thick, optical transparency (degree of transparency) is bad. However, when the deposited layer of silver, which easily causes migration, is made to be thinner, the sheet resistance is high and the sheet resistance variation in high temperature storage is large, so that electrode characteristics cannot be maintained. Consequently, an OLED using such an electrode has problems that driving voltage is high and voltage variation under constant current is large.

### RELATED ART DOCUMENTS

### Patent Documents

Patent Document 1: Japanese Patent Application Publication No. 2002-15623

Patent Document 2: Japanese Patent Application Publication No. 2006-164961

Patent Document 3: Japanese Patent Application Publication No. 2006-344497

Patent Document 4: Japanese Patent Application Publication No. 2007-031786

Patent Document 5: U.S. Patent Application Publication No. 2011/0260148

### SUMMARY OF THE INVENTION

### Problems to be Solved by the Invention

The present invention has been conceived in view of the above problems, and its solution is to provide: a transparent electrode having high optical transparency, low sheet resistance and small sheet resistance variation in high temperature storage; and an electronic device and an organic electroluminescent element each provided with the transparent electrode and having excellent optical transparency, low driving voltage and small voltage variation under constant current.

### Means for Solving the Problems

During the investigation of the causes and the like of the above problems to solve the problems, the present inventors have found out that the transparent electrode having excellent optical transparency, low sheet resistance and small sheet resistance variation in high temperature storage can be realized by a transparent electrode including: a conductive layer; and an intermediate layer disposed adjacent to the conductive layer, wherein the transparent electrode has a light transmittance of 50% or more at a wavelength of 550 nm and a sheet resistance of 20Ω/□ or less, the intermediate layer contains an organic compound containing a sulfur atom having an unshared electron pair, and the conductive layer is composed of silver as a main component. Thus, the present inventors have reached the present invention.

That is, the above problems left to the present invention are solved by the following means.

1. A transparent electrode including: a conductive layer; and an intermediate layer disposed adjacent to the conductive layer, wherein the transparent electrode has a light transmittance of 50% or more at a wavelength of 550 nm and a sheet resistance of 20Ω/□ or less, the intermediate layer contains an organic compound containing a sulfur atom having an unshared electron pair, and the conductive layer is composed of silver as a main component.

2. The transparent electrode according to the item 1, wherein the organic compound is represented by the following general formula (1) having a divalent sulfur atom:

[Chem. 1]

R₁—S—R₂ General Formula (1)

wherein R₁ and R₂ each represent a substituent.

3. The transparent electrode according to the item 1, wherein the organic compound is represented by the following general formula (2):

[Chem. 2]

R₃—S—S—R₄ General Formula (2)

wherein R₃ and R₄ each represent a substituent.

4. The transparent electrode according to the item 1, wherein the organic compound is represented by the following general formula (3):

[Chem. 3]

R₅—S—H General Formula (3)

wherein R₅ represents a substituent, and the general formula (3) includes a structure ionized by separation of the hydrogen.

5. The transparent electrode according to the item 1, wherein the organic compound is represented by the following general formula (4):

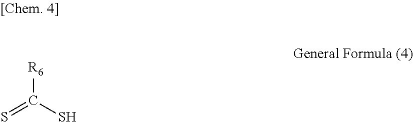

wherein R₆ represents a substituent.

6. The transparent electrode according to any one of the items 1 to 5 further including a second intermediate layer on the conductive layer, wherein the conductive layer is interposed between the two intermediate layers.

7. An electronic device including the transparent electrode according to any one of the items 1 to 6.

8. An organic electroluminescent element including the transparent electrode according to any one of the items 1 to 6.

### Advantageous Effects of the Invention

With the above means of the present invention, there can be provided: a transparent electrode having high optical transparency, low sheet resistance and small sheet resistance variation in high temperature storage; and an electronic device and an organic electroluminescent element each provided with the transparent electrode and having excellent optical transparency, low driving voltage and small voltage variation under constant current.

Although appearance mechanism of the effects of the present invention and action mechanism thereof are not clear yet, they are conjectured as follows.

The transparent electrode of the present invention has the conductive layer which contains silver as a main component on the upper side of the intermediate layer, and the intermediate layer contains the “organic compound containing a sulfur atom(s) having an unshared electron pair”, which is a compound having an atom(s) having affinity for a silver atom(s).

With this structure, when the conductive layer is formed on the intermediate layer, the silver atom(s) constituting the conductive layer and the “organic compound containing a sulfur atom(s) having an unshared electron pair” contained in the intermediate layer react with each other, and diffusion distance of the silver atom(s) on the surface of the intermediate layer decreases, whereby silver cohesion at a specific point is kept from occurring.

That is, the silver atoms are deposited by film growth in the single-layer growth mode (Frank-van der Merwe (FW) mode), in which the silver atoms first form a two-dimensional nucleus on the surface of the intermediate layer which contains the “organic compound containing a sulfur atom(s)”, the sulfur atoms having affinity for the silver atoms, and then form a two-dimensional single crystal layer having the formed nucleus as its center.

In general, silver atoms tend to be deposited in the shape of an island(s) by film growth in the island growth mode (Volumer-Weber (VW) mode), in which the silver atoms having adhered to the surface of an intermediate layer bind to each other while diffusing on the surface to forma three-dimensional nucleus (nuclei) and grow in the shape of a three-dimensional island(s). In the present invention, however, it is conjectured that the “organic compound containing a sulfur atom(s) having an unshared electron pair” contained in the intermediate layer prevents the island growth but promotes the single-layer growth.

Consequently, although being thin, the conductive layer which is uniform in thickness is obtained. As a result of that, the transparent electrode can be made as the one which has low sheet resistance and small sheet resistance variation in high temperature storage while keeping light transmittance as a thinner layer.

### BRIEF DESCRIPTION OF THE DRAWINGS

FIG. 1 is a schematic cross sectional view showing an example of the structure of a transparent electrode of the present invention.

FIG. 2 is a schematic cross sectional view showing an example of the structure of the transparent electrode of the present invention.

FIG. 3 is a schematic cross sectional view showing a first embodiment of an organic EL element to which the transparent electrode of the present invention is applied.

FIG. 4 is a schematic cross sectional view showing a second embodiment of an organic EL element to which the transparent electrode of the present invention is applied.

FIG. 5 is a schematic cross sectional view showing a third embodiment of an organic EL element to which the transparent electrode of the present invention is applied.

FIG. 6 is a schematic cross sectional view showing an example of an illumination device having a luminescent face which is enlarged by using organic EL elements provided with the transparent electrodes of the present invention.

FIG. 7 is a schematic cross sectional view to explain the structure of an organic EL element produced in Examples.

### EMBODIMENTS FOR CARRYING OUT THE INVENTION

A transparent electrode of the present invention is a transparent electrode including: a conductive layer; and an intermediate layer disposed adjacent to the conductive layer, wherein the transparent electrode has a light transmittance of 50% or more at a wavelength of 550 nm and a sheet resistance of 20Ω/□ or less, the intermediate layer contains an organic compound containing a sulfur atom having an unshared electron pair, and the conductive layer is composed of silver as a main component. This feature is a technical feature common to claims 1 to 9 of the present invention.

As an embodiment of the present invention, it is preferable that the organic compound be represented by the above General Formula (1) having a divalent sulfur atom in view of the effects aimed by the present invention, namely, high optical transparency, low sheet resistance and small sheet resistance variation in high temperature storage, to be demonstrated.

Further, it is preferable that the organic compound be represented by the above General Formula (2) in view of high optical transparency, low sheet resistance and small sheet resistance variation in high temperature storage.

Further, it is preferable that the organic compound be represented by the above General Formula (3) in view of high optical transparency, low sheet resistance and small sheet resistance variation in high temperature storage.

Further, it is preferable that the organic compound be represented by the above General Formula (4) in view of high optical transparency, low sheet resistance and small sheet resistance variation in high temperature storage.

Further, it is preferable that a second intermediate layer be on the conductive layer, and the conductive layer be interposed between the two intermediate layers in view of high optical transparency, low sheet resistance and small sheet resistance variation in high temperature storage.

An electronic device of the present invention is provided with the transparent electrode. Consequently, there can be made an electronic device having excellent optical transparency, low driving voltage and small voltage variation under constant current.

An organic electroluminescent element of the present invention is provided with the transparent electrode. Consequently, there can be made an organic electroluminescent element having excellent optical transparency, low driving voltage and small voltage variation under constant current.

Hereinafter, the present invention, its components, and forms/modes for carrying out the present invention are detailed. Note that, in this application, “-(to)” between values is used to mean that the values before and after the sign are inclusive as the lower limit and the upper limit.

<<1. Transparent Electrode>>

FIG. 1 is a schematic cross sectional view showing an example of the structure of a transparent electrode of an embodiment.

As shown in FIG. 1, a transparent electrode 1 has a two-layer structure of an intermediate layer 1a and a conductive layer 1b formed on the upper side of the intermediate layer 1a. For example, on the upper side of a base 11, the intermediate layer 1a and the conductive layer 1b are disposed in the order named. The intermediate layer 1a is a layer containing an organic compound containing a sulfur atom(s) having an unshared electron pair, and the conductive layer 1b is a layer containing silver as a main component.

The “transparent” of the transparent electrode 1 of the present invention means that the light transmittance at a wavelength of 550 nm is 50% or more. Further, the transparent electrode 1 of the present invention has a sheet resistance of 20Ω/□ or less. The sheet resistance is a value determined with a resistivity meter (MCP-T610 manufactured by Mitsubishi Chemical Corporation) by the 4-terminal method, 4-pin probe method and constant-current method.

Further, in this application, the “main component” of the conductive layer means a component having the highest component percentage among the components constituting the conductive layer. The conductive layer of the present invention has silver as a main component, and its component percentage is preferably 60 mass % or more, far preferably 80 mass % or more, still far preferably 90 mass % or more and particularly preferably 98 mass % or more.

Next, the structures of the base 11 on which the transparent electrode 1 having this multilayer structure is disposed, and the intermediate layer 1a and the conductive layer 1b, which constitute the transparent electrode 1, are detailed in the order named.

[Base 11]

The base 11 on which the transparent electrode 1 of the present invention is formed is, for example, glass or plastic, but not limited thereto. The base 11 may be transparent or nontransparent. In the case where the transparent electrode 1 of the present invention is used for an electronic device which extracts light from the base 11 side, it is preferable that the base 11 be transparent. Examples of the transparent base 11 used by preference include glass, quartz and a transparent resin film.

Examples of the glass include silica glass, soda-lime silica glass, lead glass, borosilicate glass and alkali-free glass. On the surface of any of these glass materials, as needed, a physical treatment such as polishing may be carried out, or a coating composed of an inorganic matter or an organic matter or a hybrid coating composed of these may be formed, in view of adhesion to the intermediate layer 1a, durability and smoothness.

Examples of the resin film include polyesters, such as polyethylene terephthalate (PET) and polyethylene naphthalate (PEN); polyethylene; polypropylene; cellulose esters and their derivatives, such as cellophane, cellulose diacetate, cellulose triacetate (TAC), cellulose acetate butyrate, cellulose acetate propionate (CAP), cellulose acetate phthalate and cellulose nitrate; polyvinylidene chloride; polyvinyl alcohol; polyethylene vinyl alcohol; syndiotactic polystyrene; polycarbonate; norbornene resin; polymethyl pentene; polyether ketone; polyimide; polyether sulfone (PES); polyphenylene sulfide; polysulfones; polyether imide; polyether ketone imide; polyamide; fluororesin; nylon; polymethyl methacrylate; acrylic; polyarylates; and cycloolefin resins, such as ARTON™ (produced by JSR Corporation) and APEL® (produced by MITSUI CHEMICALS, INC.).

On the surface of the resin film, a coating composed of an inorganic matter or an organic matter or a hybrid coating composed of these may be formed. It is preferable that this coating or hybrid coating be a barrier film (also called a barrier layer or the like) having a water vapor permeability (25±0.5° C. and a relative humidity of 90±2% RH) of 0.01 g/(m²·24 h) or less determined by a method in conformity with JIS-K-7129-1992.

Further, it is preferable that the coating or hybrid coating be a high-barrier film having an oxygen permeability of 1×10⁻³ ml/(m²·24 h·atm) or less determined by a method in conformity with JIS-K-7126-1987 and a water vapor permeability of 1×10⁻⁵ g/(m²·24 h) or less.

As a material which forms the above described barrier film, any material can be used as long as it is impermeable to substances such as moisture and oxygen which cause deterioration of an organic EL element. For example, silicon dioxide, silicon nitride or the like can be used.

In order to reduce fragility of the barrier film, it is far preferable that the barrier film have a multilayer structure of an inorganic layer composed of any of the above and a layer (organic layer) composed of an organic material. Although the stacking order of the inorganic layer and the organic layer is not particularly limited, it is preferable that these layers be alternately stacked multiple times.

A forming method of the barrier film includes but is not particularly limited to: vacuum deposition, sputtering, reactive sputtering, molecular beam epitaxy, cluster ion beam, ion plating, plasma polymerization, atmospheric pressure plasma polymerization, plasma CVD (Chemical Vapor Deposition), laser CVD, thermal CVD and coating. However, atmospheric pressure plasma polymerization described in Japanese Patent Application Publication No. 2004-68143 is particularly preferable.

On the other hand, in the case where the base 11 is nontransparent, a metal substrate or film composed of aluminum, stainless steel or the like, a nontransparent resin substrate, a ceramic substrate, or the like can be used.

<Intermediate Layer 1a>

The intermediate layer 1a is a layer containing an organic compound containing a sulfur atom(s) having an unshared electron pair. In the case where this intermediate layer 1a is formed on the base 11, examples of its forming method include wet processes, such as application, the inkjet method, coating and dipping, and dry processes, such as vapor deposition (resistance heating, the EB (Electron Beam) method, etc.), sputtering and CVD. Among these, vapor deposition is used by preference.

[Organic Compound Contained in Intermediate Layer 1a]

In the transparent electrode 1 of the present invention, the intermediate layer 1a contains an organic compound containing a sulfur atom(s) having an unshared electron pair.

As the organic compound containing a sulfur atom(s), a compound used as a material for an organic electroluminescent element or a photosensitive material for a picture is suitably used.

The organic compound used in the present invention is preferably represented by the following General Formula (1) having a divalent sulfur atom, General Formula (2), General Formula (3) or General Formula (4).

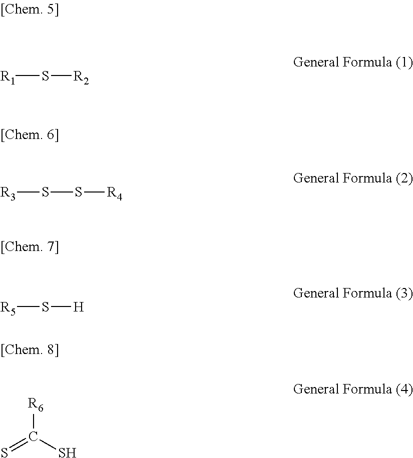

In the above General Formula (1), R₁ and R₂ each represent a substituent.

Examples of the substituent represented by each of R₁ and R₂ include substituted and non-substituted hydrocarbon groups. These hydrocarbon groups each may contain one or more oxygen atoms and/or phosphorous atoms.

Examples of the non-substituted hydrocarbon group include an alkyl group and an aryl group. Examples of the alkyl group include a methyl group, an ethyl group, a propyl group, an i-propyl group, a butyl group, a t-butyl group, a pentyl group, a cyclopentyl group, a hexyl group, a cyclohexyl group, an octyl group, a dodecyl group, a hydroxyethyl group, a methoxyethyl group, a trifluoromethyl group and a benzil group. Examples of the aryl group include a phenyl group and a naphthyl group.

Examples of a group for the substituted hydrocarbon group include a hydroxy group, a halogen compound, a carboxylic acid group, a carboxylate group, a sulfinic acid group, a sulfonic acid group, a sulfate group, a phosphonic acid group, a phosphate group and a cyano group.

Other examples of the substituent include: an alkyl group (a methyl group, an ethyl group, a propyl group, an isopropyl group, a tert-butyl group, a pentyl group, a hexyl group, an octyl group, a dodecyl group, a tridecyl group, a tetradecyl group, a pentadecyl group, etc.); a cycloalkyl group (a cyclopentyl group, a cyclohexyl group, etc.); an alkenyl group (a vinyl group, an allyl group, etc); an alkynyl group (an ethynyl group, a propargyl group, etc.); an aromatic hydrocarbon group (also called an aromatic carbocyclic group, an aryl group or the like; a phenyl group, a p-chlorophenyl group, a mesityl group, a tolyl group, a xylyl group, a naphthyl group, an anthryl group, an azulenyl group, an acenaphthenyl group, a fluorenyl group, a phenanthryl group, an indenyl group, a pyrenyl group, a biphenyryl group, etc.); an aromatic heterocyclic group (a furyl group, a thienyl group, a pyridyl group, a pyridazinyl group, a pyrimidinyl group, a pyrazinyl group, a triazinyl group, an imidazolyl group, a pyrazolyl group, a thiazolyl group, a quinazolinyl group, a carbazolyl group, a carbolinyl group, a diazacarbazolyl group (indicating a group formed in such a way that one of carbon atoms constituting a carboline ring of a carbolinyl group is substituted by a nitrogen atom), a phtharazinyl group, etc.); a heterocyclic group (a pyrrolidyl group, an imidazolidyl group, a morpholyl group, an oxazolidyl group, etc.); an alkoxy group (a methoxy group, an ethoxy group, a propyloxy group, a pentyloxy group, a hexyloxy group, an octyloxy group, a dodecyloxy group, etc.); a cycloalkoxy group (a cyclopentyloxy group, a cyclohexyloxy group, etc.); an aryloxy group (a phenoxy group, a naphthyloxy group, etc.); an alkylthio group (a methylthio group, an ethylthio group, a propylthio group, a pentylthio group, a hexylthio group, an octylthio group, a dodecylthio group, etc.); a cycloalkylthio group (a cyclopentylthio group, a cyclohexylthio group, etc.); an arylthio group (a phenylthio group, a naphthylthio group, etc.); an alkoxycarbonyl group (a methyloxycarbonyl group, an ethyloxycarbonyl group, a butyloxycarbonyl group, an octyloxycarbonyl group, a dodecyloxycarbonyl group, etc.); an aryloxycarbonyl group (a phenyloxycarbonyl group, a naphthyloxycarbonyl group, etc.); a sulfamoyl group (an aminosulfonyl group, a methylaminosulfonyl group, a dimethylaminosulfonyl group, a butylaminosulfonyl group, a hexylaminosulfonyl group, a cyclohexylaminosulfonyl group, an octylaminosulfonyl group, a dodecylaminosulfonyl group, a phenylaminosulfonyl group, a naphthylaminosulfonyl group, a 2-pyridylaminosulfonyl group, etc.); an acyl group (an acetyl group, an ethylcarbonyl group, a propylcarbonyl group, a pentylcarbonyl group, a cyclohexylcarbonyl group, an octylcarbonyl group, a 2-ethylhexylcarbonyl group, a dodecylcarbonyl group, a phenylcarbonyl group, a naphthylcarbonyl group, a pyridylcarbonyl group, etc.); an acyloxy group (an acetyloxy group, an ethylcarbonyloxy group, a butylcarbonyloxy group, an octylcarbonyloxy group, a dodecylcarbonyloxy group, a phenylcarbonyloxy group, etc.); an amido group (a methylcarbonylamino group, an ethylcarbonylamino group, a dimethylcarbonylamino group, a propylcarbonylamino group, a pentylcarbonylamino group, a cyclohexylcarbonylamino group, a 2-ethylhexylcarbonylamino group, an octylcarbonylamino group, a dodecylcarbonylamino group, a phenylcarbonylamino group, a naphthylcarbonylamino group, etc.); a carbamoyl group (an aminocarbonyl group, a methylaminocarbonyl group, a dimethylaminocarbonyl group, a propylaminocarbonyl group, a pentylaminocarbonyl group, a cyclohexylaminocarbonyl group, an octylaminocarbonyl group, a 2-ethylhexylaminocarbonyl group, a dodecylaminocarbonyl group, a phenylaminocarbonyl group, a naphthylaminocarbonyl group, a 2-pyridylaminocarbonyl group, etc.); an ureido group (a methylureido group, an ethylureido group, a pentylureido group, a cyclohexylureido group, an octylureido group, a dodecylureido group, a phenylureido group naphthylureido group, a 2-pyridylaminoureido group, etc.); a sulfinyl group (a methylsulfinyl group, an ethylsulfinyl group, a butylsulfinyl group, a cyclohexylsulfinyl group, a 2-ethylhexylsulfinyl group, a dodecylsulfinyl group, a phenylsulfinyl group, a naphthylsulfinyl group, a 2-pyridylsulfinyl group, etc.); an alkylsulfonyl group (a methylsulfonyl group, an ethylsulfonyl group, a butylsulfonyl group, a cyclohexylsulfonyl group, a 2-ethylhexylsulfonyl group, a dodecylsulfonyl group, etc.); an arylsulfonyl group or a heteroarylsulfonyl group (a phenylsulfonyl group, a naphthylsulfonyl group, a 2-pyridylsulfonyl group, etc.); an amino group (an amino group, an ethylamino group, a dimethylamino group, a butylamino group, a cyclopentylamino group, a 2-ethylhexylamino group, a dodecylamino group, an anilino group, a naphthylamino group, a 2-pyridylamino group, a piperidyl group (also called a piperidinyl group), a 2,2,6,6-tetramethylpiperidinyl group, etc.); a halogen atom (a fluorine atom, a chlorine atom, a bromine atom, etc.); a fluorohydrocarbon group (a fluoromethyl group, a trifluoromethyl group, a pentafluoroethyl group, a pentafluorophenyl group, etc.); a cyano group; a nitro group; a hydroxy group; a mercapto group; a silyl group (a trimethylsilyl group, a triisopropylsilyl group, a triphenylsilyl group, a phenyldiethylsilyl group, etc.); a phosphate group (a dihexylphosphoryl group, etc.); a phosphite group (a diphenylphosphinyl group, etc.); and a phosphono group.

In the above General Formula (2), R₃ and R₄ each represent a substituent.

Examples of the substituent represented by each of R₃ and R₄ are the same as those of the substituent represented by R₁.

In the above General Formula (3), R₅ represents a substituent.

Examples of the substituent represented by R₅ are the same as those of the substituent represented by R₁.

In the above General Formula (4), R₆ represents a substituent.

Examples of the substituent represented by R₆ are the same as those of the substituent represented by R₁.

<Specific Examples of Organic Compound Usable in Intermediate Layer 1a>

Specific examples of the organic compound containing a sulfur atom(s) having an unshared electron pair containable in the intermediate layer 1a of the present invention are shown below, but the organic compound is not limited thereto.

The specific examples of the organic compound containing a sulfur atom(s) having an unshared electron pair include the following compounds S-1 to S-10.

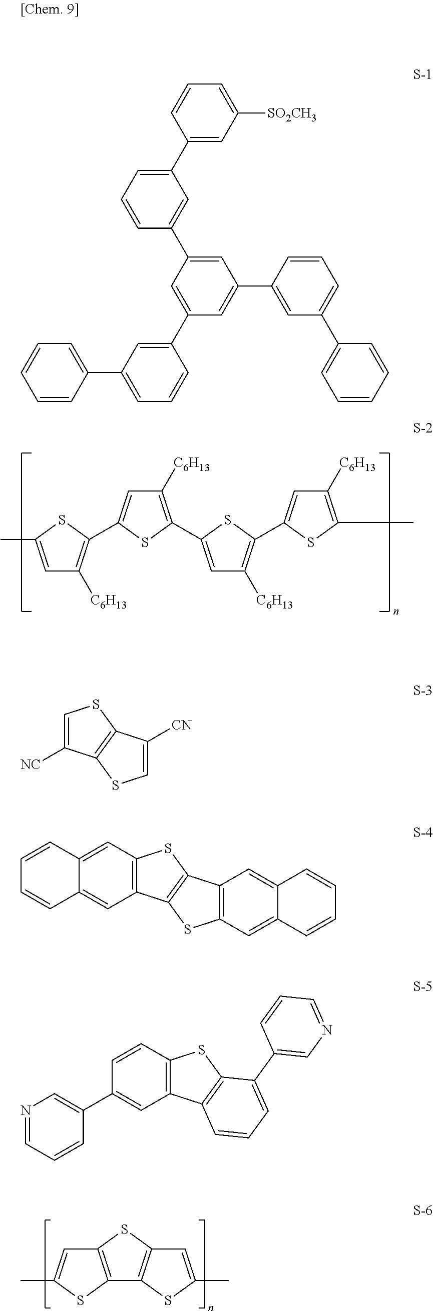

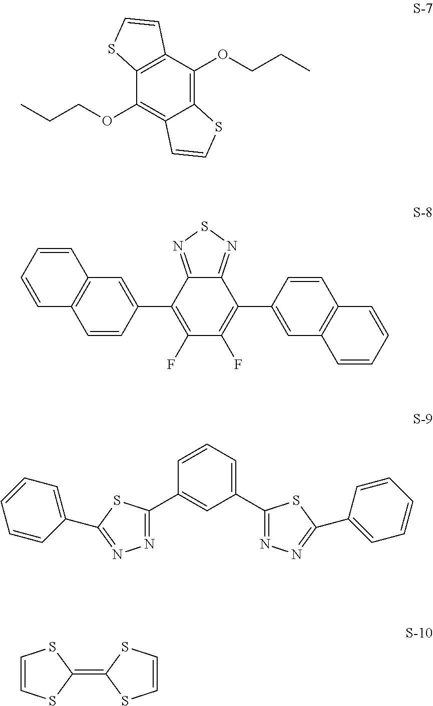 [SMILES: CCCOc1c2ccsc2c(OCCC)c2ccsc12 ; Fc1c(F)c(-c2ccc3ccccc3c2)c2nsnc2c1-c1ccc2ccccc2c1 ; c1ccc(-c2nnc(-c3cccc(-c4nnc(-c5ccccc5)s4)c3)s2)cc1 ; C1=CSC(=C2SC=CS2)S1]

In particular, the specific examples of the compound represented by General Formula (1) having a divalent sulfur atom include the following compounds.

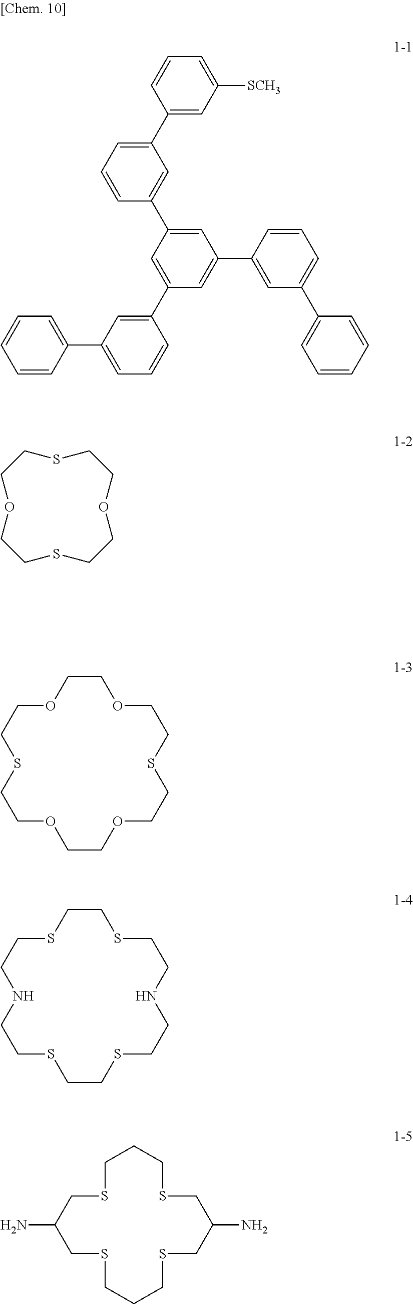

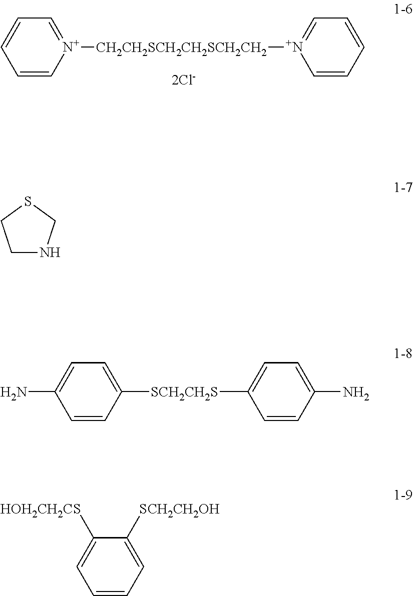

Further, the specific examples of the compound represented by General Formula (2) include the following compounds.

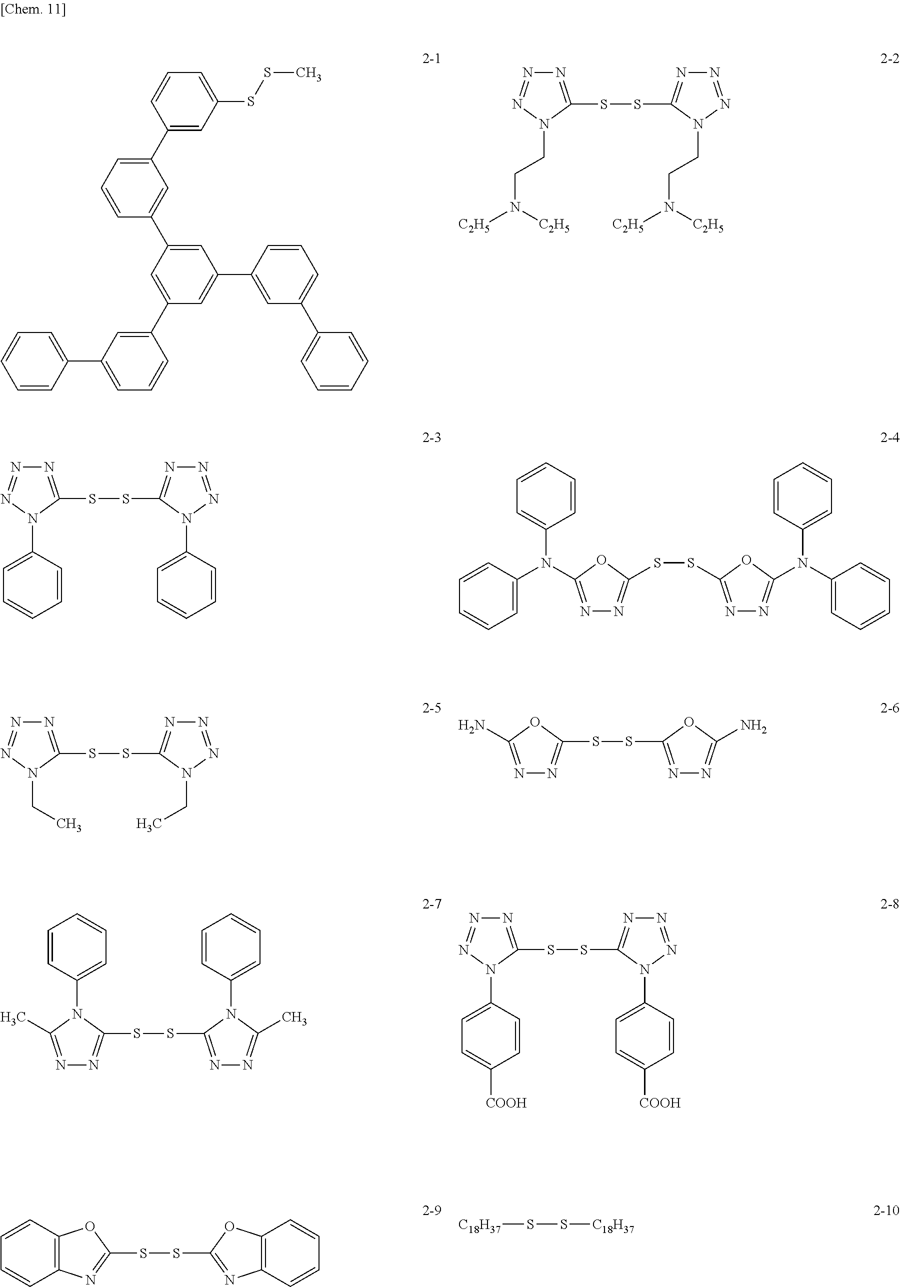

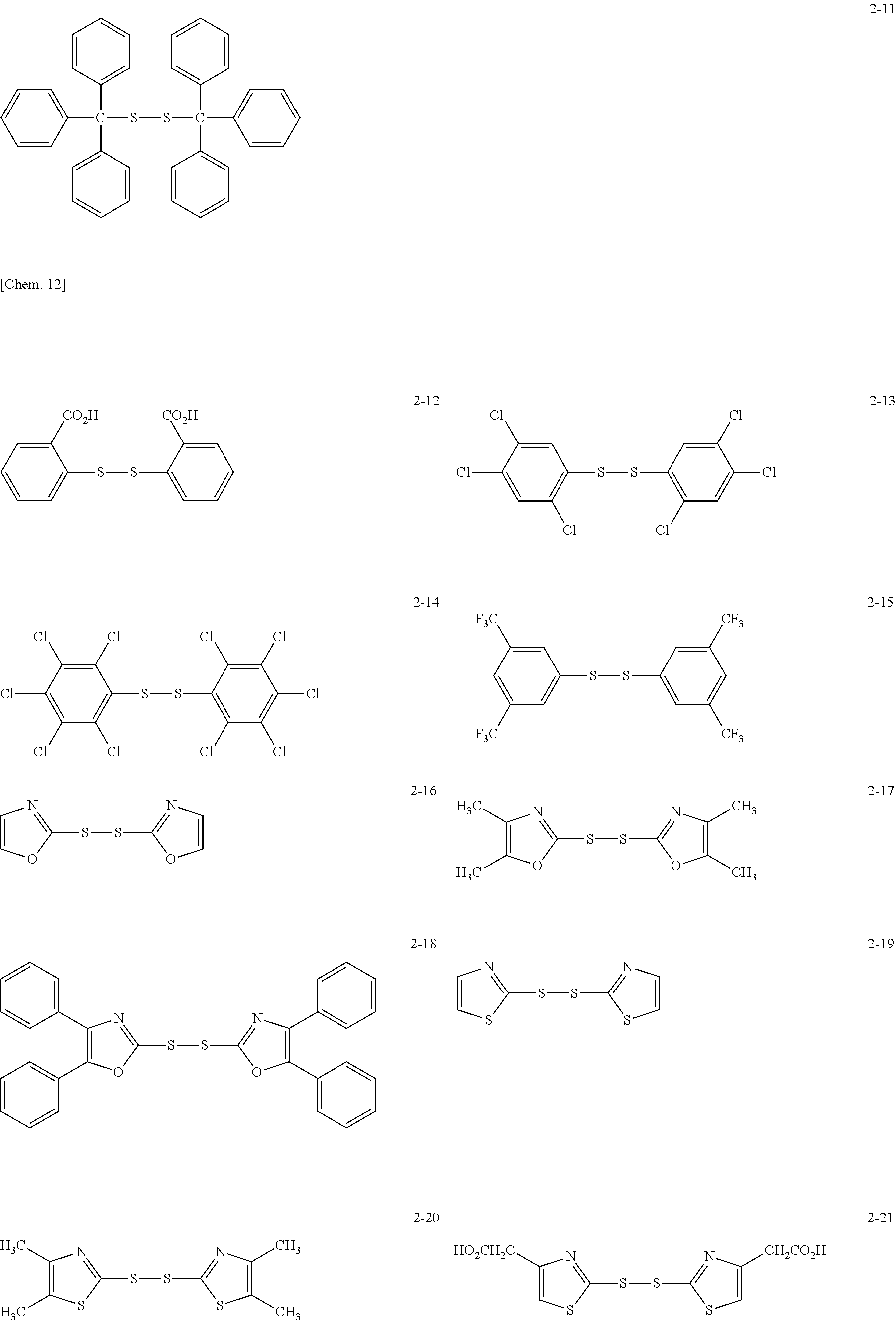

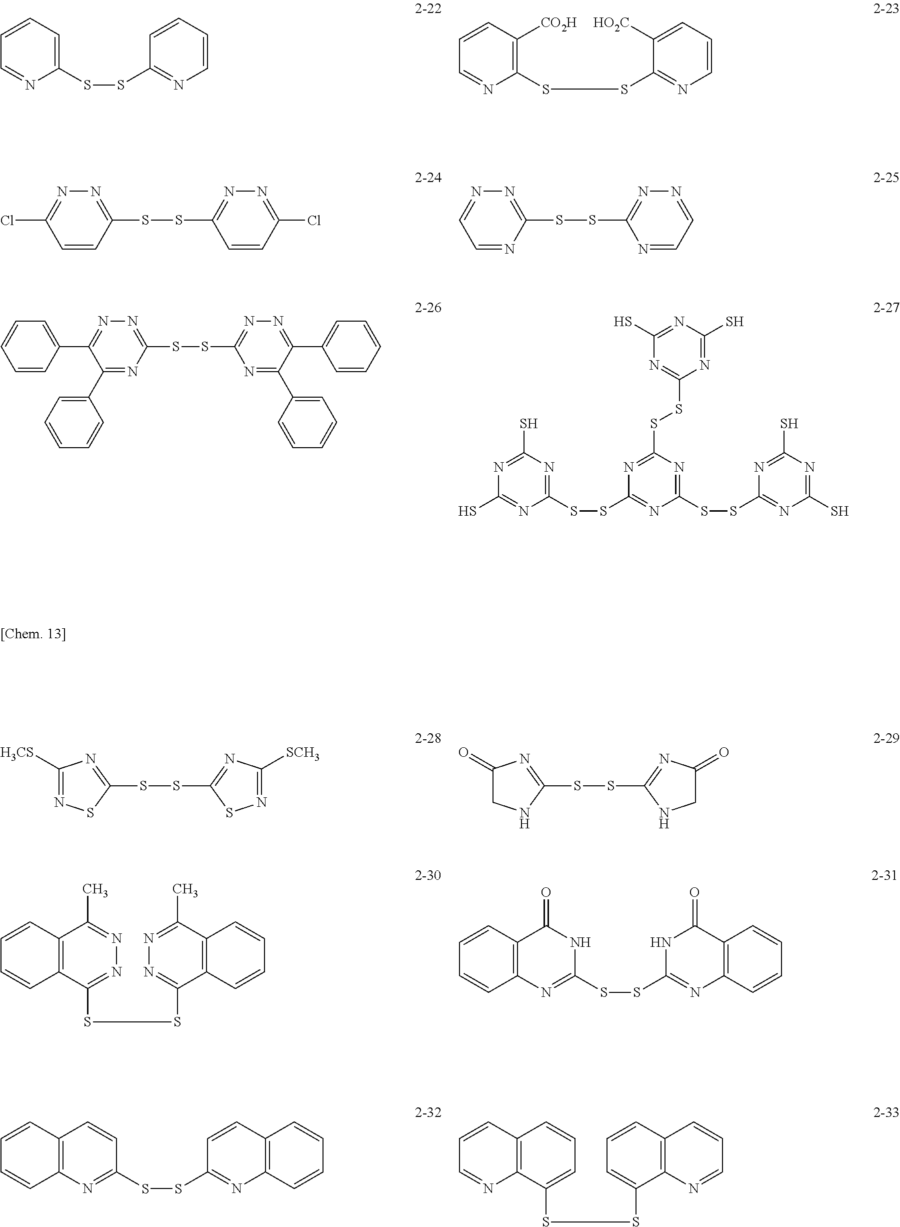

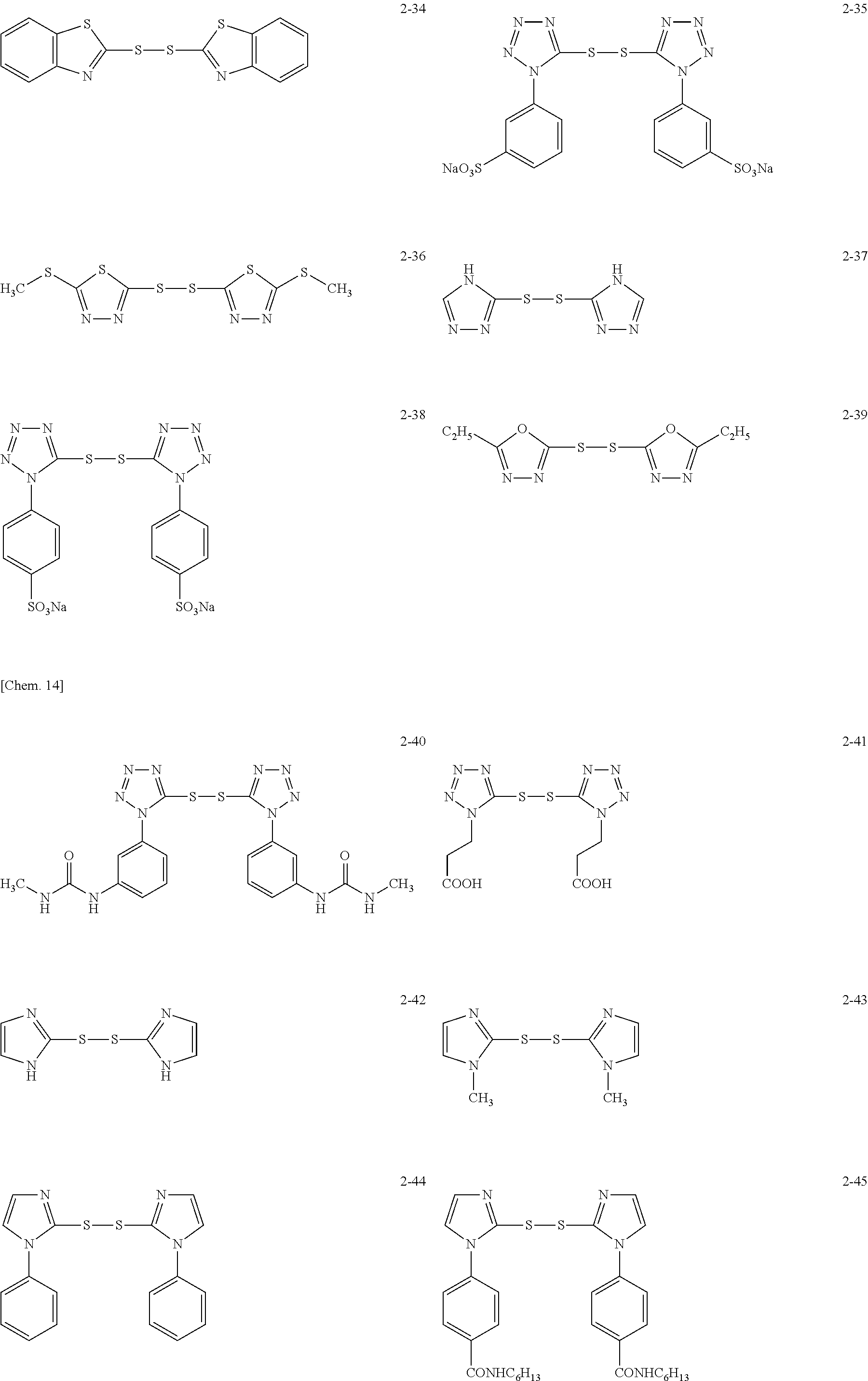

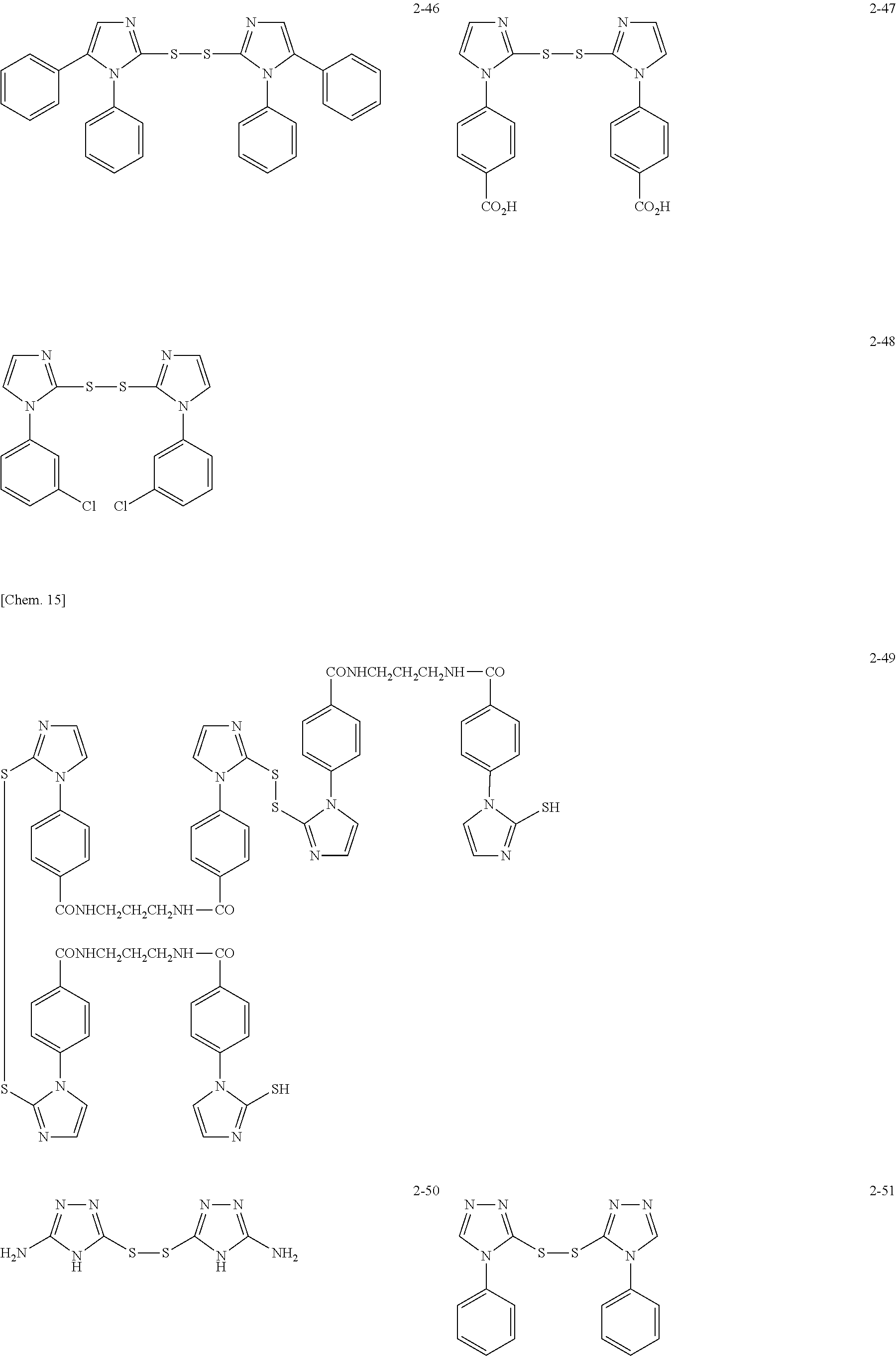

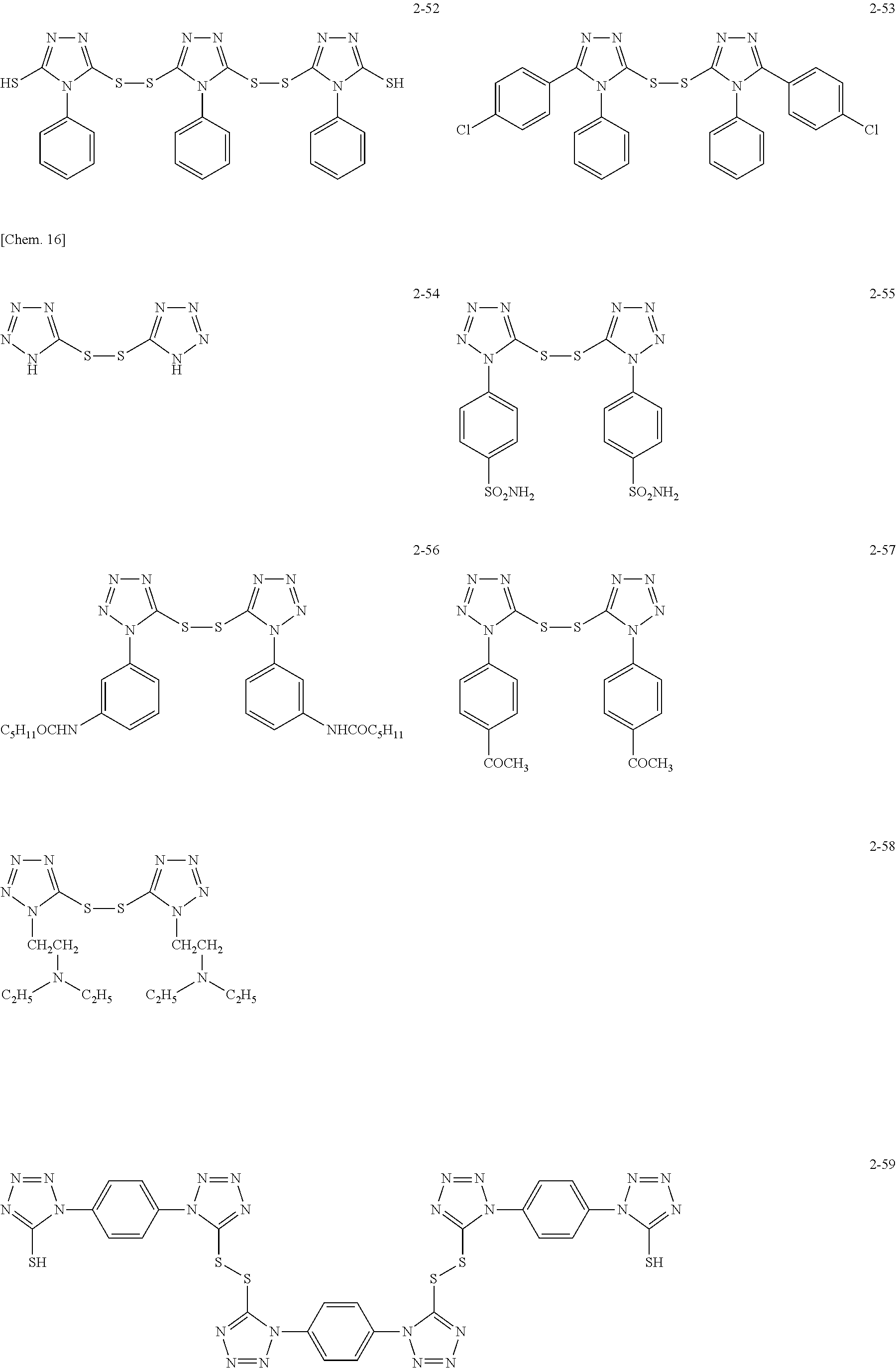

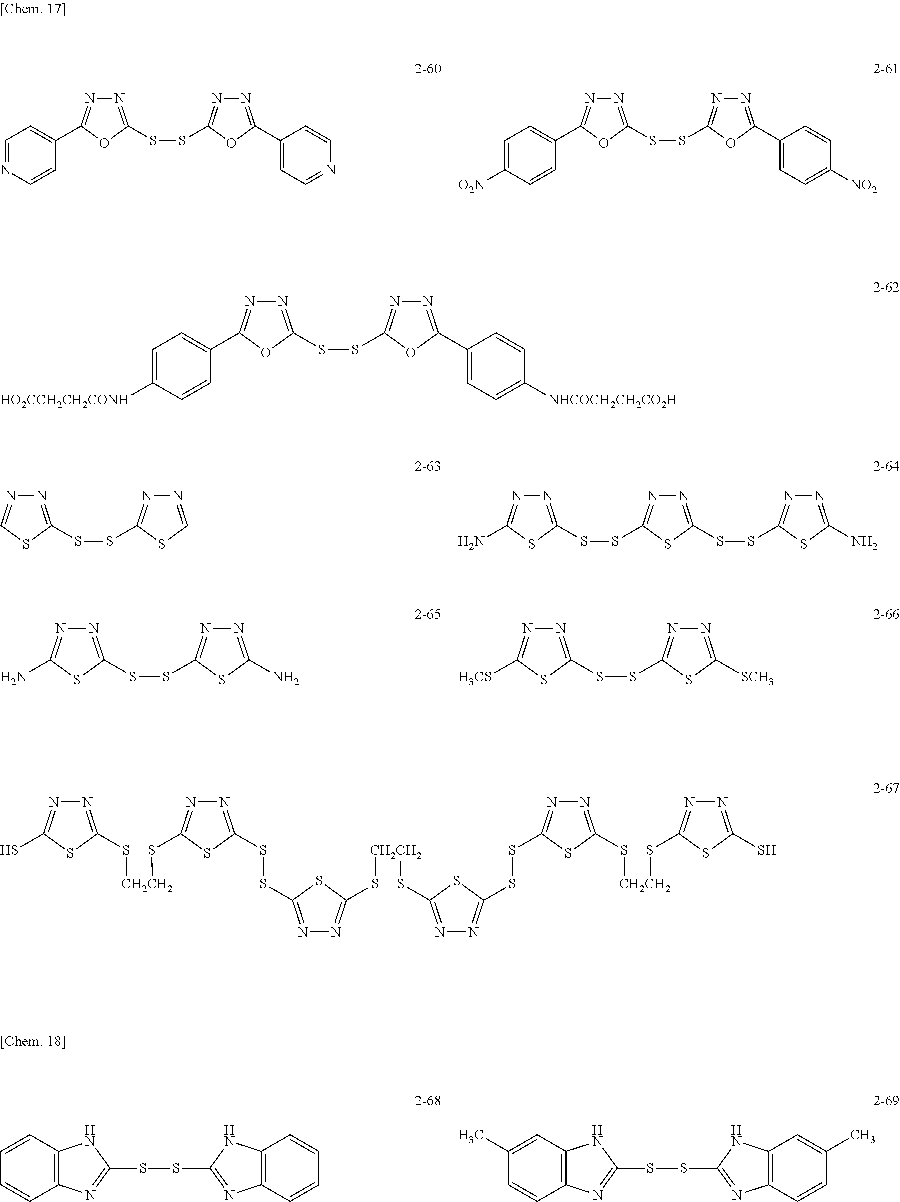

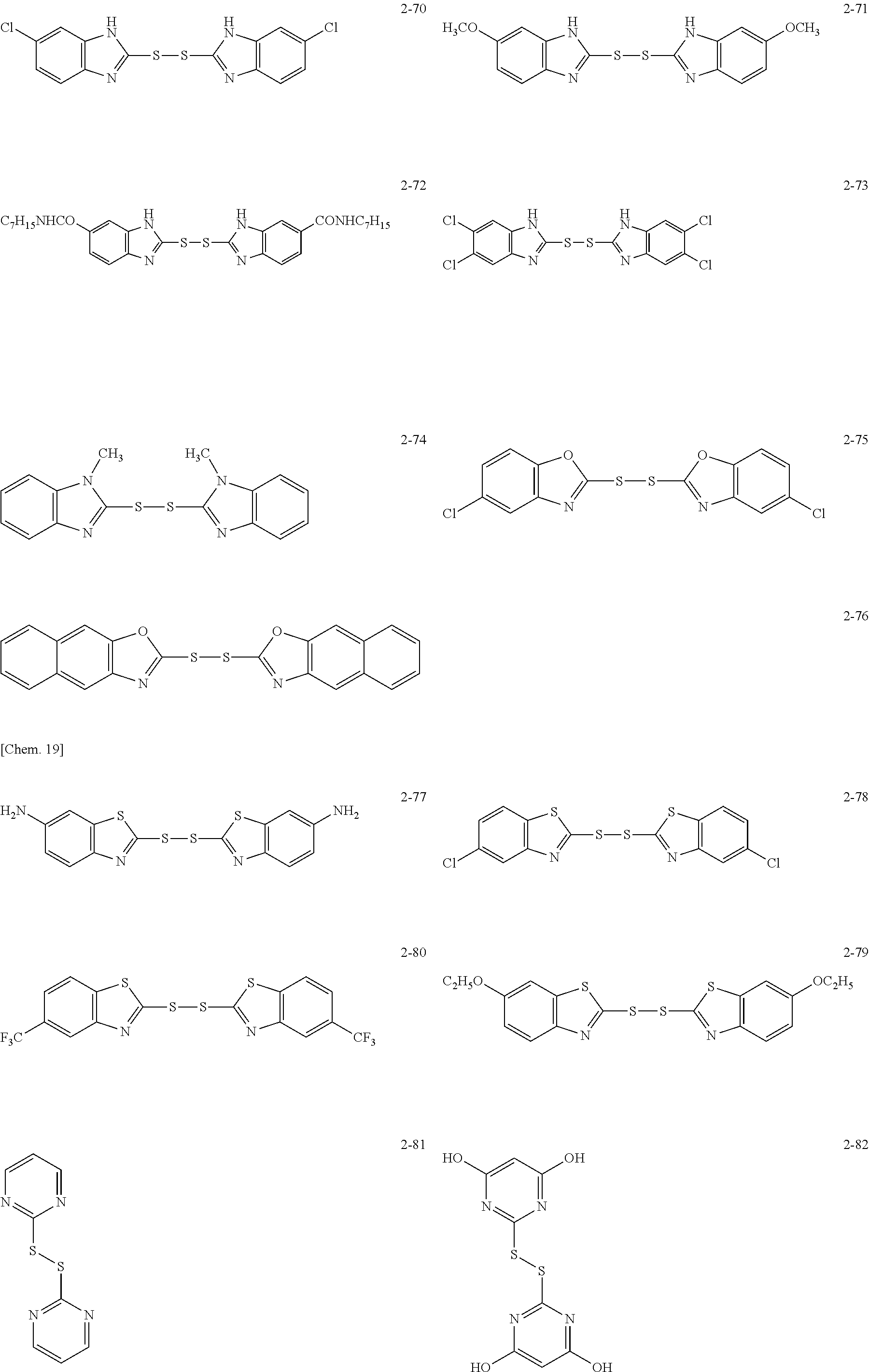

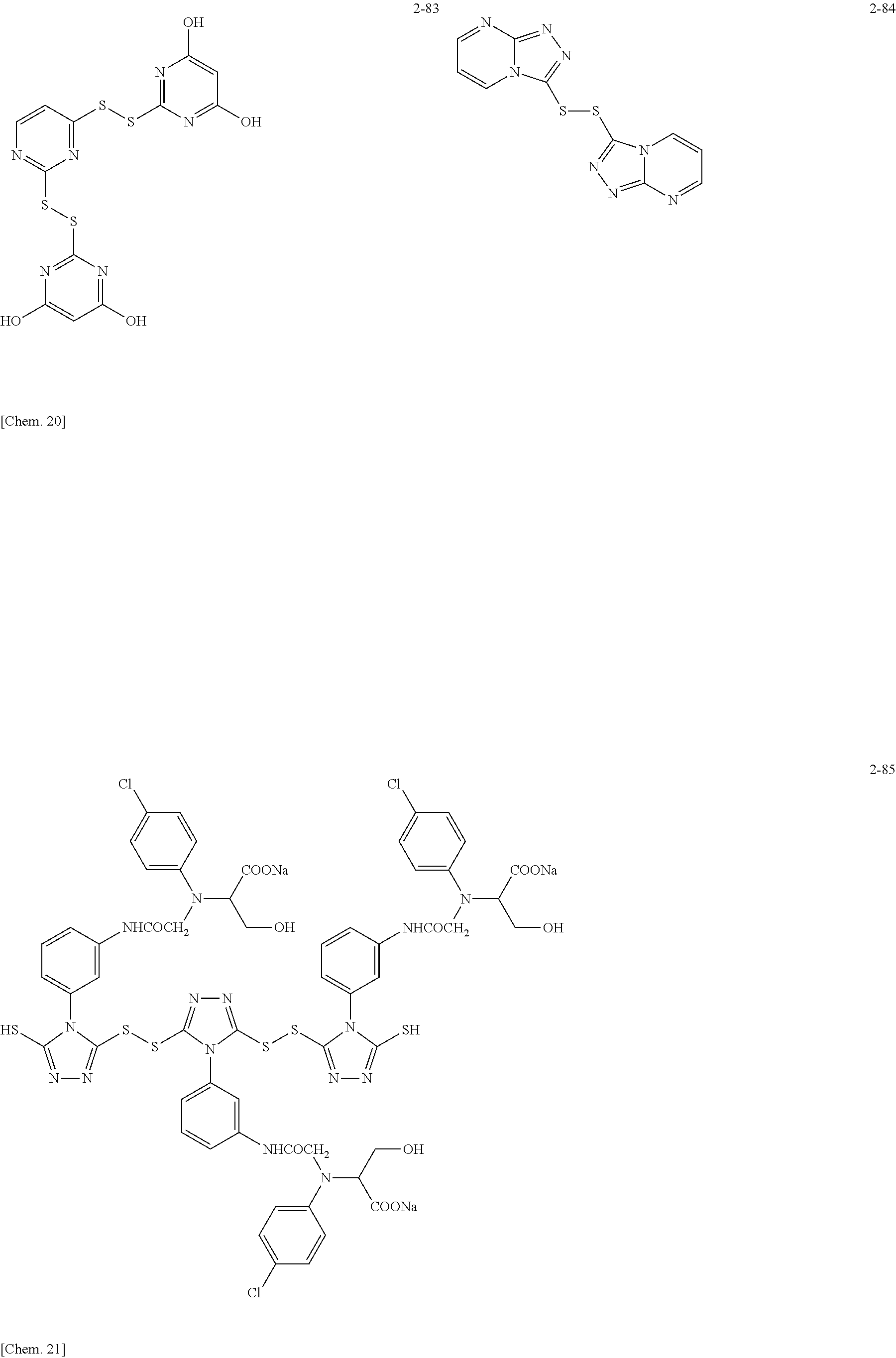

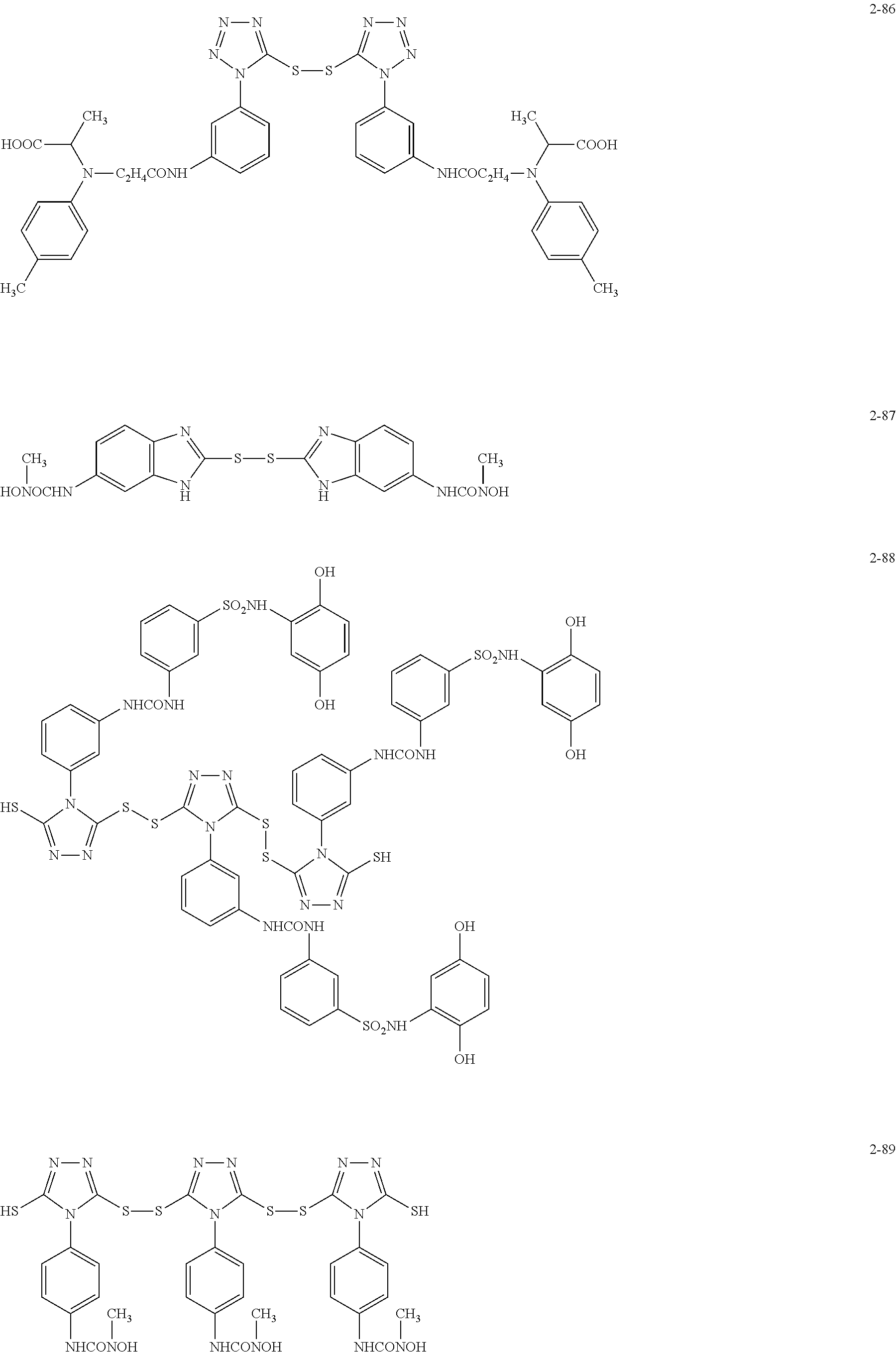

Further, the specific examples of the compound represented by General Formula (3) include the following compounds.

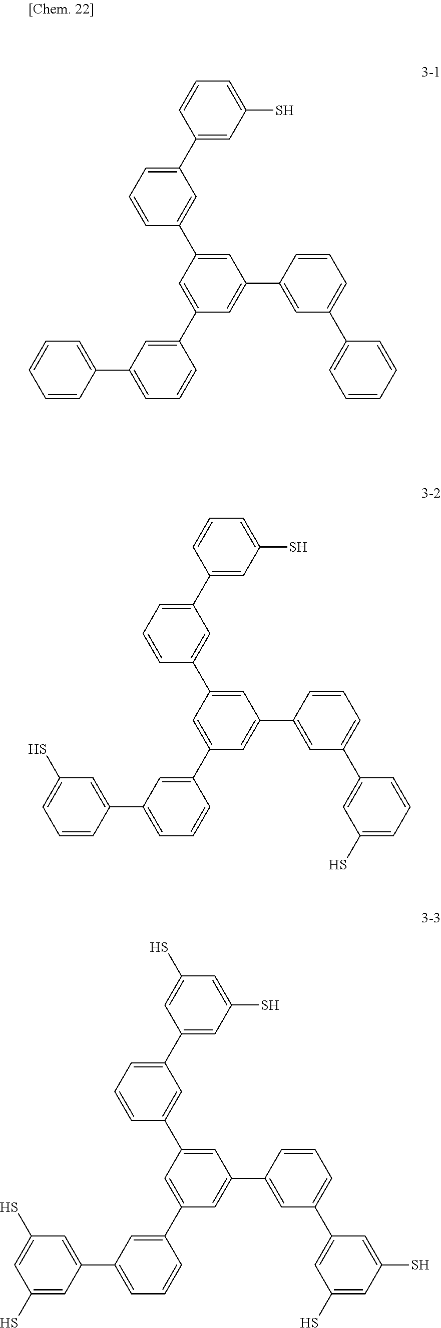

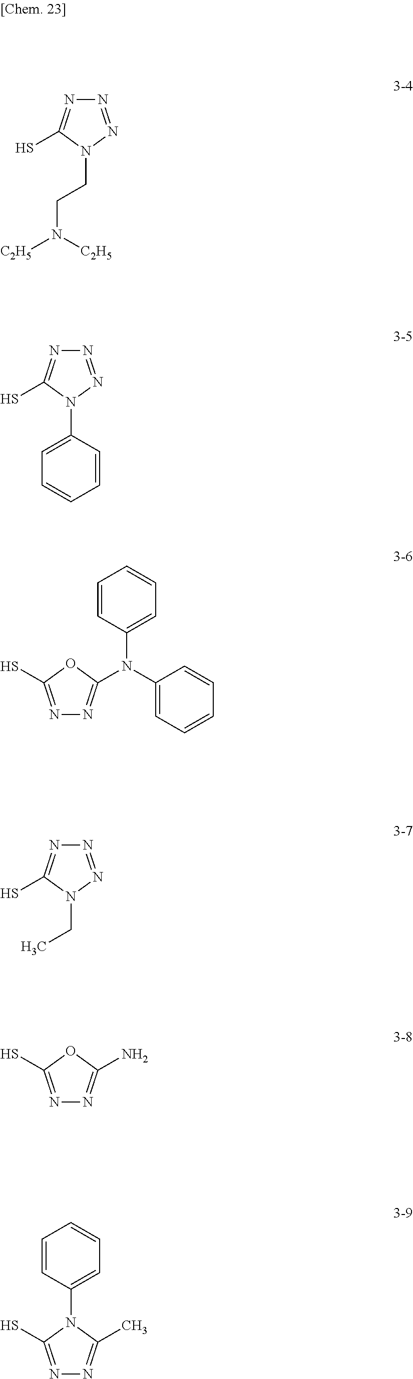

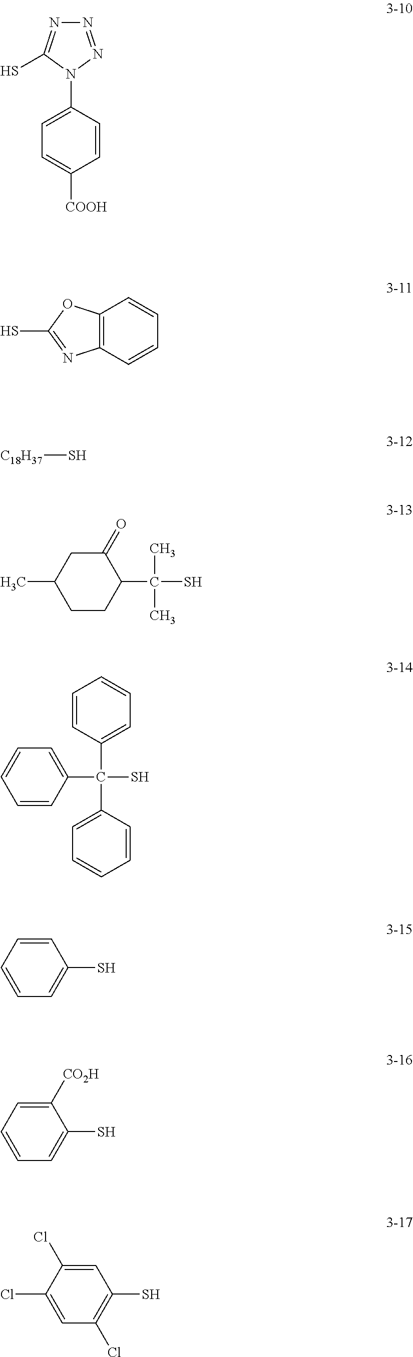

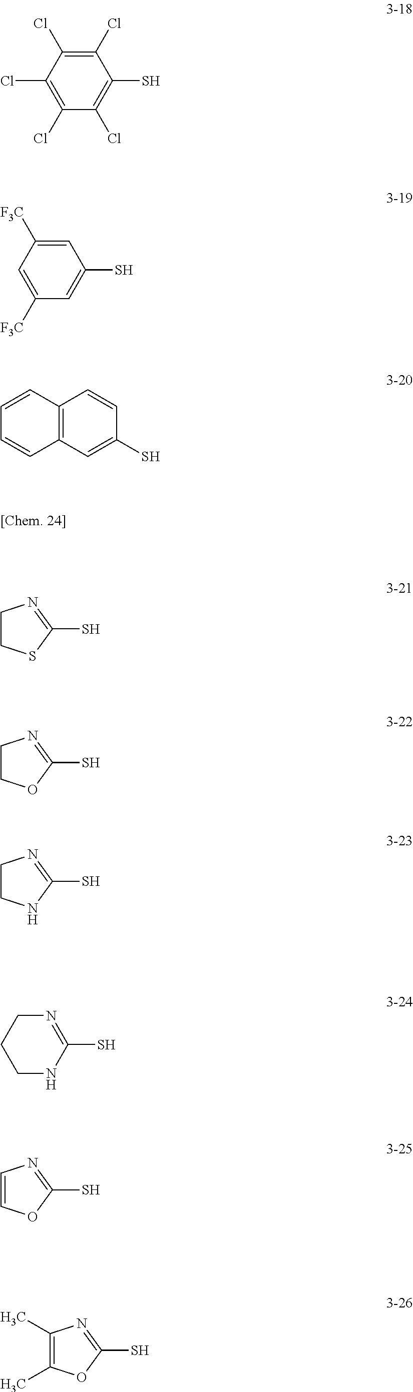

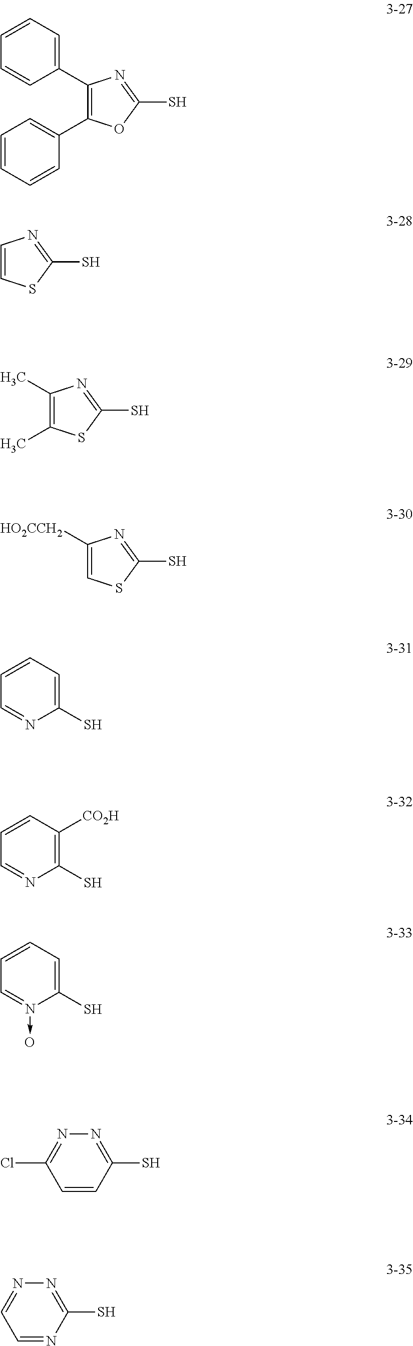

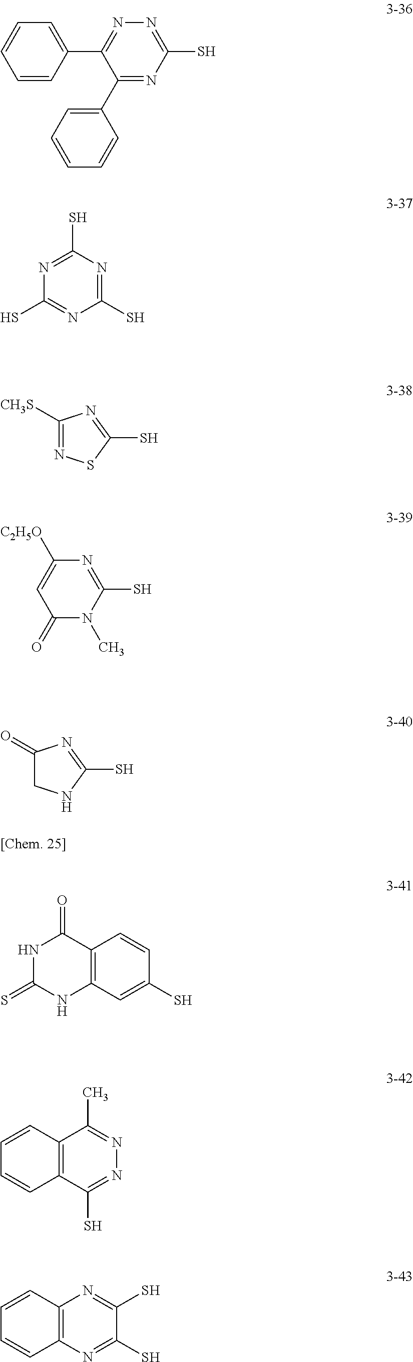

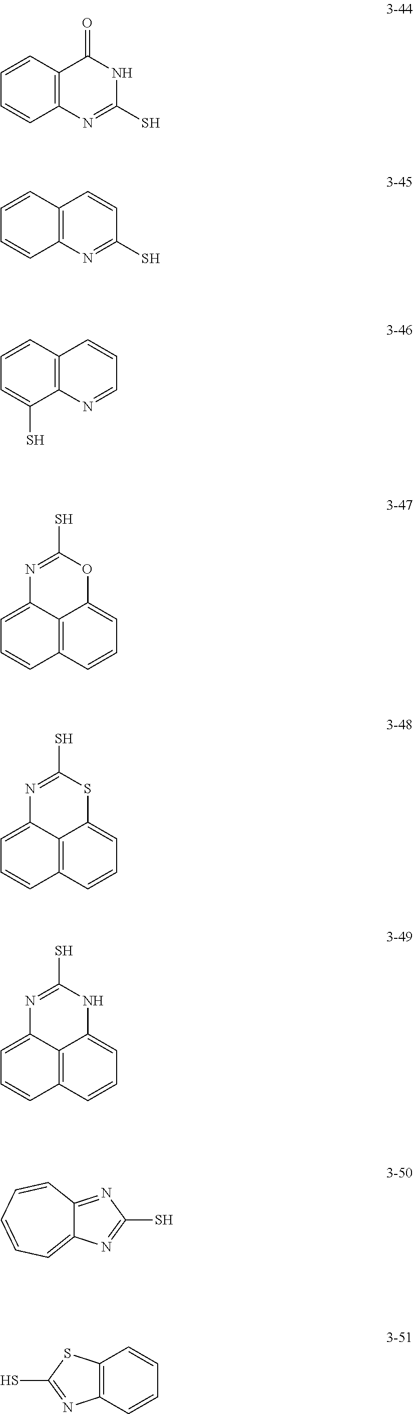

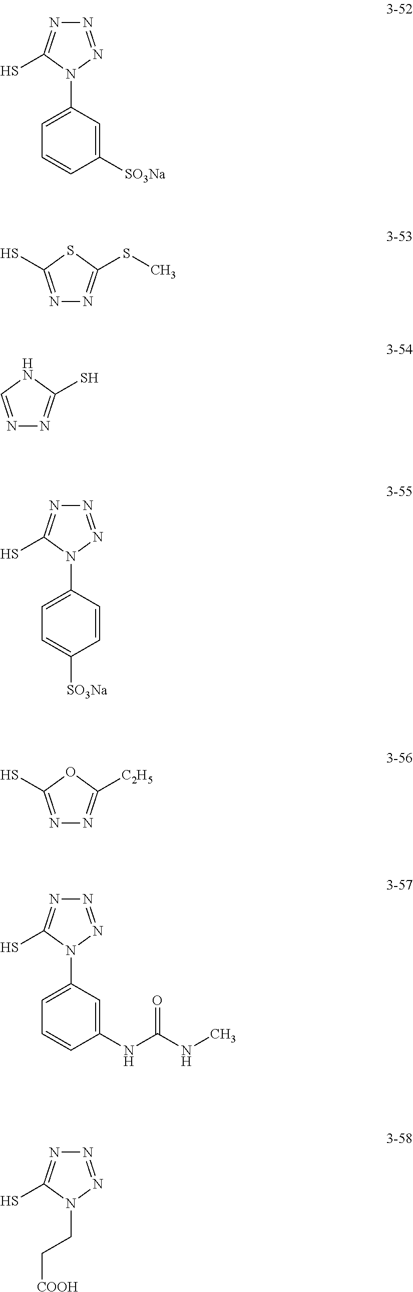

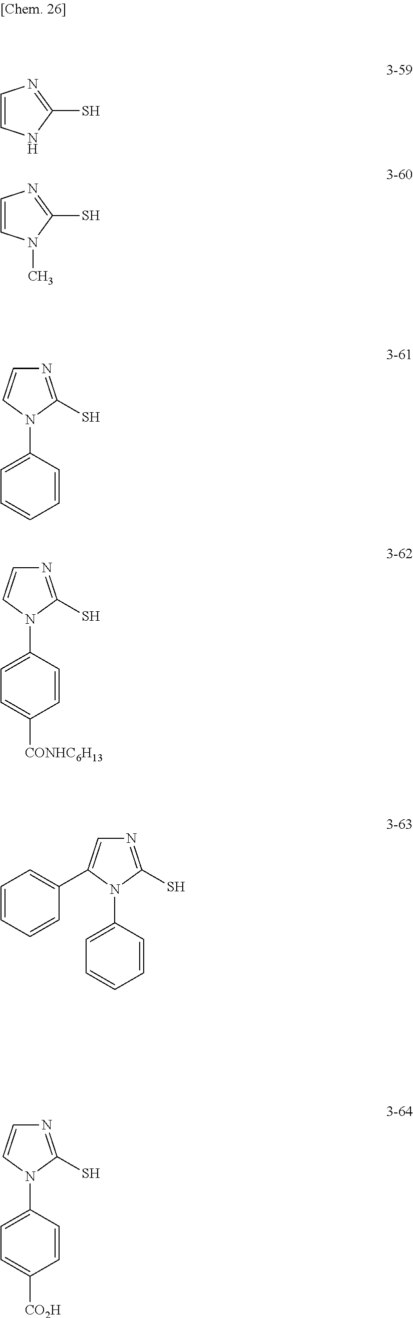

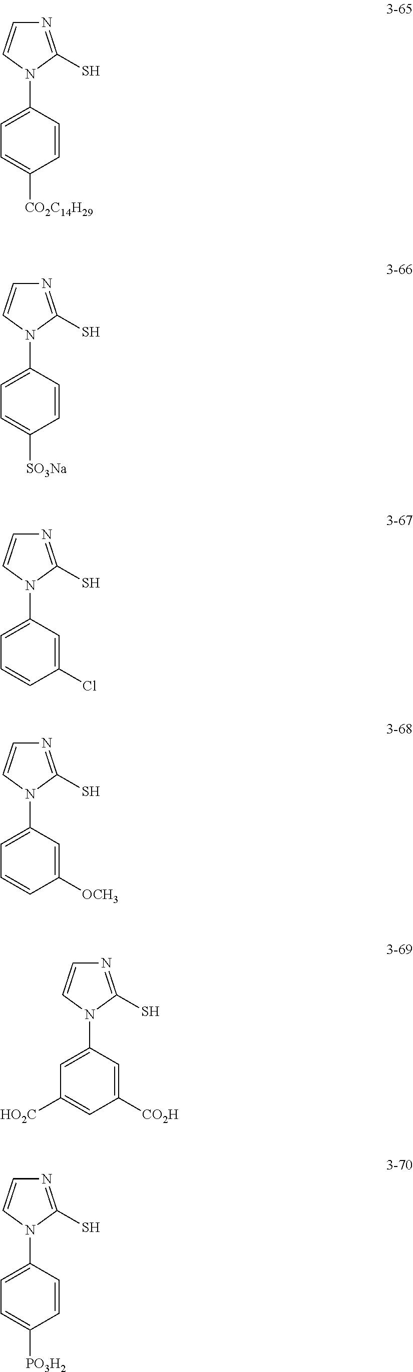

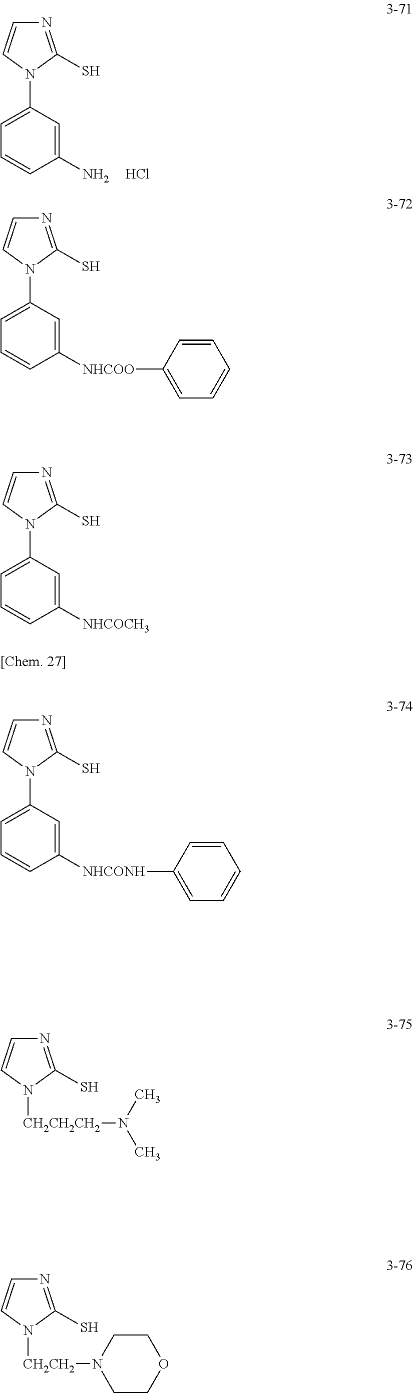

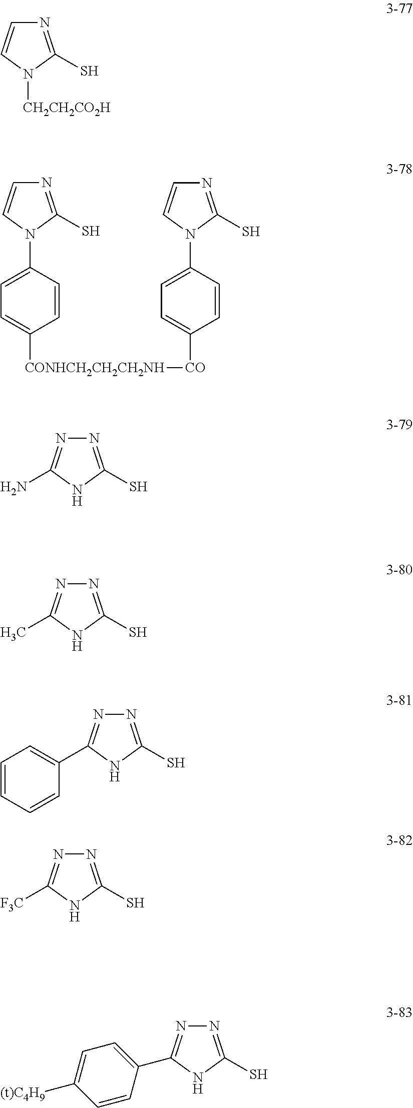

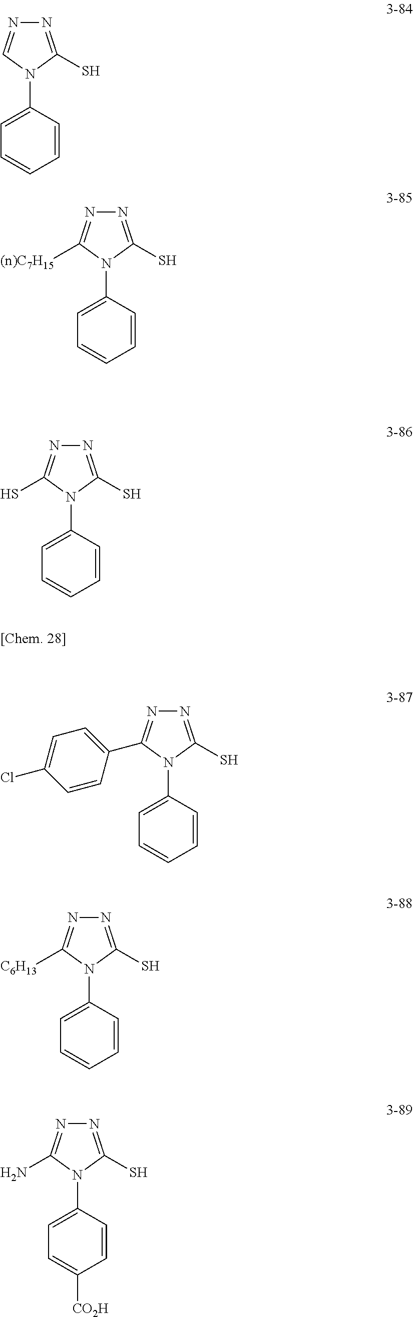

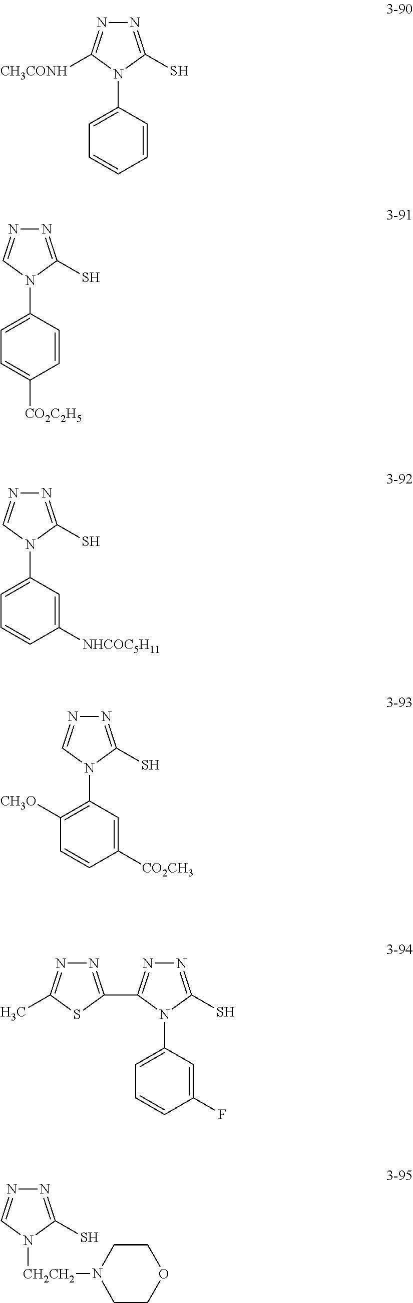

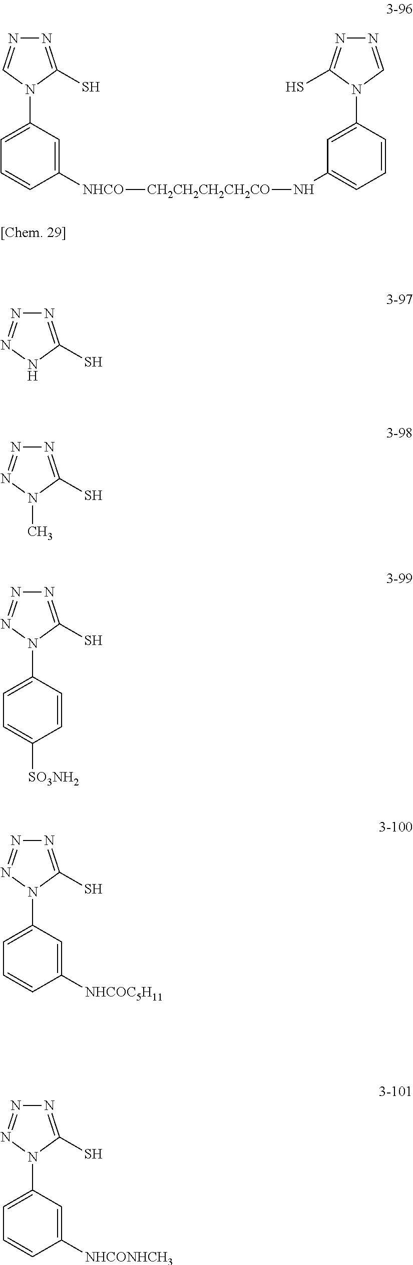

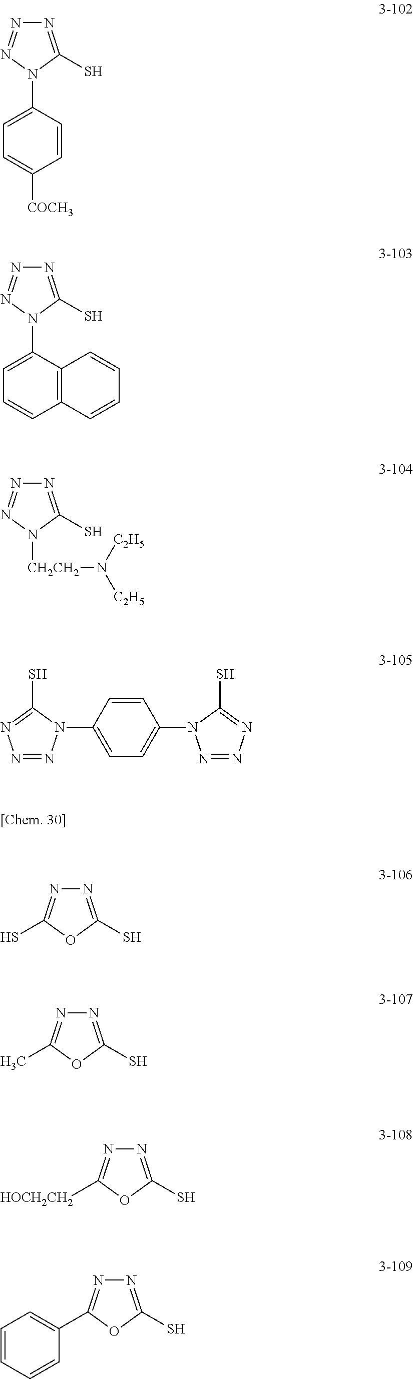

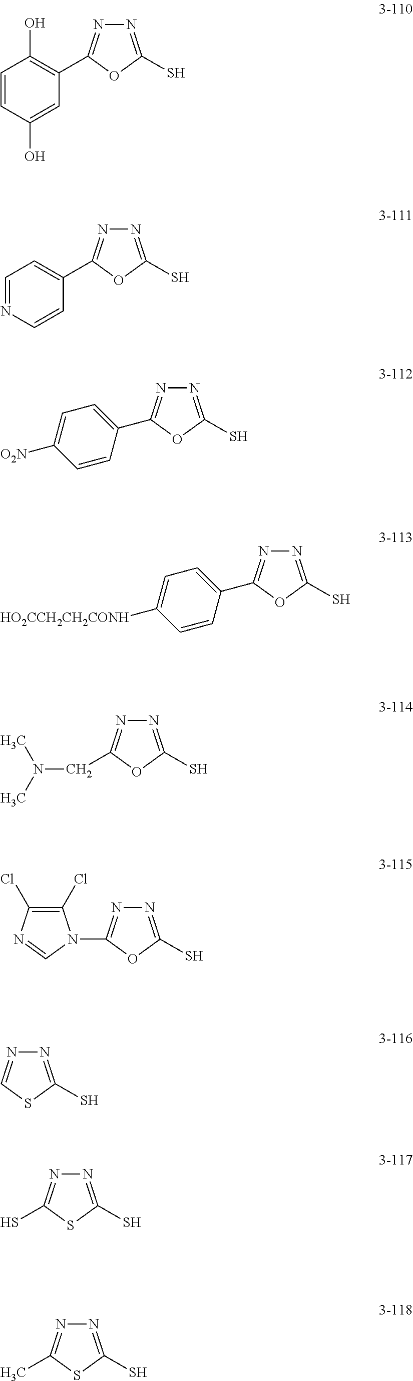

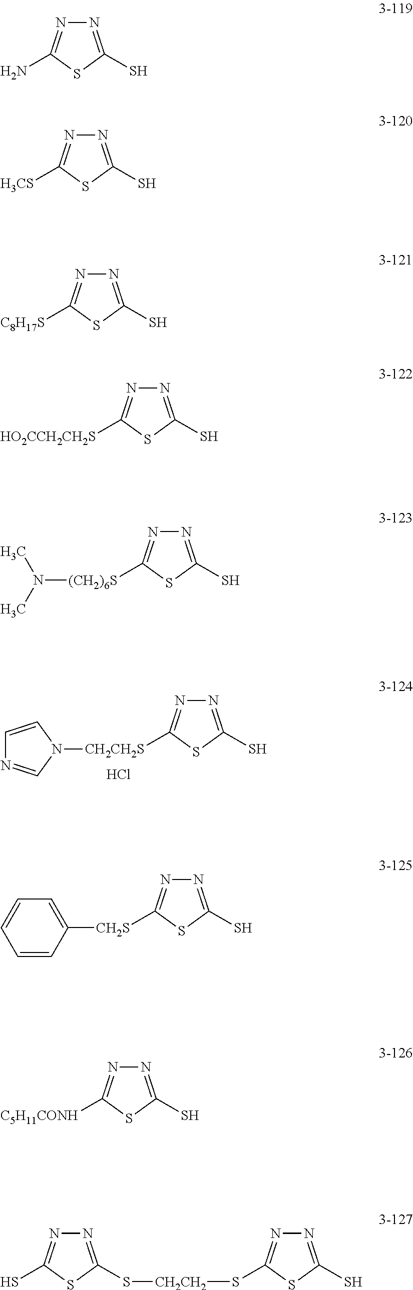

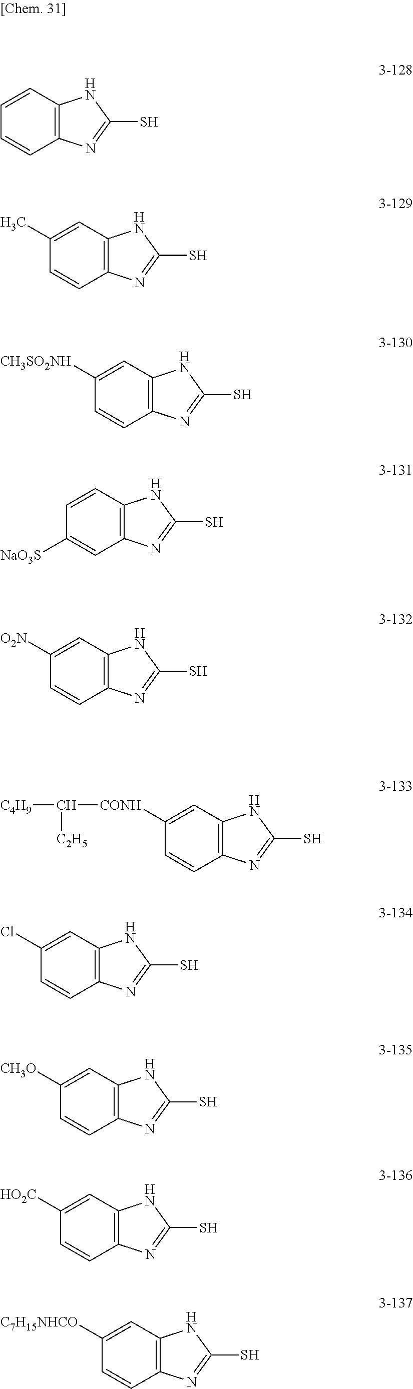

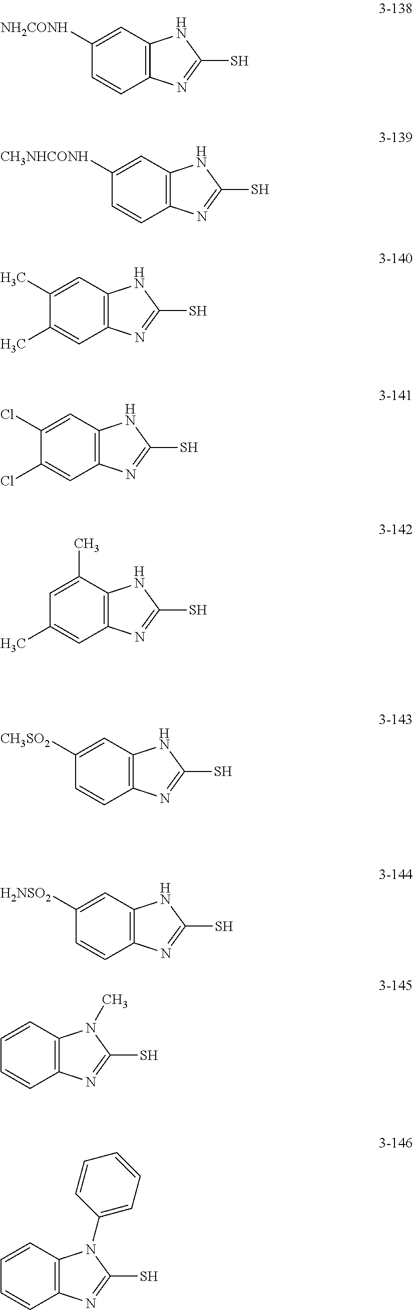

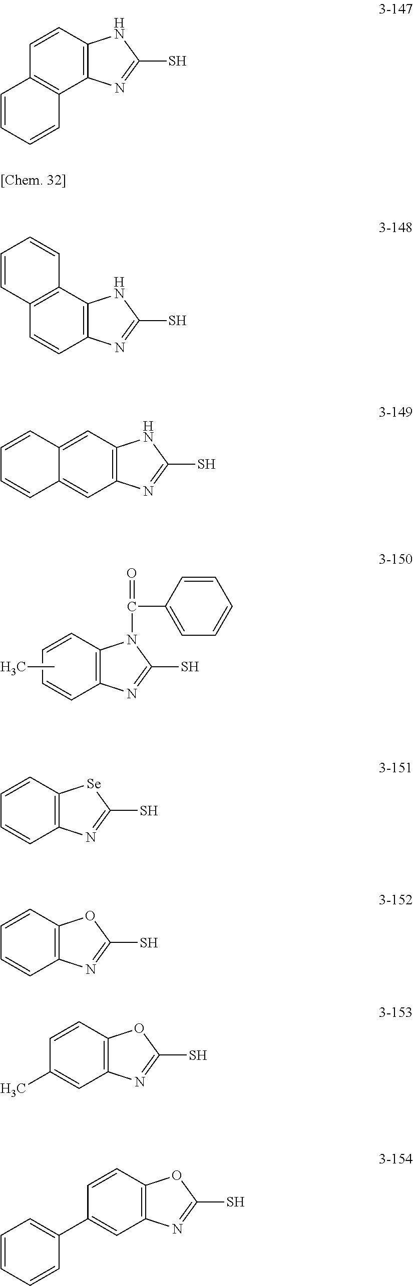

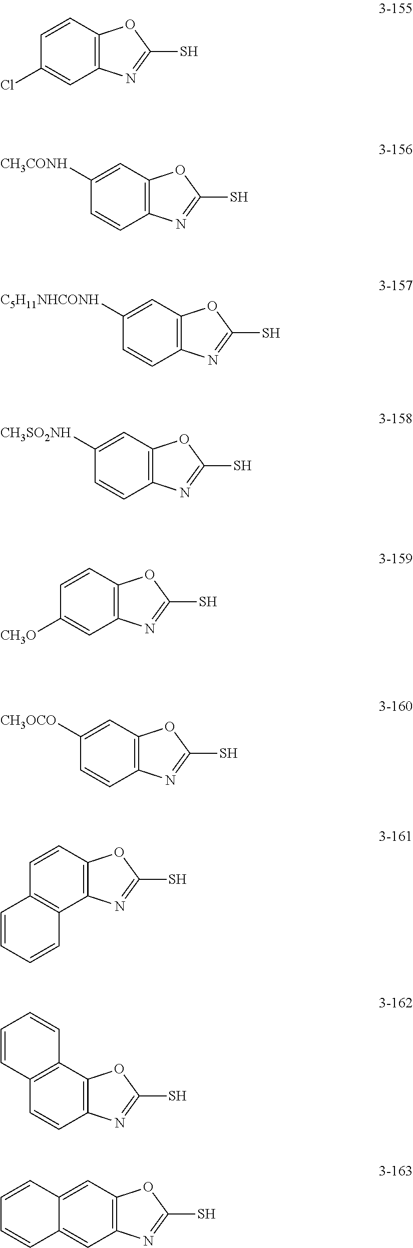

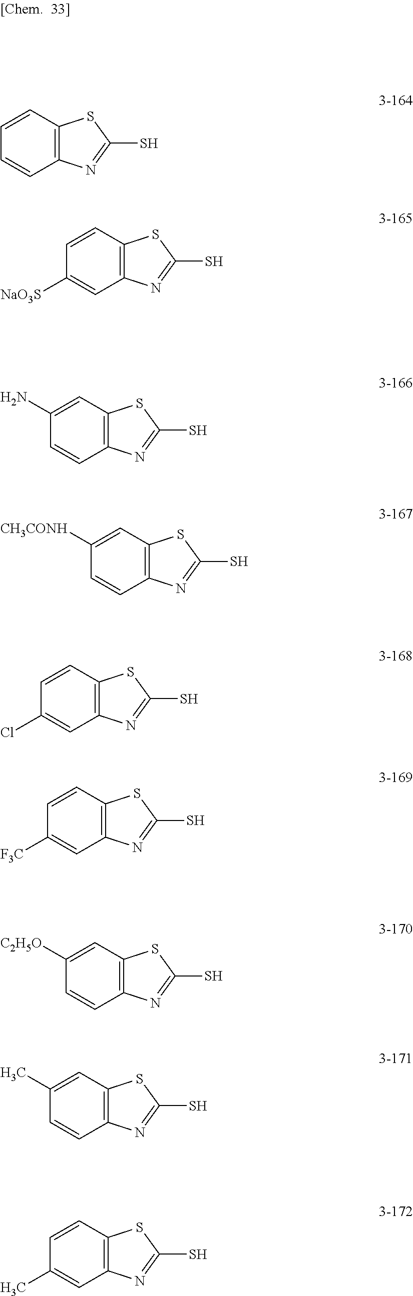

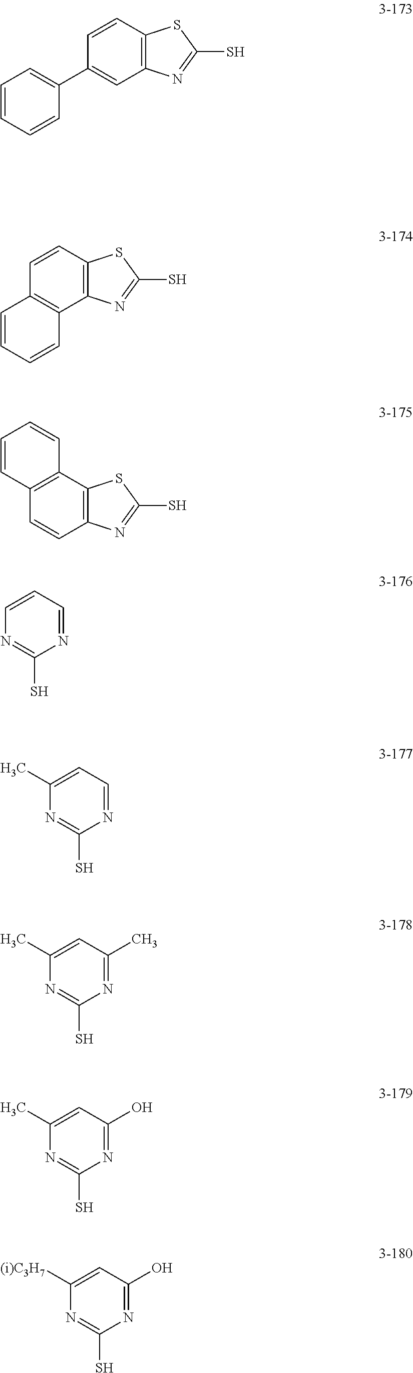

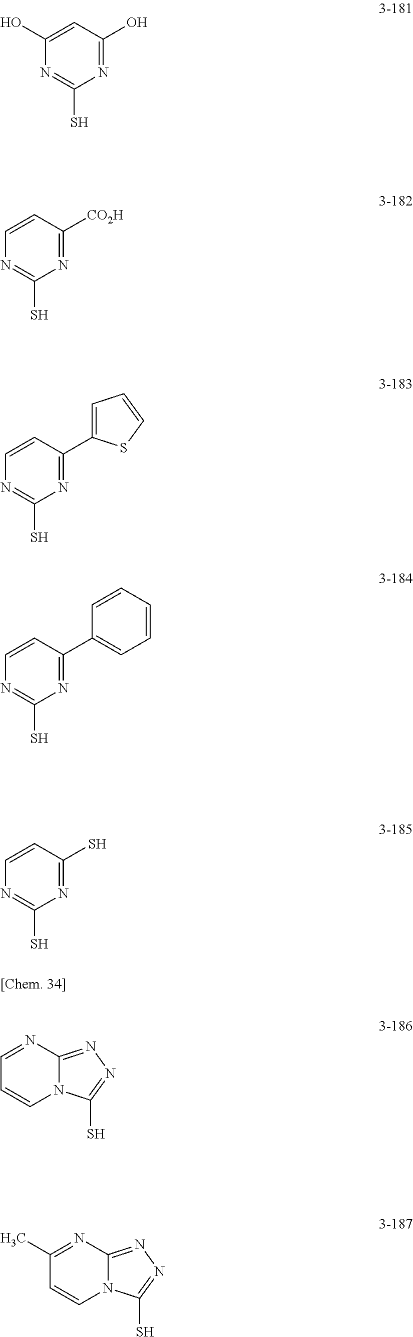

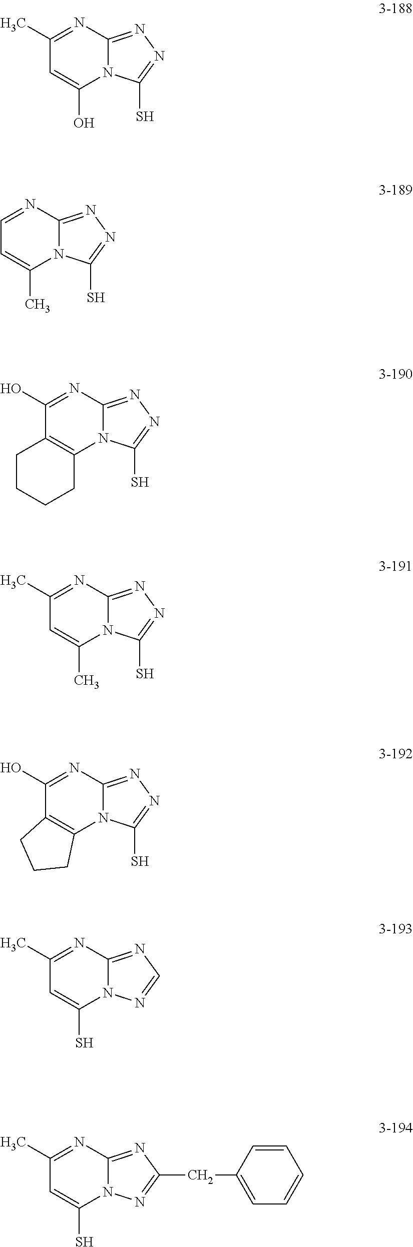

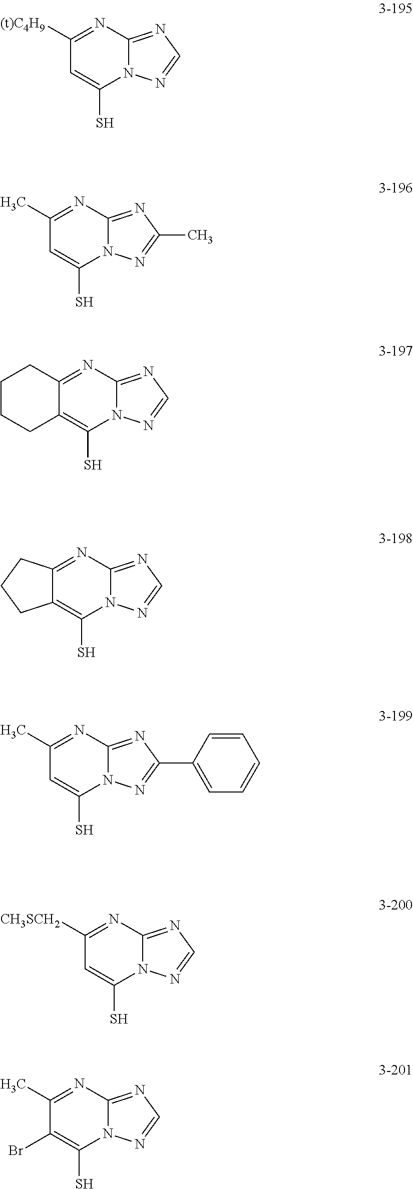

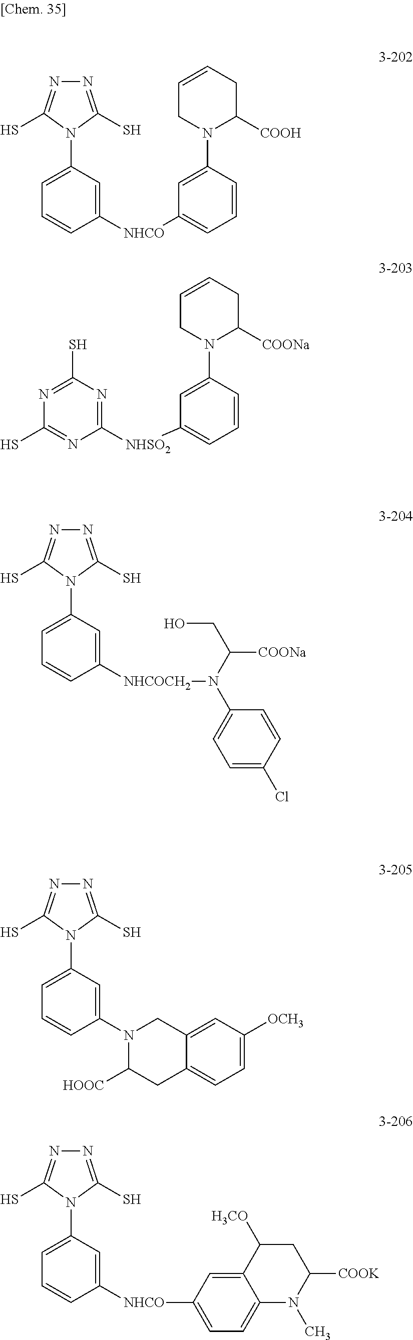

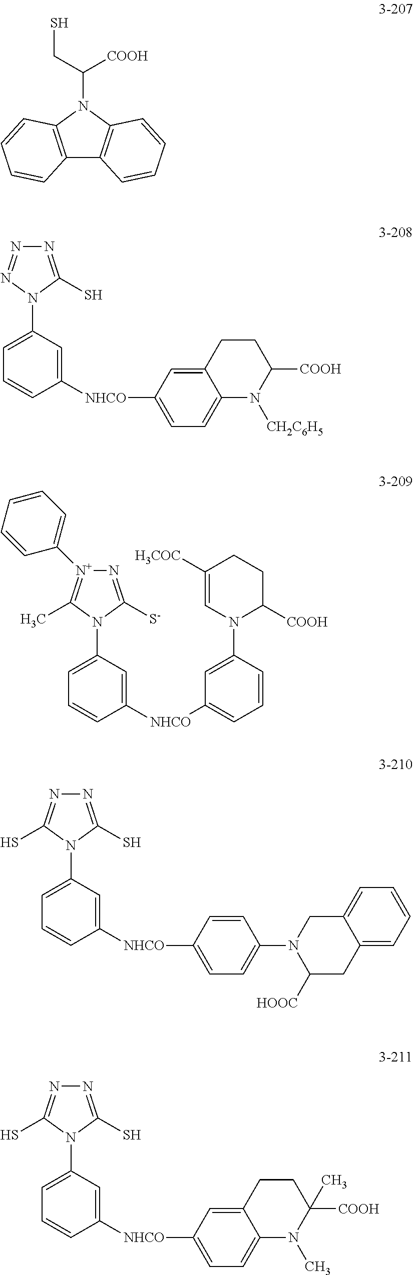

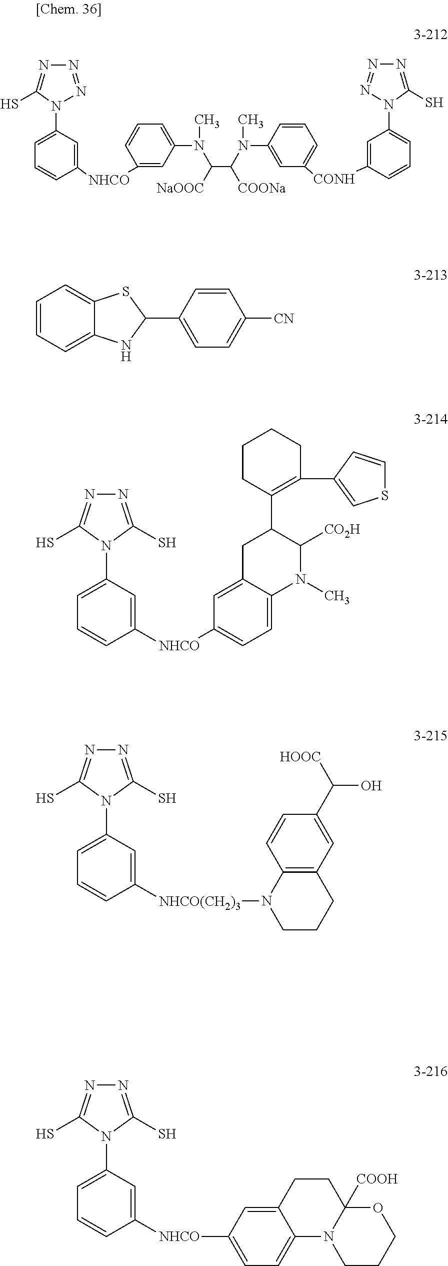

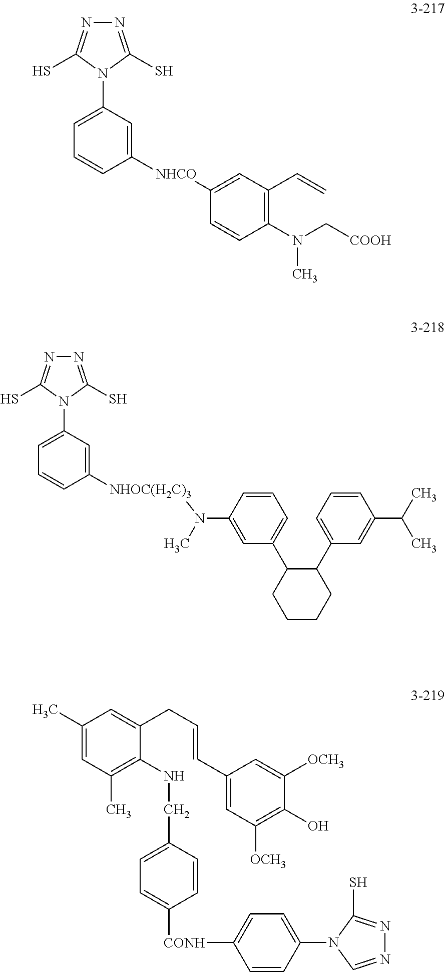

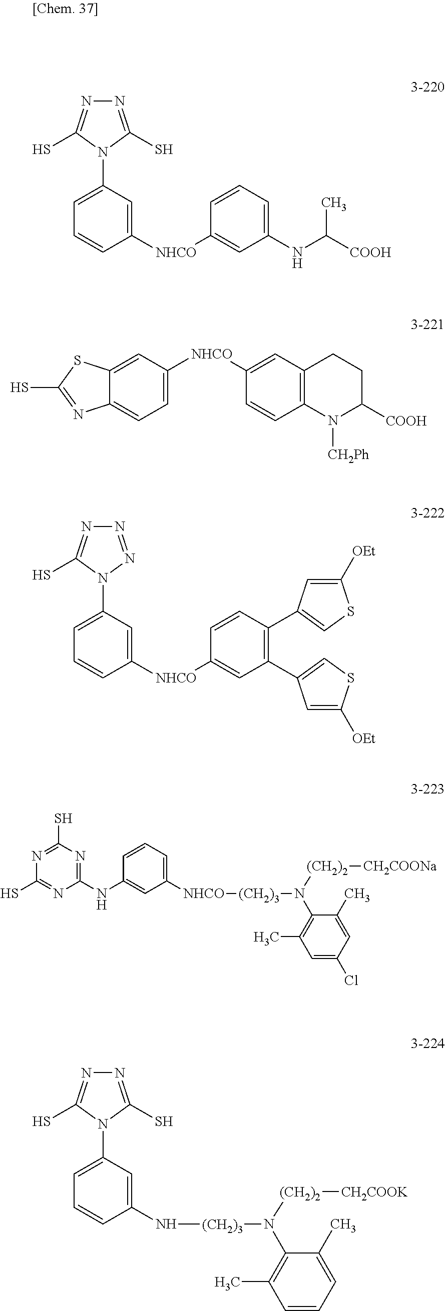

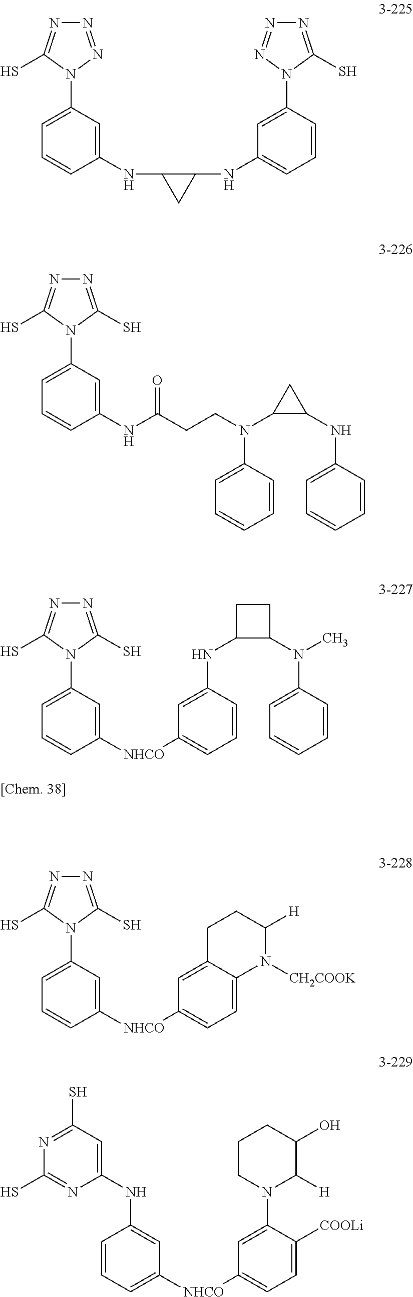

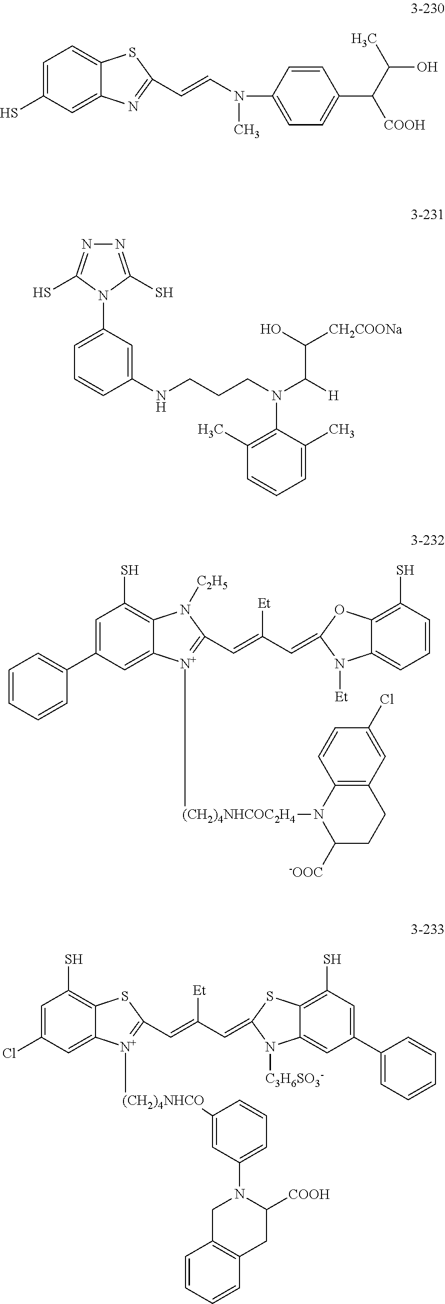

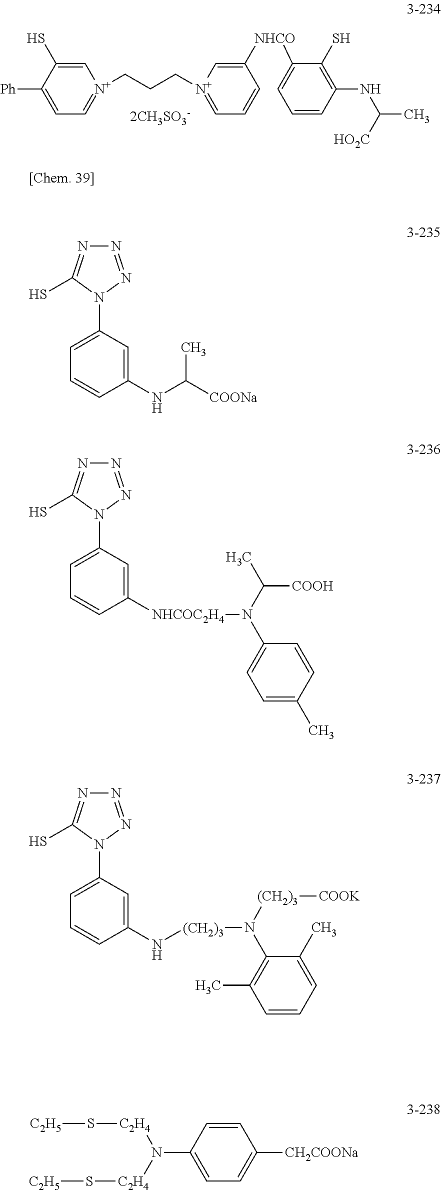

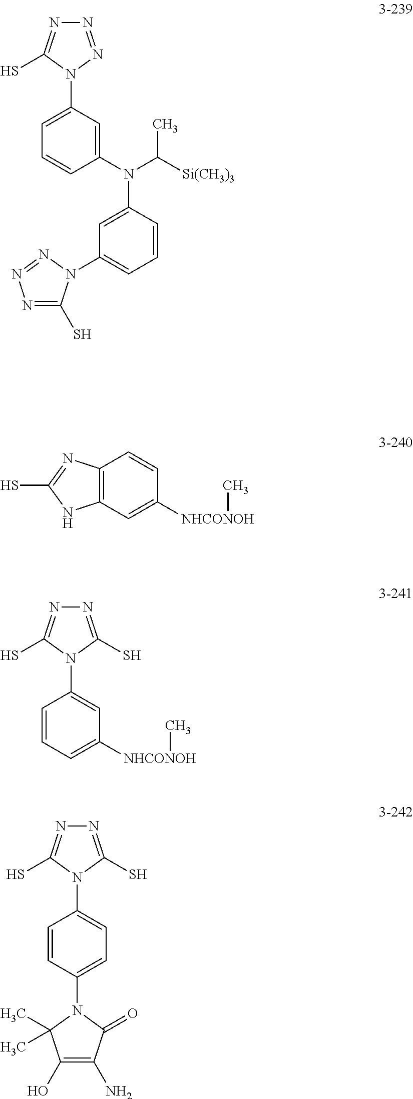

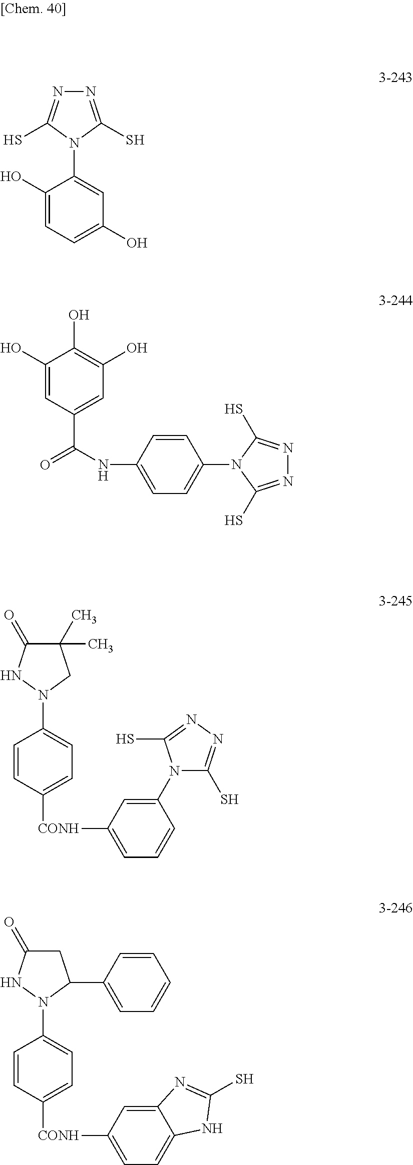

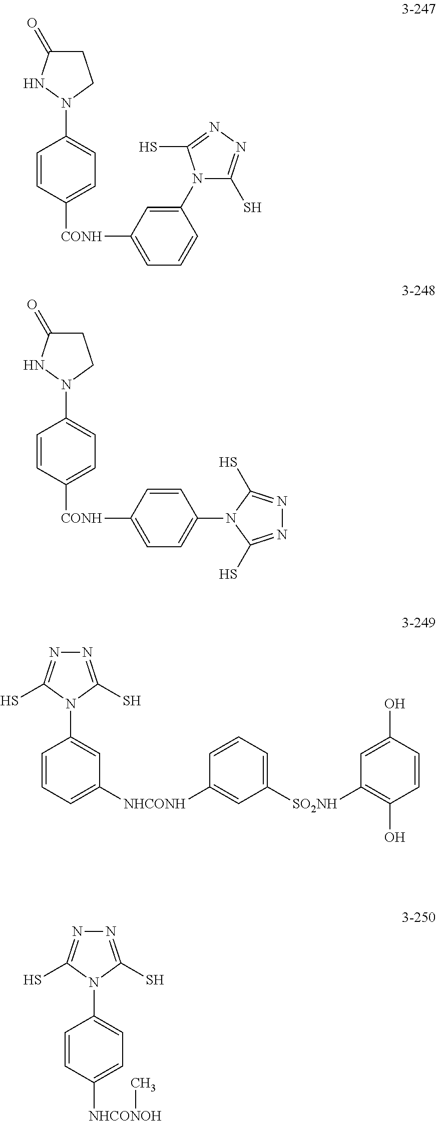

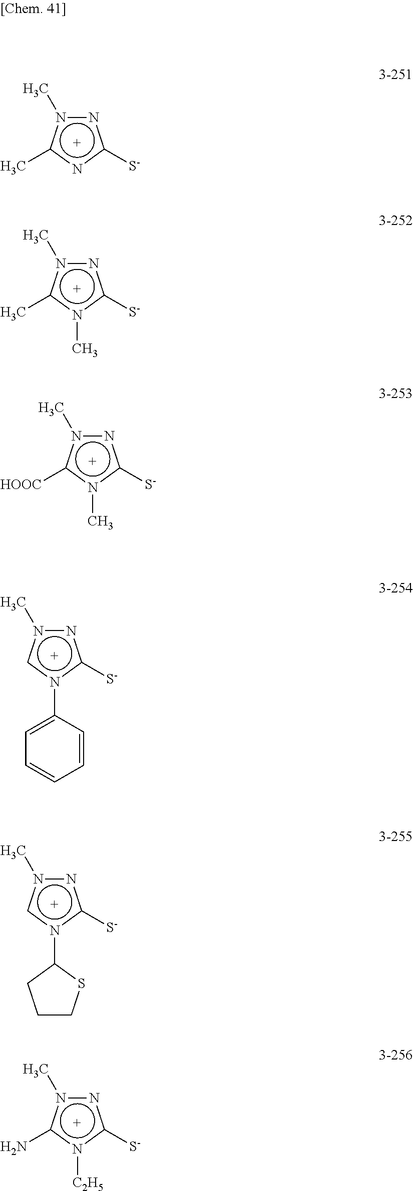

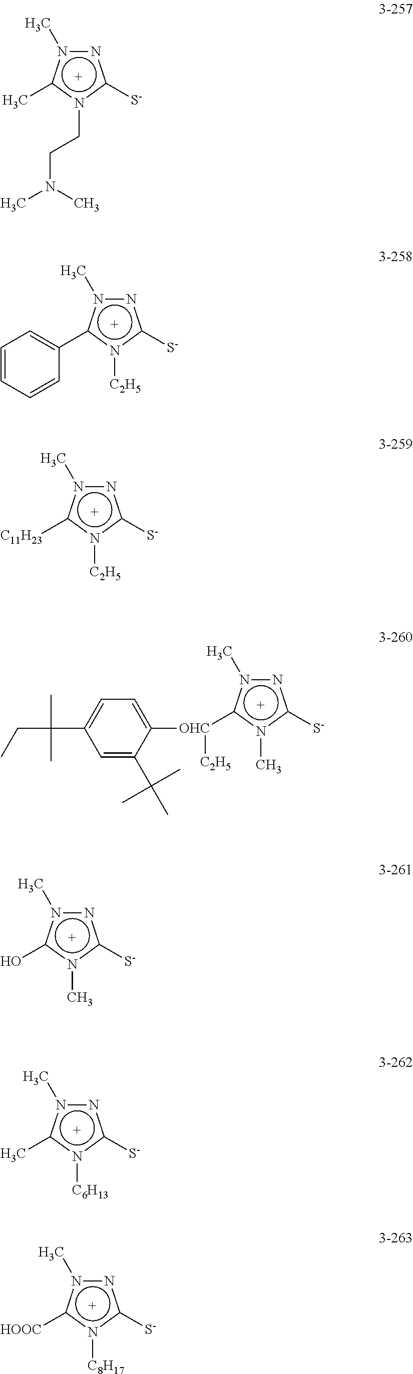

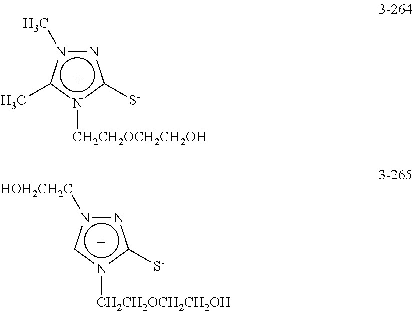

Further, the specific examples of the compound represented by General Formula (4) include the following compounds.

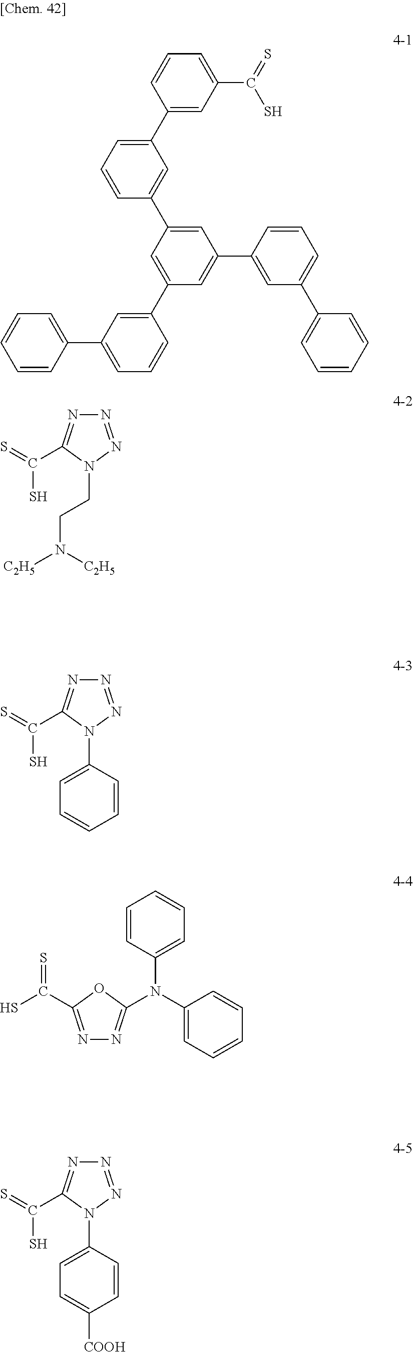

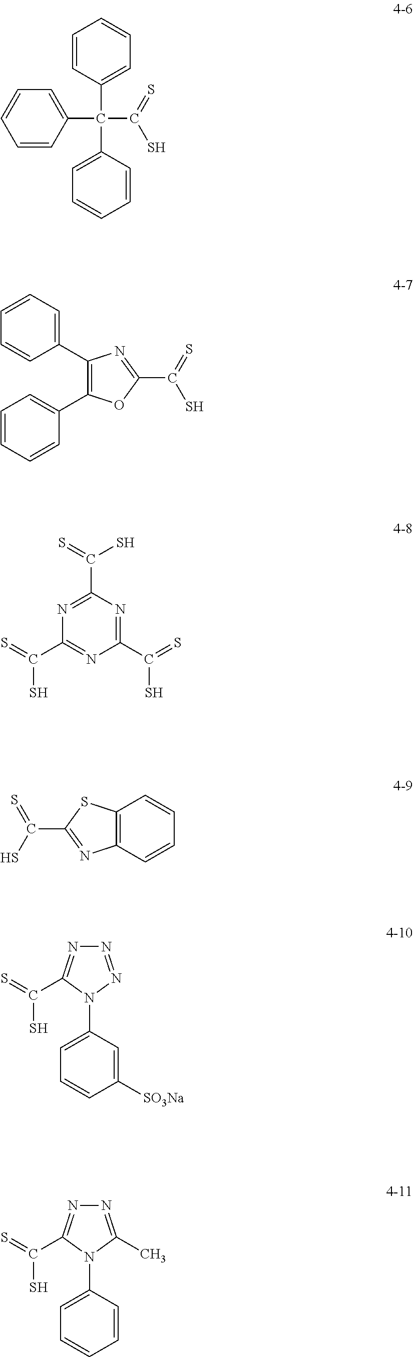

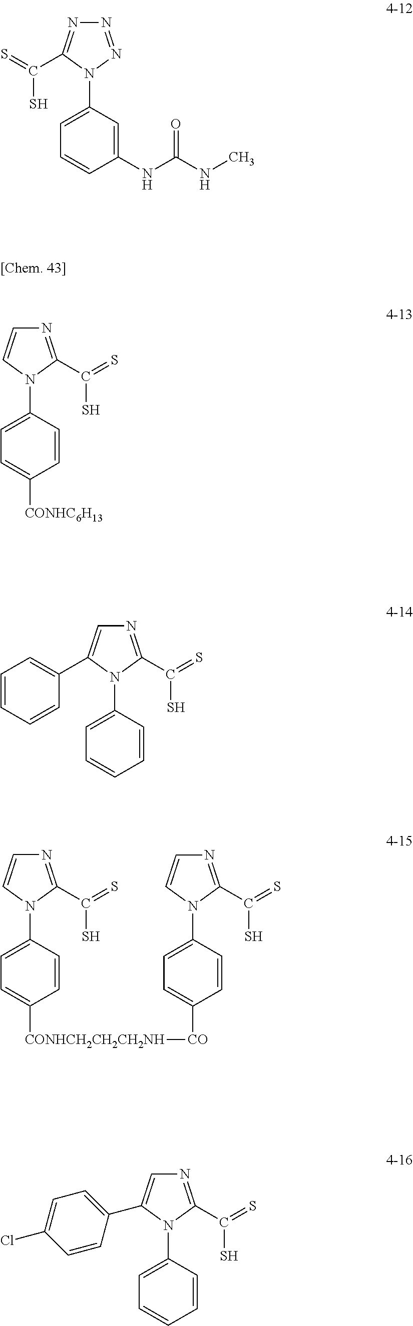

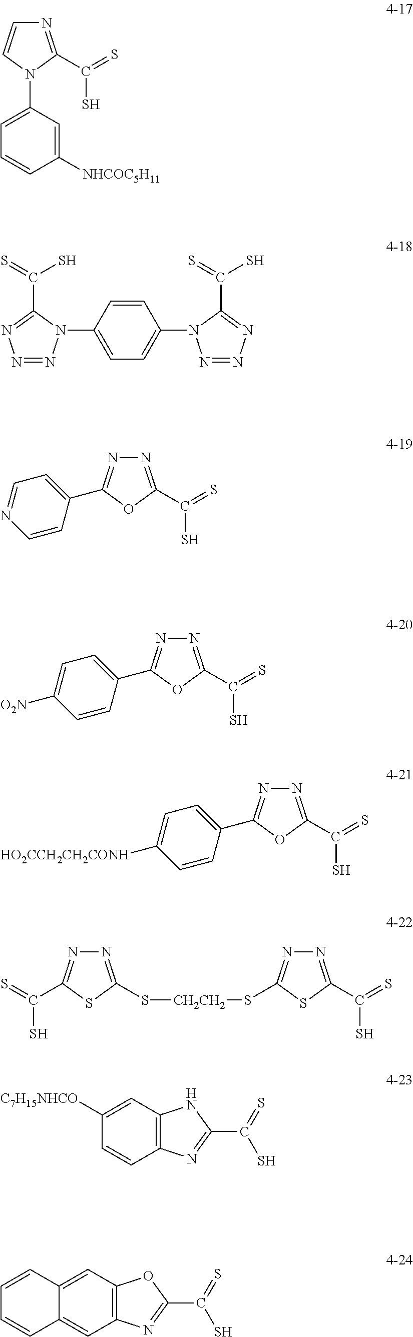

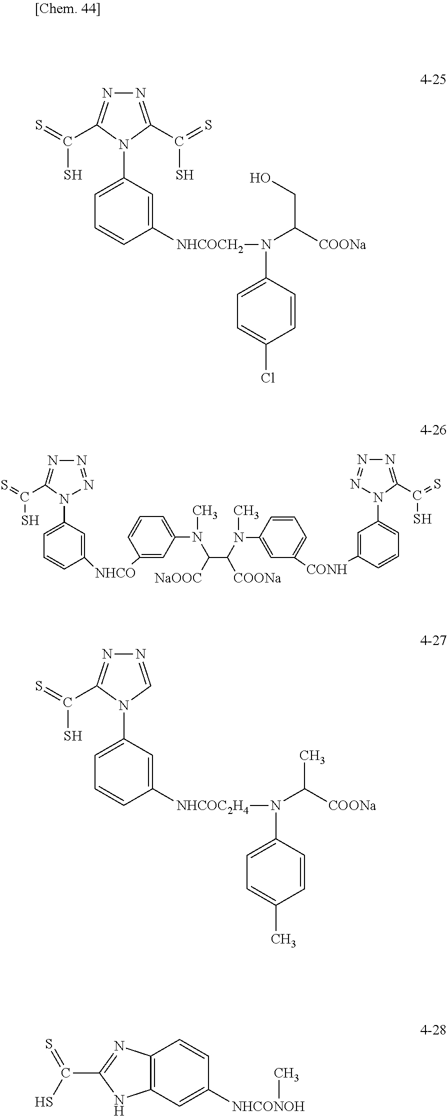

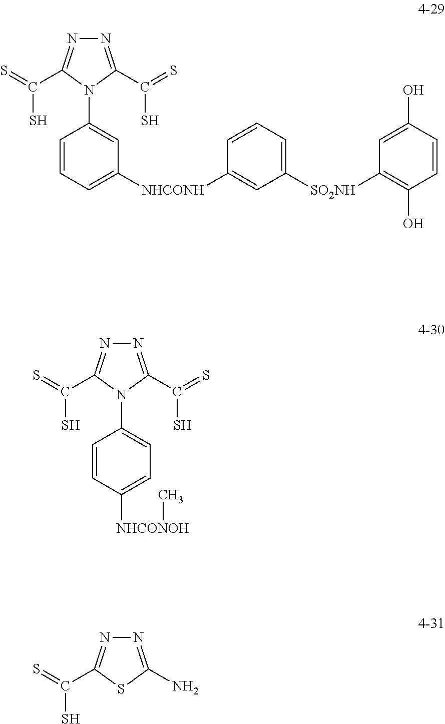

[Conductive Layer 1b]

The conductive layer 1b of the present invention is a layer containing silver as a main component and being formed on the intermediate layer 1a. Examples of a forming method of the conductive layer 1b include wet processes, such as application, the inkjet method, coating and dipping, and dry processes, such as vapor deposition (resistance heating, the EB method, etc.), sputtering and CVD. Among these, vapor deposition is used by preference.

By being formed on the intermediate layer 1a, the conductive layer 1b has sufficient conductivity without annealing at high temperature (for example, a heating process at 150° C. or more) after its formation, but, as needed, may be subjected to annealing at high temperature or the like after its formation.

The conductive layer 1b may be composed of an alloy containing silver (Ag). Examples of the alloy include silver and magnesium (Ag.Mg), silver and copper (Ag.Cu), silver and palladium (Ag.Pd), silver, palladium and copper (Ag.Pd.Cu), and silver and indium (Ag.In).

The content of silver needs to be 60 mass % or more, preferably 80 mass % or more, far preferably 90 mass % or more and particularly preferably 98 mass % or more.

The conductive layer 1b of the present invention may be configured, as needed, in such a way that a layer containing silver as a main component is divided into a plurality of layers and the layers are stacked.

It is preferable that the thickness of the conductive layer 1b be within a range from 5 nm to 20 nm and far preferably within a range from 5 nm to 8 nm. When the thickness is 20 nm or less, an absorbing component or a reflection component of the layer decreases and transmittance of the transparent electrode increases, which is far preferable, whereas when the thickness is 5 nm or more, conductivity of the layer is sufficient, which is preferable.

The transparent electrode 1 having a multilayer structure of the intermediate layer 1a and the conductive layer 1b formed on the upper side of the intermediate layer 1a may be configured in such a way that the conductive layer 1b has the upper side which is covered with a protective layer or on which another conductive layer is disposed. In this case, in order not to reduce optical transparency of the transparent electrode 1, it is preferable that the protective layer and the above mentioned another conductive layer have optical transparency.

On the lower side of the intermediate layer 1a, namely, between the intermediate layer 1a and the base 11, a layer may also be disposed as needed.

[Effects of Transparent Electrode 1]

As described above, the transparent electrode 1 of the present invention is configured in such a way that the conductive layer 1b containing silver as a main component is disposed on the intermediate layer 1a made with the organic compound containing a sulfur atom(s) having an unshared electron pair. With this structure, when the conductive layer 1b is formed on the upper side of the intermediate layer 1a, the silver atom(s) constituting the conductive layer 1b and the sulfur atom(s) having an unshared electron pair constituting the intermediate layer 1a react with each other, and diffusion distance of the silver atom(s) on the surface of the intermediate layer 1a decreases, whereby silver cohesion can be kept from occurring.

In general, in forming the conductive layer 1b composed of silver as a main component, thin-film growth is carried out in the nucleus growth mode (Volumer-Weber (VW) mode). Hence, silver particles are easily isolated in the shape of islands, and when the layer is thin, conductivity is difficult to obtain, and sheet resistance increases. Therefore, in order to ensure conductivity, the layer needs to be thick to a certain degree. However, when the layer is thick, the light transmittance decreases, which is improper as a transparent electrode.

However, according to the transparent electrode 1 having the structure defined by the present invention, as described above, cohesion of silver on the intermediate layer 1a is prevented. Hence, in forming the conductive layer 1b containing silver as a main component, thin-film growth is carried out in the single-layer growth mode (Frank-van der Merwe (FW) mode).

The “transparent” of the transparent electrode 1 of the present invention means that light transmittance at a wavelength of 550 nm is 50% or more. The above materials used for the intermediate layer 1a each have sufficient optical transparency, thereby forming an excellent layer having sufficient optical transparency, as compared with the conductive layer 1b composed of silver as a main component. Meanwhile, conductivity of the transparent electrode 1 is mainly ensured by the conductive layer 1b.

Therefore, as described above, with the conductive layer 1b containing silver as a main component being thinner and ensuring conductivity, high optical transparency, low sheet resistance and small sheet resistance variation in high temperature storage of the transparent electrode 1 can be achieved.

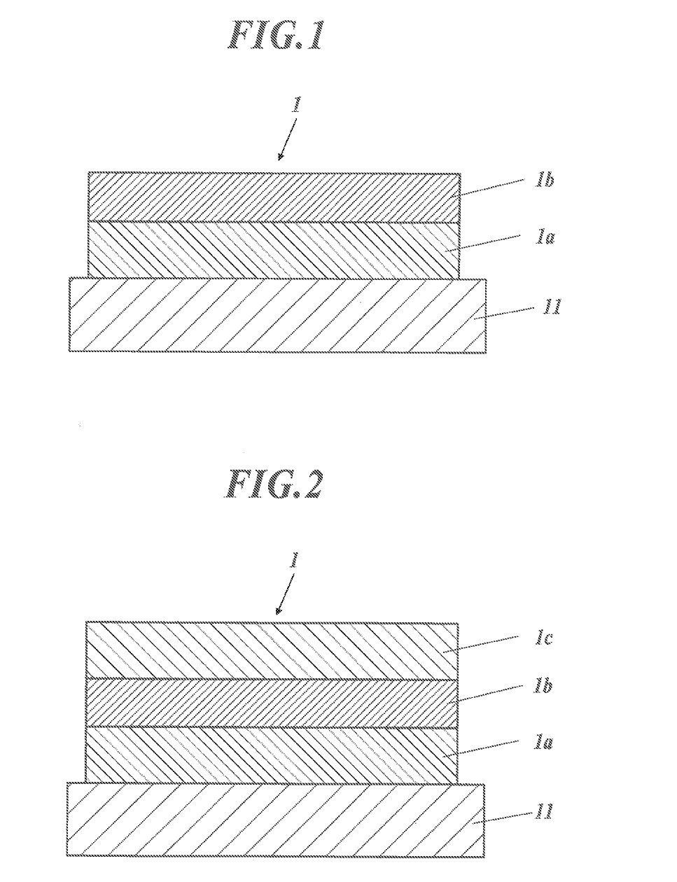

As shown in FIG. 2, the transparent electrode 1 may be configured in such a way that a second intermediate layer 1c is disposed on the upper side of the conductive layer 1b. This second intermediate layer 1c is a layer made with an organic compound containing a sulfur atom(s) having an unshared electron pair, which is the same as the organic compound of the intermediate layer 1a. With this structure in which the conductive layer 1b is interposed between the intermediate layer 1a and the second intermediate layer 1c, the silver atom(s) constituting the conductive layer 1b and the sulfur atom(s) having an unshared electron pair constituting the intermediate layer 1a and the second intermediate layer 1c react with each other, and diffusion distance of the silver atom(s) on the surfaces of the intermediate layer 1a and the second intermediate layer 1c decreases, whereby silver cohesion can be kept from occurring for sure. Consequently, there can be made a transparent electrode which ensures sufficient conductivity and has high optical transparency, low sheet resistance and small sheet resistance variation in high temperature storage.

<<2. Uses of Transparent Electrode>>

The transparent electrode 1, having the above structure, of the present invention can be used for various electronic devices. Examples of the electronic devices include an organic EL element, an LED (Light Emitting Diode), a liquid crystal element, a solar cell and a touch panel. As an electrode member which requires optical transparency in each of these electronic devices, the transparent electrode 1 of the present invention can be used.

Hereinafter, as an example of the uses, embodiments of organic EL elements each using the transparent electrode are described.

<<3. First Embodiment of Organic EL Element>>

[Structure of Organic EL Element 100]

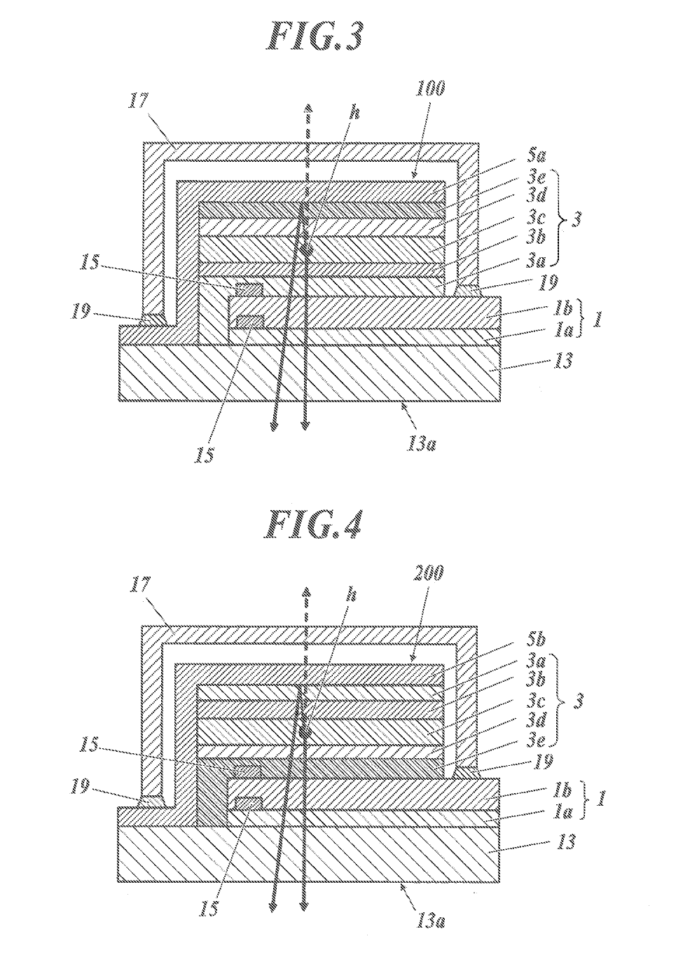

FIG. 3 is a cross sectional view showing the structure of a first embodiment of an organic EL element provided with the transparent electrode 1 of the present invention as an example of an electronic device of the present invention. Hereinafter, the structure of the organic EL element is described with reference to FIG. 3.

An organic EL element 100 shown in FIG. 3 is disposed on a transparent substrate (base) 13 and is configured in such a way that a transparent electrode 1, a light-emitting functional layer 3 made with an organic material and the like and a counter electrode 5a are stacked on the transparent substrate 13 in the order named. In the organic EL element 100, as the transparent electrode 1, the above described transparent electrode 1 of the present invention is used. Hence, the organic EL element 100 is configured to extract the generated light (hereinafter “emission light h”) at least from the transparent substrate 13 side.

Hereinafter, the layer structure of the organic EL element 100 is described, but the layer structure thereof is not limited to the illustrated structure example and may be a general layer structure. In the structure shown in FIG. 3, the transparent electrode 1 functions as an anode (i.e., a positive pole), and the counter electrode 5a functions as a cathode (i.e., a negative pole). For this case, the light-emitting functional layer 3 has a layer structure of, for example, a positive hole injection layer 3a, a positive hole transport layer 3b, a luminescent layer 3c, an electron transport layer 3d and an electron injection layer 3e stacked on the transparent electrode 1 as an anode in the order named as shown in FIG. 3. It is essential for the light-emitting functional layer 3 to have, among them, at least the luminescent layer 3c made with an organic material.

The positive hole injection layer 3a and the positive hole transport layer 3b may be provided as a positive hole transport•injection layer.

The electron transport layer 3d and the electron injection layer 3e may be provided as an electron transport•injection layer.

Further, of the light-emitting functional layer 3, for example, the electron injection layer 3e may be composed of an inorganic material.

In the light-emitting functional layer 3, in addition to these illustrated constituent layers, a positive hole block layer, an electron block layer and the like may be disposed at their needed positions as needed. Further, the luminescent layer 3c may have a plurality of luminescent layers for different colors, the luminescent layers generating emission light of respective wavelength ranges, and may have a multilayer structure of these luminescent layers stacked with a non-luminescent intermediate layer(s) in between.

The intermediate layer(s) may double as a positive hole block layer and an electron block layer. Further, the counter electrode 5a as a cathode may also have a multilayer structure as needed. In the structure described above, only the portion where the light-emitting functional layer 3 is interposed between the transparent electrode 1 and the counter electrode 5a is a luminescent region in the organic EL element 100.

In the above described layer structure, in order to reduce resistance of the transparent electrode 1, an auxiliary electrode 15 may be disposed in contact with the conductive layer 1b of the transparent electrode 1.

The organic EL element 100 thus configured is sealed with a sealing member 17, which is described below, on the transparent substrate 13 in order to prevent deterioration of the light-emitting functional layer 3 made with an organic material and the like.

The sealing member 17 is fixed to the transparent substrate 13 side with an adhesive 19. Terminal portions of the transparent electrode 1 and the counter electrode 5a are disposed in such a way as to be exposed from the sealing member 17 while being insulated from each other by the light-emitting functional layer 3 on the transparent substrate 13.

Hereinafter, the main layers of the organic EL element 100 shown in FIG. 3 are detailed in the following order; the transparent substrate 13, the transparent electrode 1, the counter electrode 5a, the luminescent layer 3c of the light-emitting functional layer 3, other layers of the light-emitting functional layer 3, the auxiliary electrode 15 and the sealing member 17. Thereafter, a production method of the organic EL element 100 is described.

(Transparent Substrate 13)

The transparent substrate 13 is the above described base 11 on which the transparent electrode 1 of the present invention is disposed, and of the above described base 11, the base 11 which is transparent and has optical transparency is used therefor.

(Transparent Electrode 1)

The transparent electrode 1 (anode or positive pole) is the above described transparent electrode 1 of the present invention and configured in such a way that the intermediate layer 1a and the conductive layer 1b are formed on the transparent substrate 13 in the order named. Especially in the embodiment, the transparent electrode 1 functions as an anode (positive pole), and the conductive layer 1b is the substantial anode.

(Counter Electrode 5a)

The counter electrode 5a (cathode or negative pole) is an electrode layer which functions as a cathode (negative pole) for supplying electrons to the light-emitting functional layer 3 and is composed of, for example, a metal, an alloy, an organic conductive compound, an inorganic conductive compound or a mixture of any of these.

Examples thereof include: aluminum; silver; magnesium; lithium; magnesium/copper mixture; magnesium/silver mixture; magnesium/aluminum mixture; magnesium/indium mixture; indium; lithium/aluminum mixture; rare-earth metal; and oxide semiconductors, such as ITO, ZnO, TiO₂ and SnO₂.

The counter electrode 5a can be produced by forming a thin film of any of the above mentioned conductive materials by vapor deposition, sputtering or another method. It is preferable that the sheet resistance of the counter electrode 5a be several hundred Ω/□ or less. The thickness is selected from normally a range of 5 nm to 5 μm, preferably a range of 5 nm to 200 nm.

In the case where the organic EL element 100 is configured to extract emission light h from the counter electrode 5a side too, the counter electrode 5a should be composed of a conductive material having excellent optical transparency selected from the above mentioned conductive materials.

(Luminescent Layer 3c)

The luminescent layer 3c used in the present invention contains a luminescent material, preferably a phosphorescent compound as the luminescent material.

The luminescent layer 3c is a layer which emits light through rebinding of electrons injected from the electrode or the electron transport layer 3d and positive holes injected from the positive hole transport layer 3b. A portion to emit light may be either inside of the luminescent layer 3c or an interface between the luminescent layer 3c and its adjacent layer.

The structure of the luminescent layer 3c is not particularly limited as long as the luminescent material contained therein satisfies a light emission requirement. Further, the luminescent layer 3c may be composed of a plurality of layers having the same emission spectrum and/or maximum emission wavelength. In this case, it is preferable that non-luminescent auxiliary layers be present between the luminescent layers 3c.

The total thickness of the luminescent layer(s) 3c is preferably within a range from 1 nm to 100 nm and, in order to obtain a lower driving voltage, far preferably within a range from 1 nm to 30 nm. The total thickness of the luminescent layer(s) 3c is, if the non-luminescent auxiliary layers are present between the luminescent layers 3c, the thickness including the thickness of the auxiliary layers.

In the case where the luminescent layer 3c has a multilayer structure of a plurality of layers stacked, it is preferable to adjust the thickness of each luminescent layer to be within a range from 1 nm to 50 nm and far preferable to adjust the thickness thereof to be within a range from 1 nm to 20 nm. In the case where the stacked luminescent layers are for respective luminescent colors of blue, green and red, a relationship between the thickness of the luminescent layer for blue, the thickness of the luminescent layer for green and the thickness of the luminescent layer for red is not particularly limited.

The luminescent layer 3c thus configured can be formed by forming a thin film of a luminescent material and a host compound, which are described below, by a well-known thin-film forming method such as vacuum deposition, spin coating, casting, the LB method or the inkjet method.

The luminescent layer 3c may be composed of a plurality of luminescent materials mixed or a phosphorescent material and a fluorescent material (hereinafter may be referred to as a fluorescent dopant or a fluorescent compound) mixed.

It is preferable that the luminescent layer 3c contain a host compound (also called a luminescent host or the like) and a luminescent material (also called a luminescent dopant compound or a dopant compound) and emit light from the luminescent material.

<Host Compound>

The host compound contained in the luminescent layer 3c is a compound exhibiting, in phosphorescence emission at room temperature (25° C.), preferably a phosphorescence quantum yield of less than 0.1 and far preferably a phosphorescence quantum yield of less than 0.01. Further, of the compounds contained in the luminescent layer 3c, a volume percentage of the host compound in the layer being 50% or more is preferable.

As the host compound, one type of well-known host compounds may be used alone, or multiple types thereof may be used together. Use of multiple types of host compounds enables adjustment of transfer of charges, thereby increasing efficiency of the organic EL element. Further, use of multiple types of luminescent materials described below enables mixture of emission light of different colors, thereby producing any luminescent color.

The host compound to be used may be a well-known low molecular weight compound, a high polymer having a repeating unit or a low molecular weight compound (a vapor deposition polymerizable luminescent host) having a polymerizable group such as a vinyl group or an epoxy group.

Of the well-known host compounds, a compound which has a positive hole transport property and an electron transport property, prevents red shift and has a high Tg (glass transition temperature) is preferable.

The glass transition temperature (Tg) here is a value obtained using DSC (Differential Scanning Colorimetry) by a method in conformity with JIS-K-7121.

Specific examples (H1 to H79) of the host compound usable in the present invention are shown below, but the host compound is not limited thereto. In the host compound H68, x and y represent a ratio in a random copolymer, and in the host compound H69, p, q and r represent a ratio in a random copolymer. The ratio can be x:y=1:10, for example.

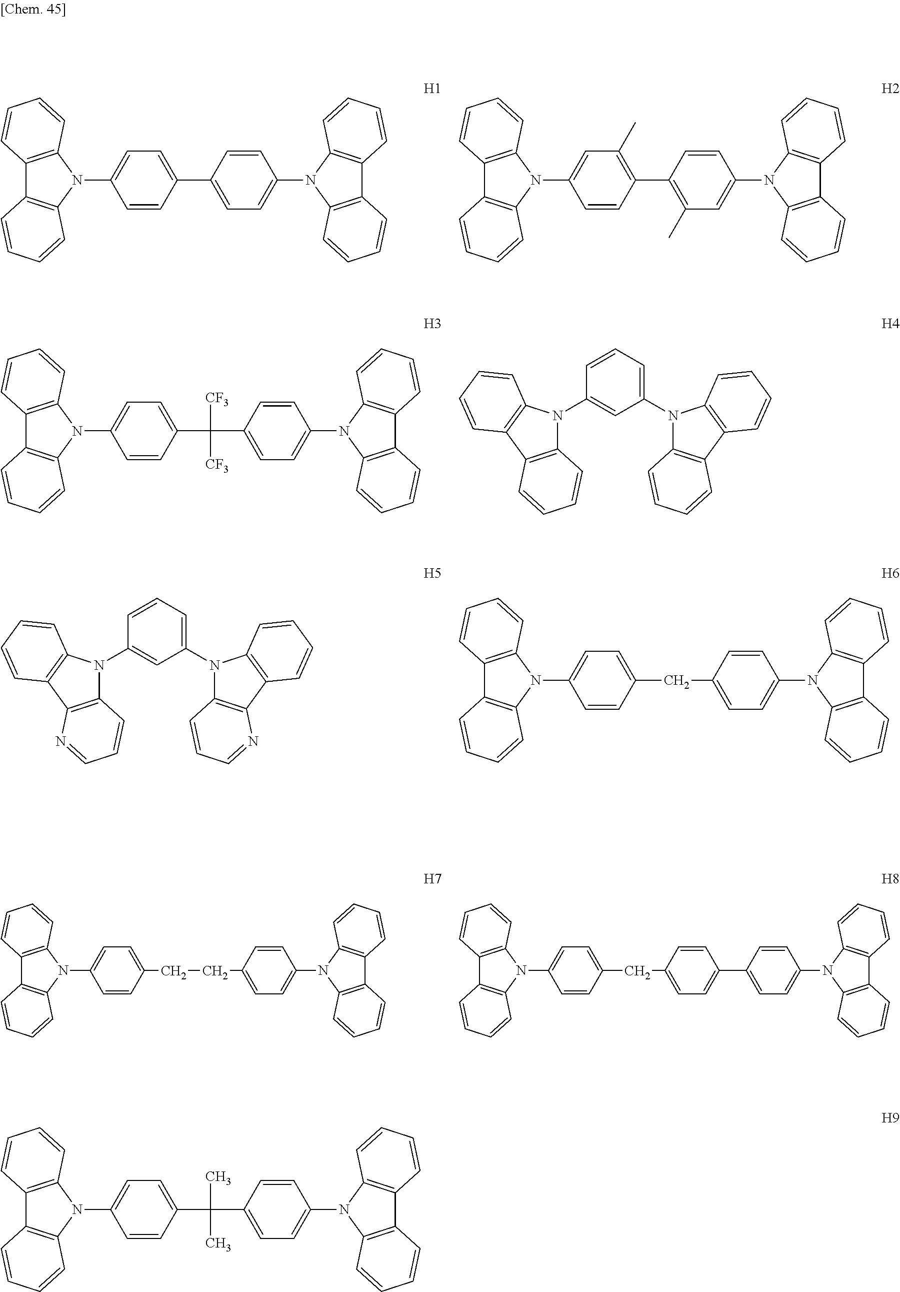

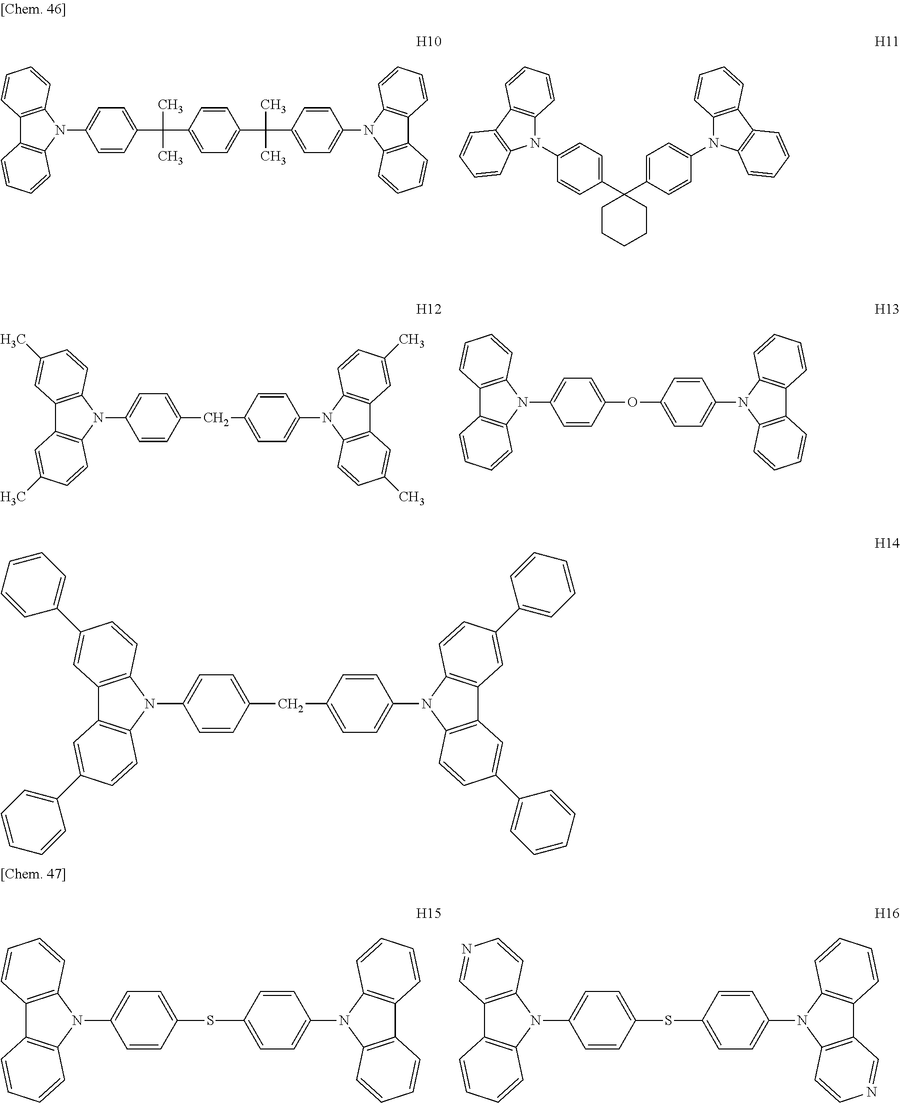

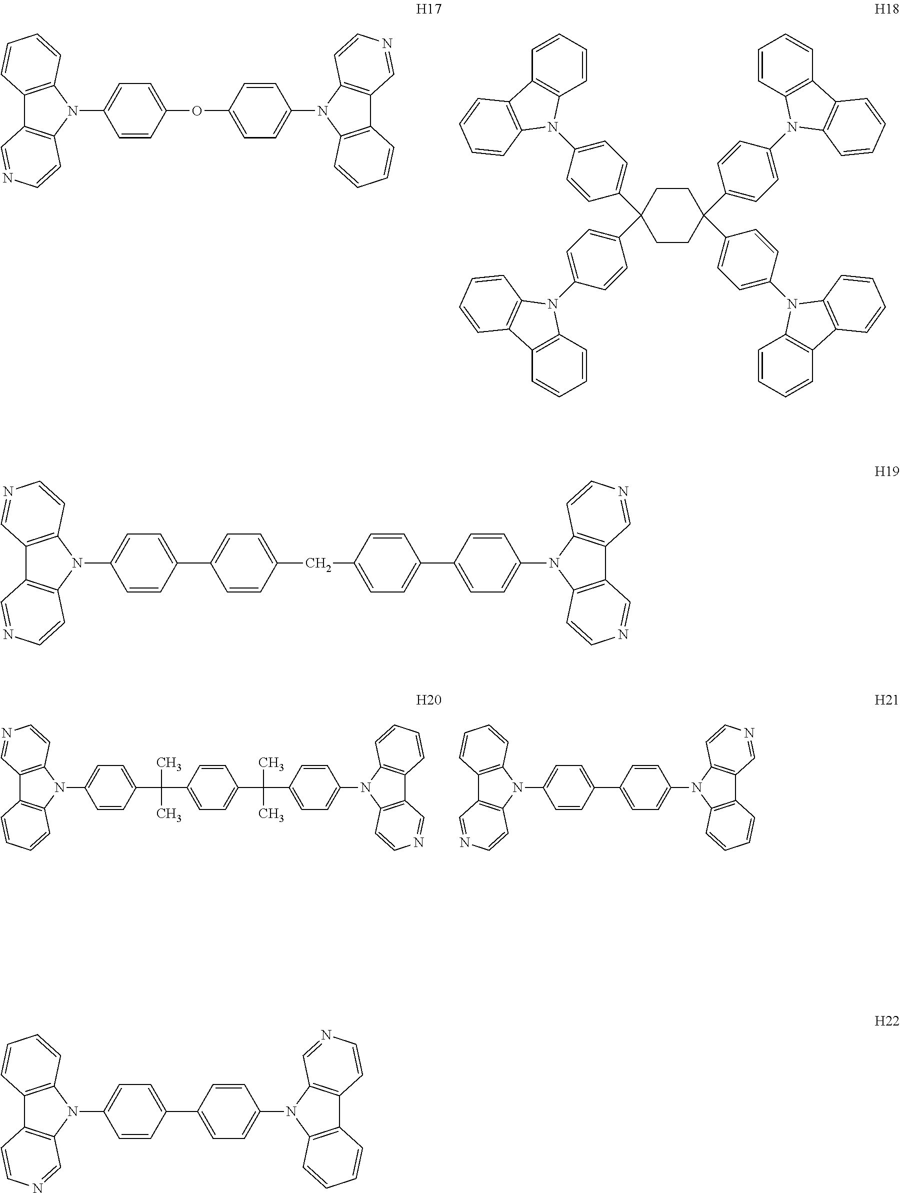

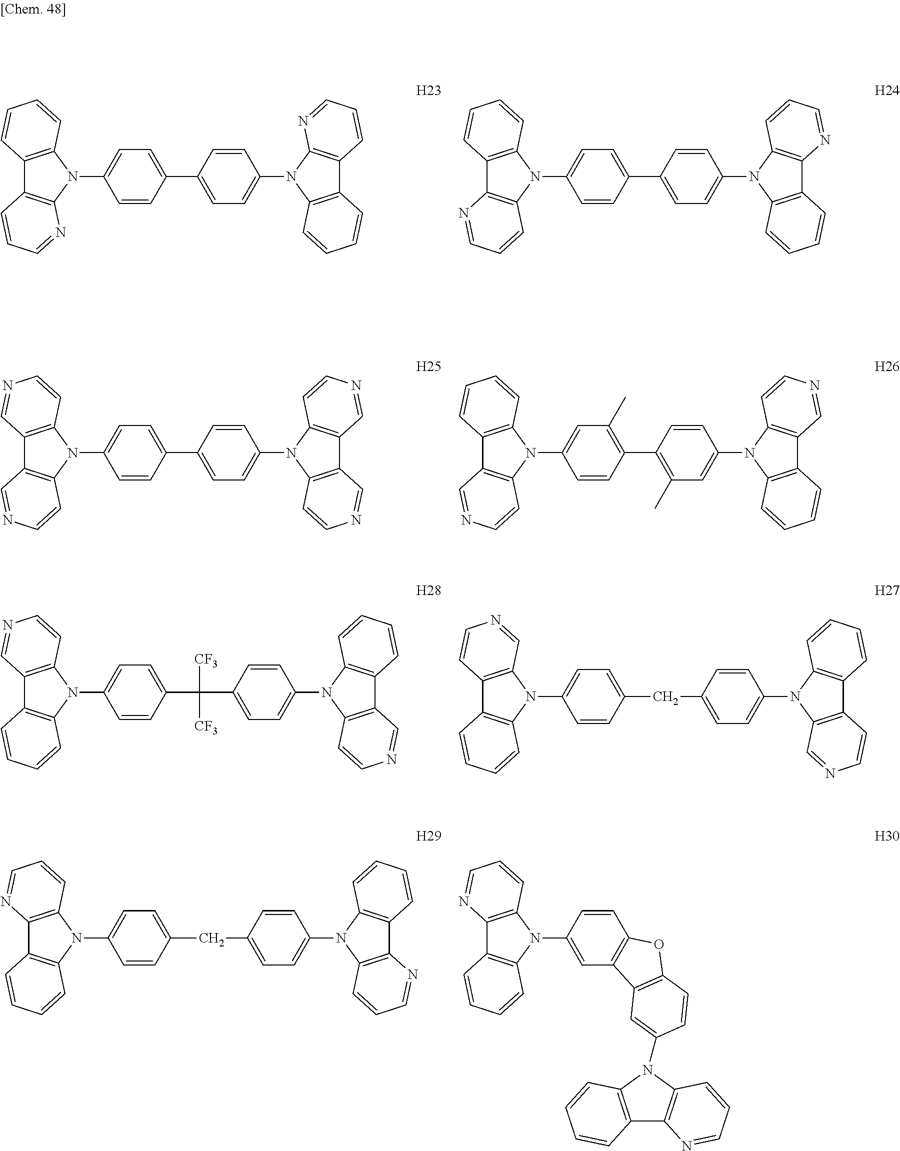

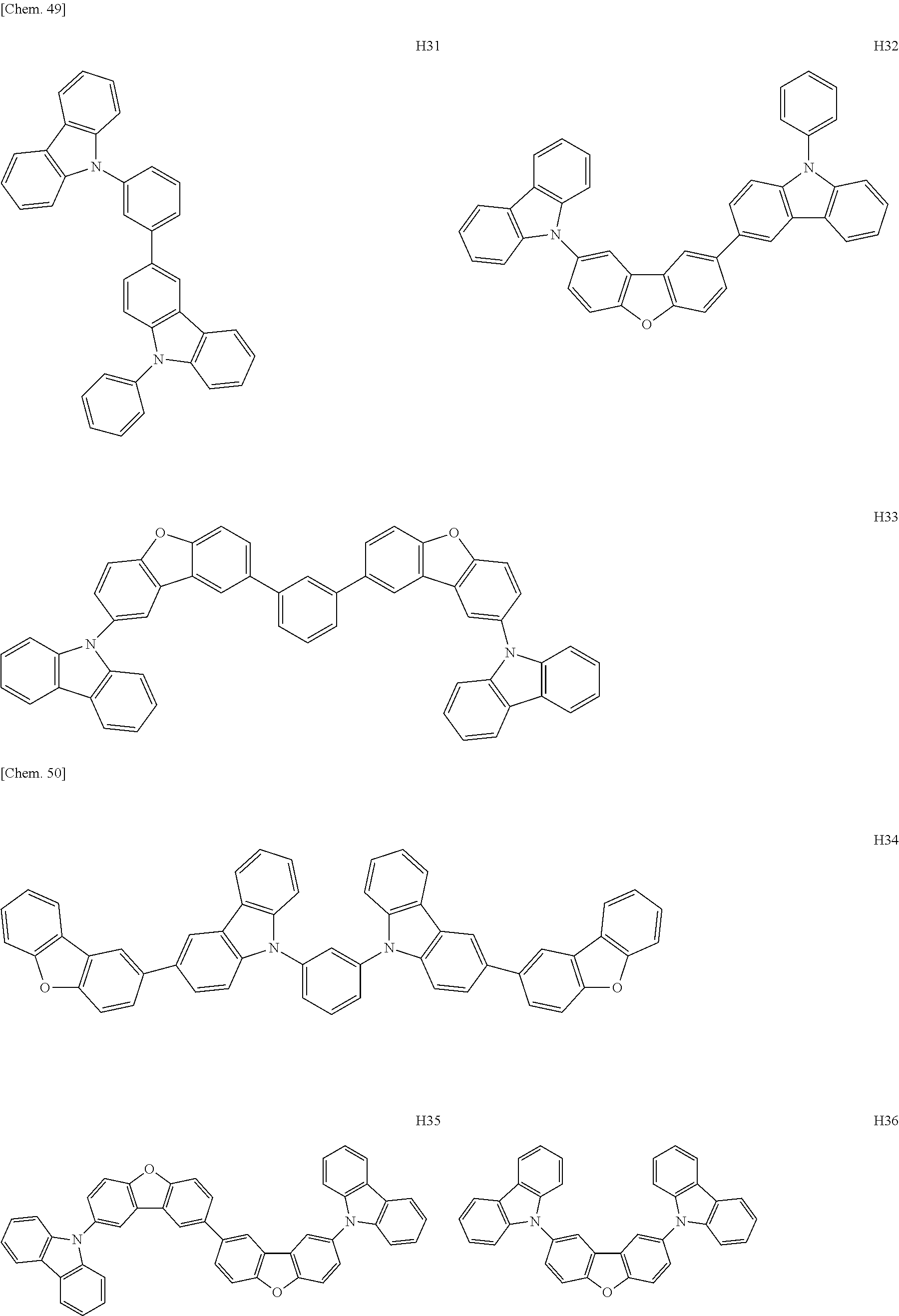

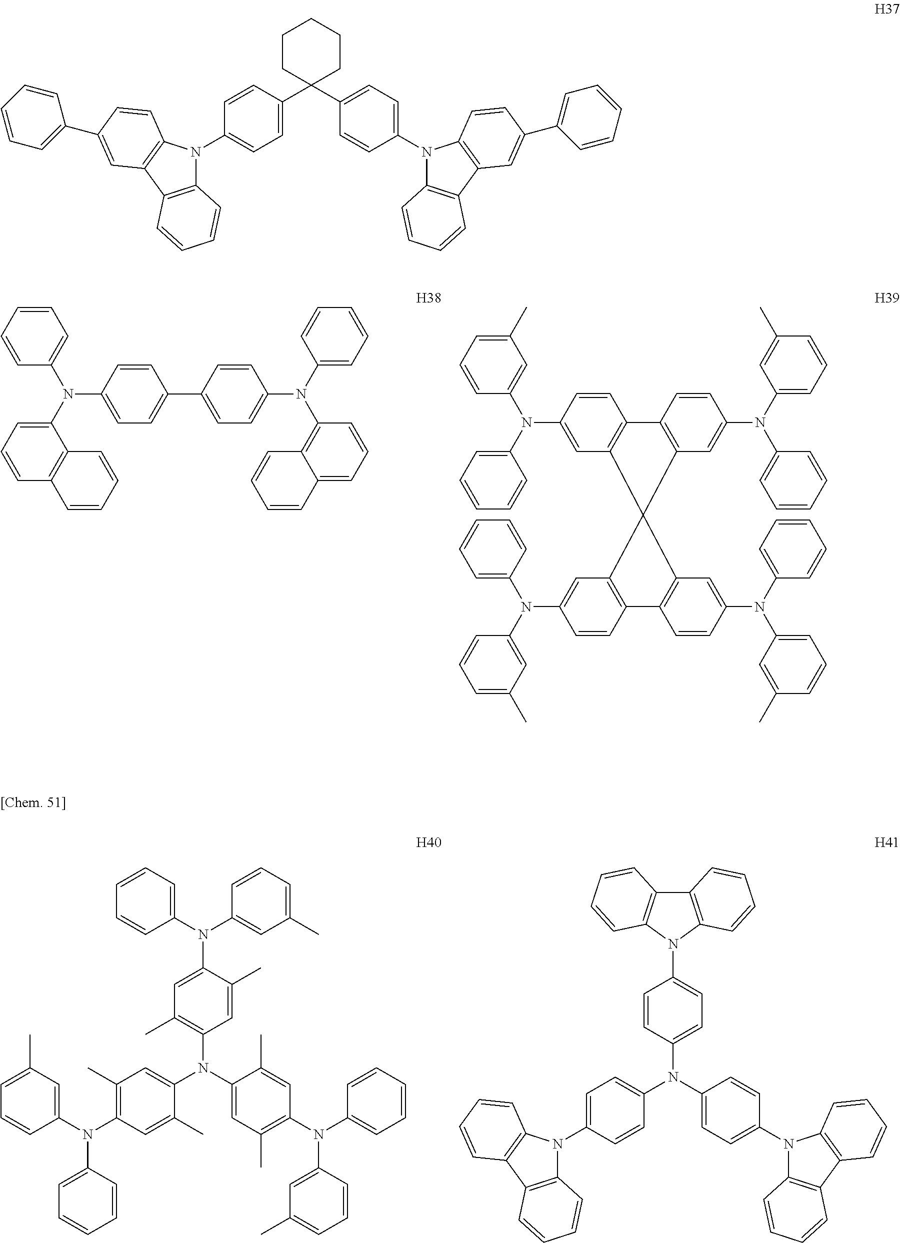

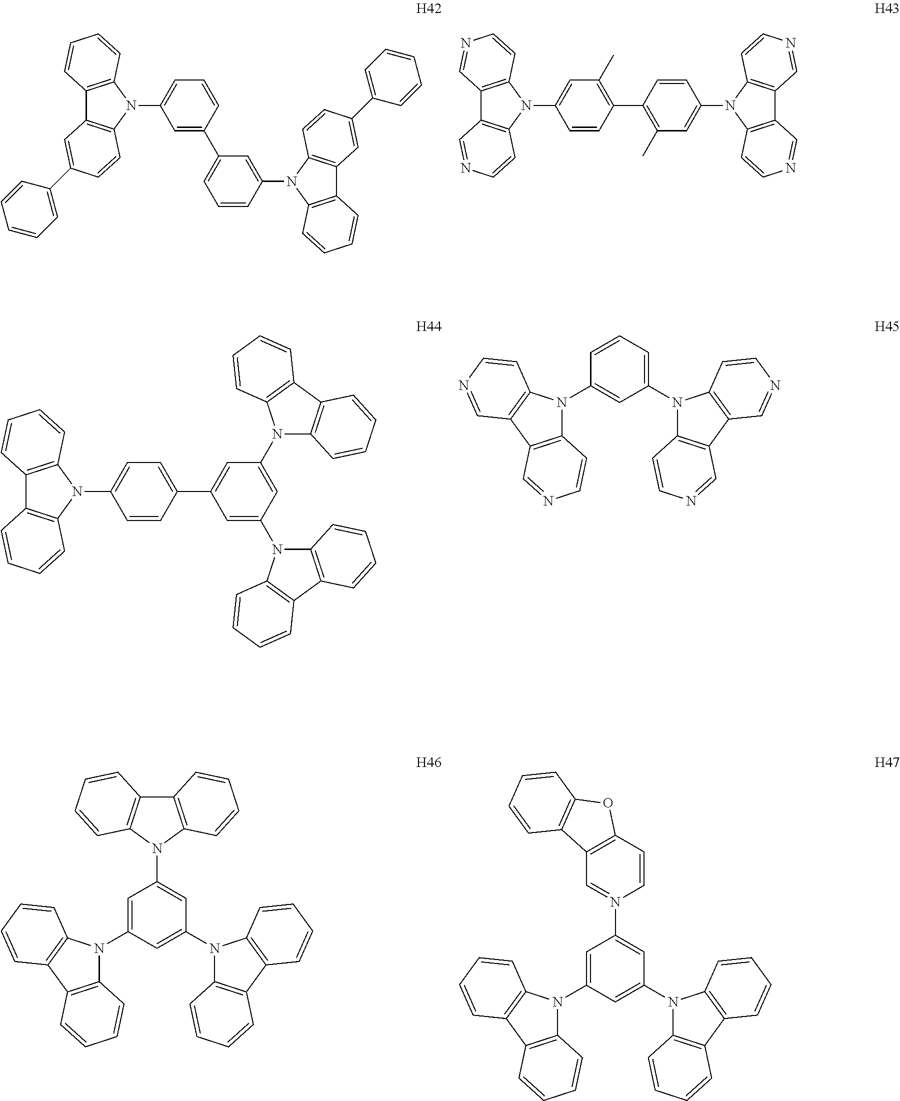

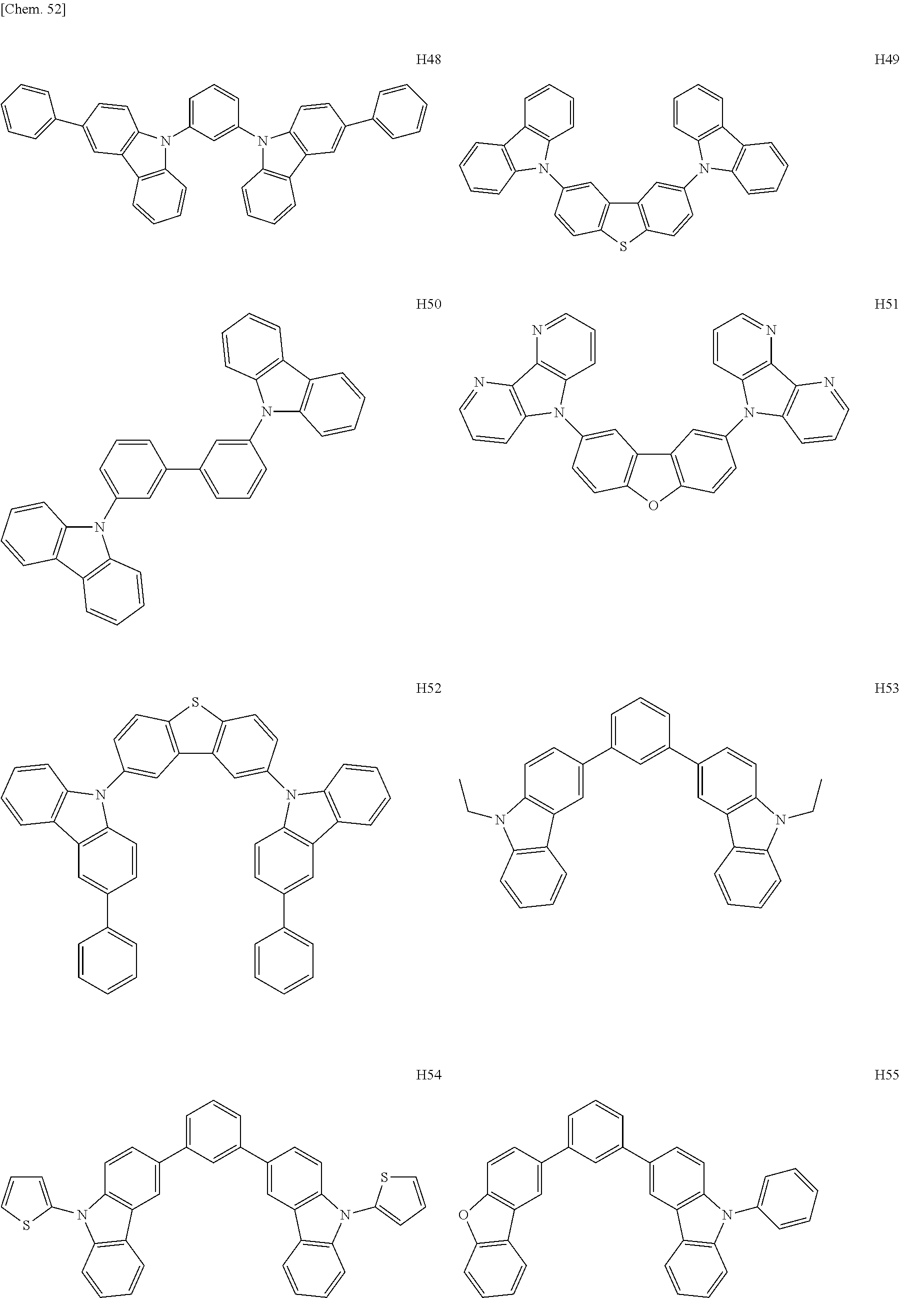

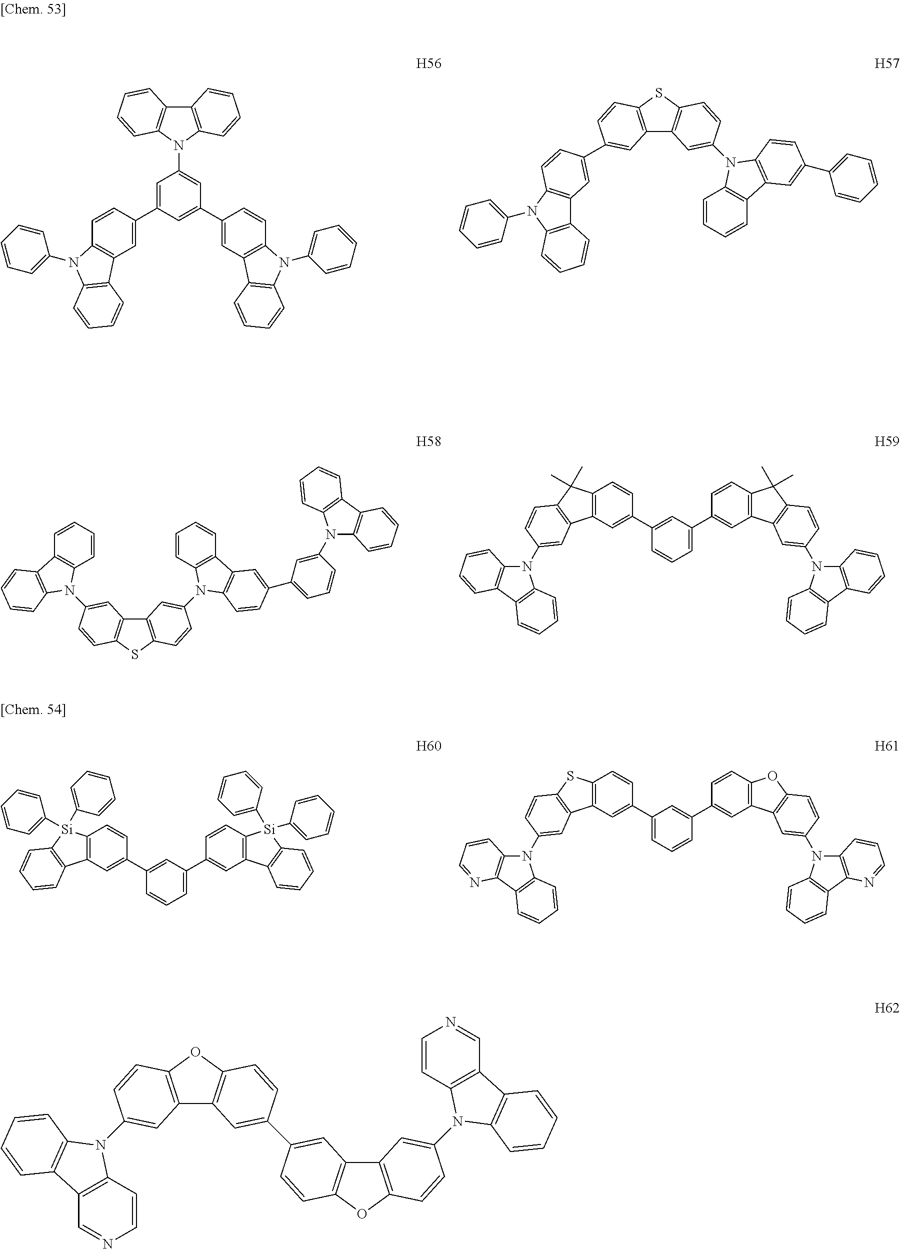

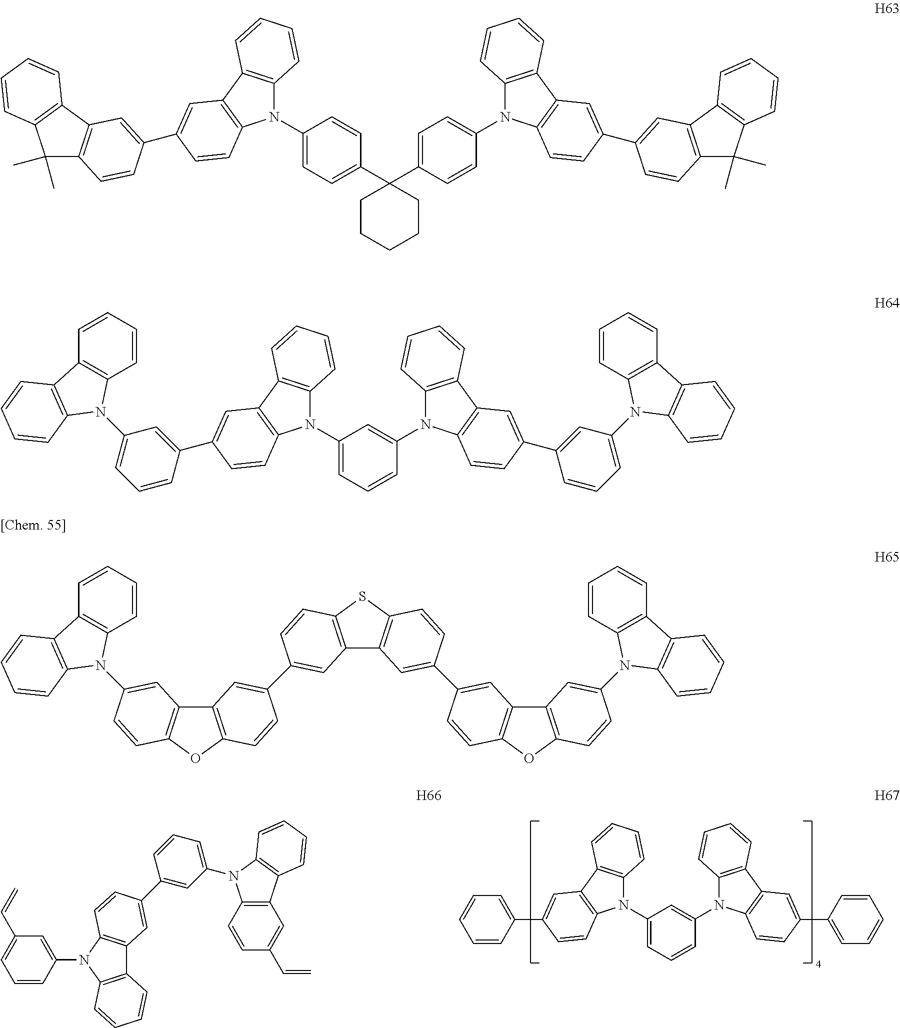

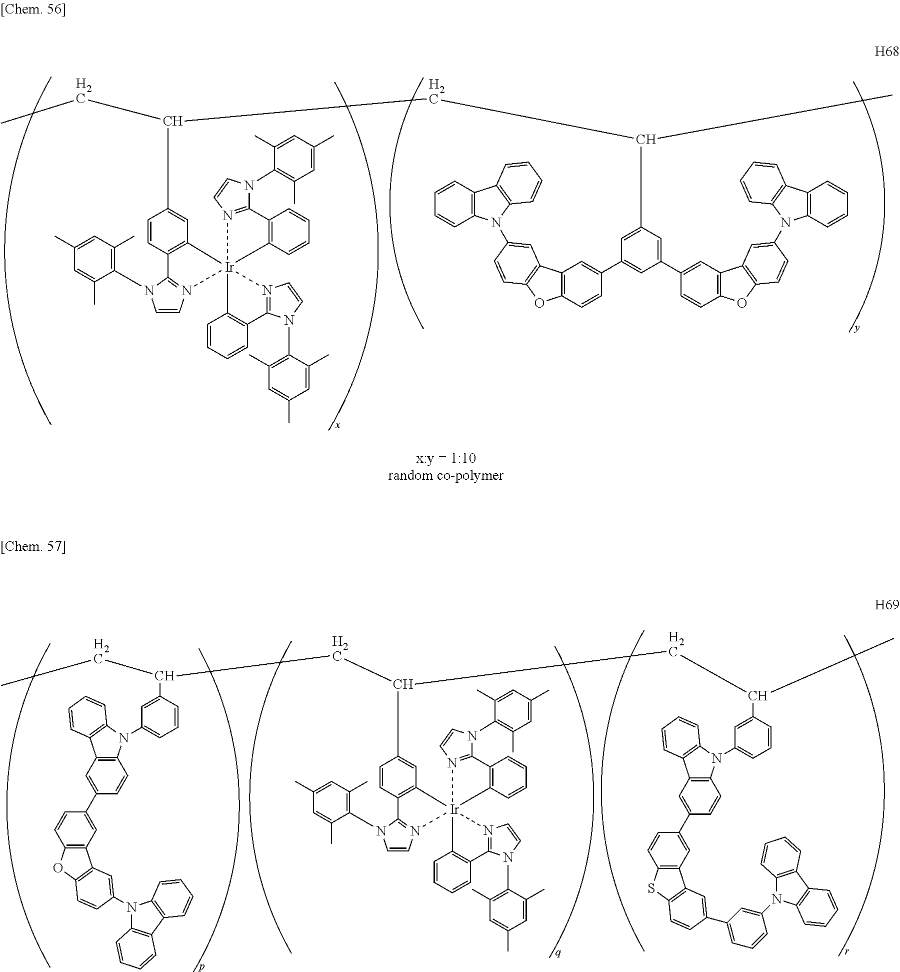

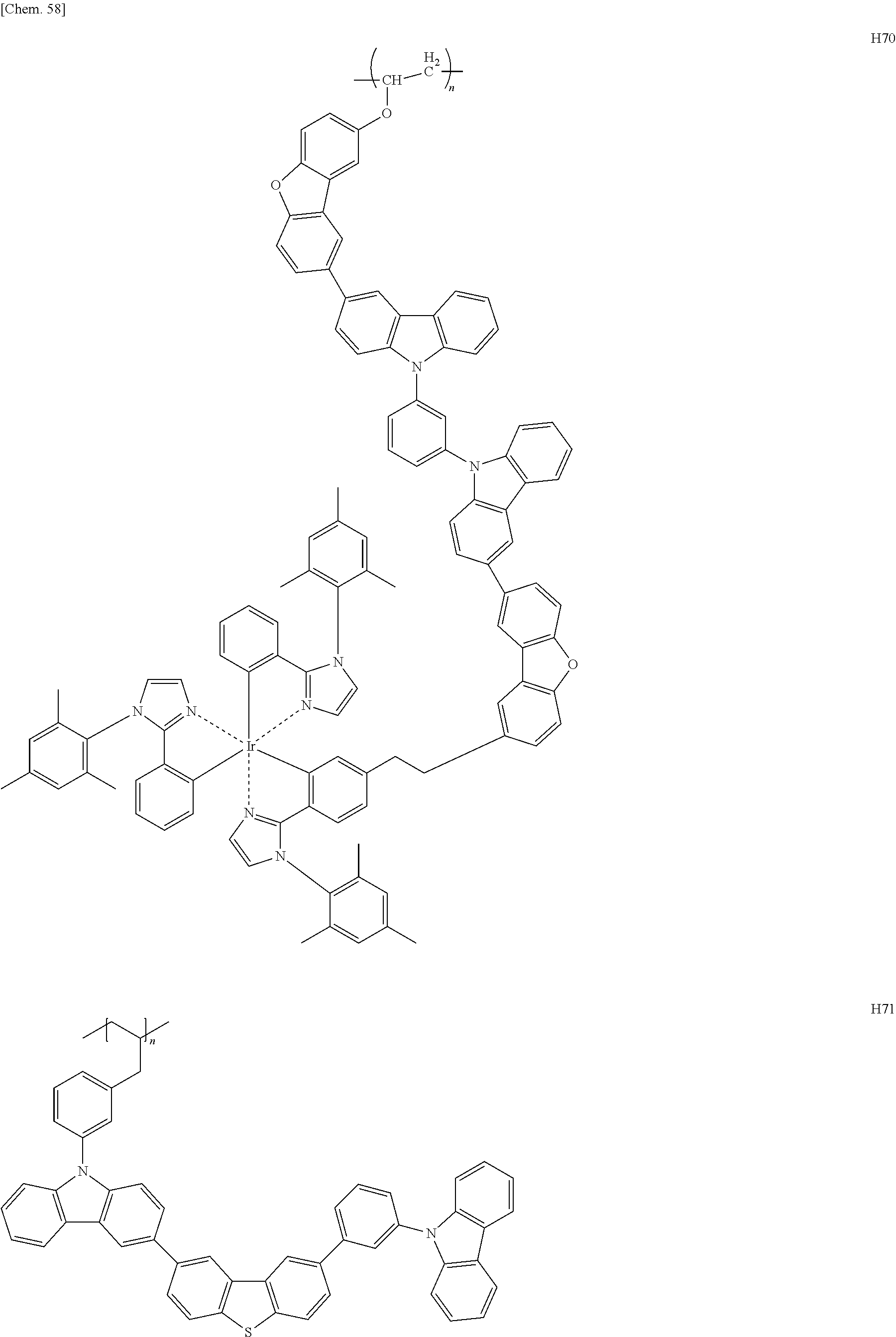

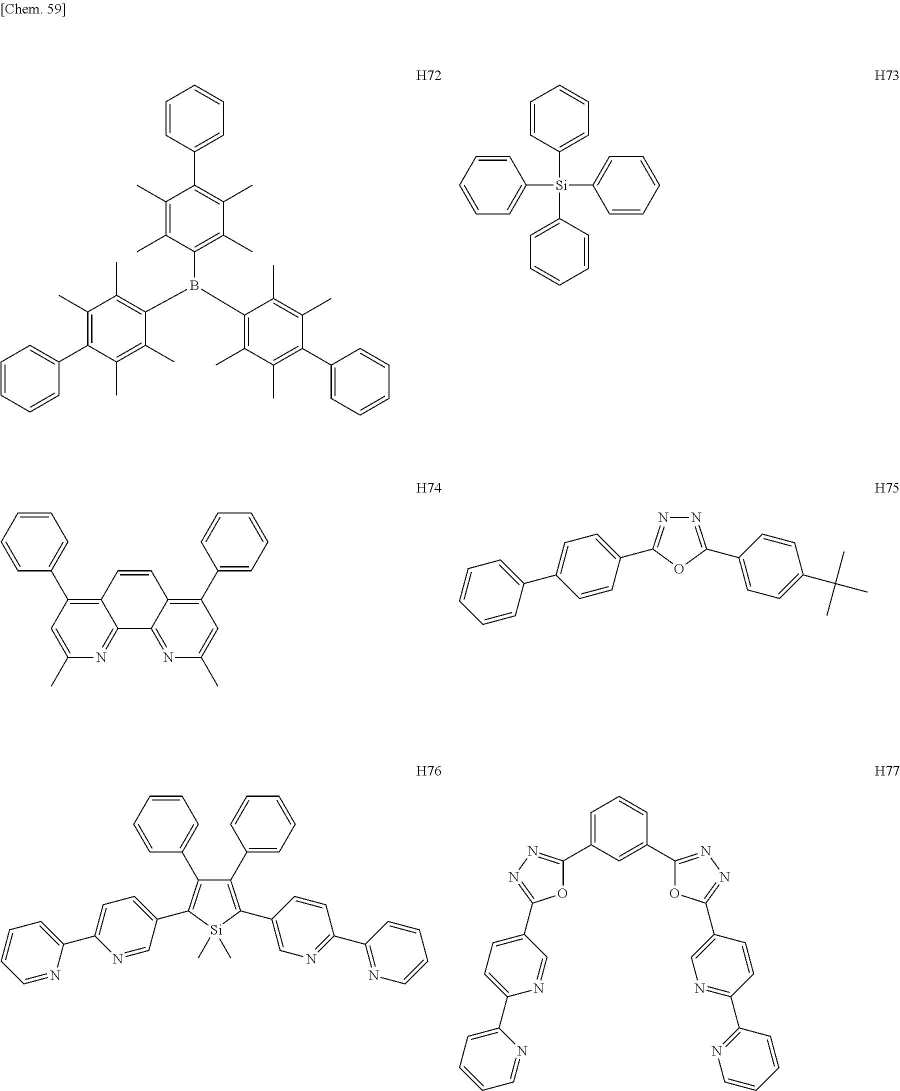 [SMILES: Cc1c(C)c(-c2ccccc2)c(C)c(C)c1B(c1c(C)c(C)c(-c2ccccc2)c(C)c1C)c1c(C)c(C)c(-c2ccccc2)c(C)c1C ; c1ccc([Si](c2ccccc2)(c2ccccc2)c2ccccc2)cc1 ; Cc1cc(-c2ccccc2)c2ccc3c(-c4ccccc4)cc(C)nc3c2n1 ; CC(C)(C)c1ccc(-c2nnc(-c3ccc(-c4ccccc4)cc3)o2)cc1 ; C[Si]1(C)C(c2ccc(-c3ccccn3)nc2)=C(c2ccccc2)C(c2ccccc2)=C1c1ccc(-c2ccccn2)nc1 ; c1ccc(-c2ccc(-c3nnc(-c4cccc(-c5nnc(-c6ccc(-c7ccccn7)nc6)o5)c4)o3)cn2)nc1]

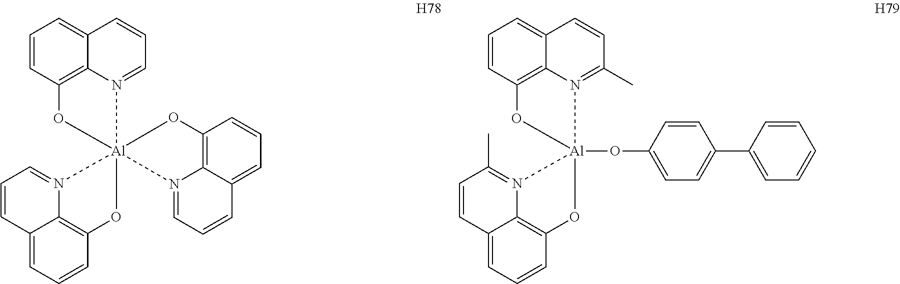

As the specific examples of the well-known host compounds, compounds mentioned in the following documents are included; for example, Japanese Patent Application Publication Nos. 2001-257076, 2002-308855, 2001-313179, 2002-319491, 2001-357977, 2002-334786, 2002-8860, 2002-334787, 2002-15871, 2002-334788, 2002-43056, 2002-334789, 2002-75645, 2002-338579, 2002-105445, 2002-343568, 2002-141173, 2002-352957, 2002-203683, 2002-363227, 2002-231453, 2003-3165, 2002-234888, 2003-27048, 2002-255934, 2002-260861, 2002-280183, 2002-299060, 2002-302516, 2002-305083, 2002-305084 and 2002-308837.

<Luminescent Material>

Examples of the luminescent material (also called a luminescent dopant compound or a dopant compound) usable in the present invention include a phosphorescent compound (also called a phosphorescent material or the like).

The phosphorescent compound is a compound in which light emission from an excited triplet state is observed, and, to be more specific, a compound which emits phosphorescence at room temperature (25° C.) and exhibits at 25° C. a phosphorescence quantum yield of 0.01 or more, preferably a phosphorescence quantum yield of 0.1 or more.

The phosphorescence quantum yield can be measured by a method mentioned on page 398 of Bunko II of Dai 4 Han Jikken Kagaku Koza 7 (Spectroscopy II of Lecture of Experimental Chemistry vol. 7, 4^{th} edition) (1992, published by Maruzen Co., Ltd.).

The phosphorescence quantum yield in a solution can be measured by using various solvents. With respect to the phosphorescent compound used in the present invention, it is only necessary to achieve the above mentioned phosphorescence quantum yield of 0.01 or more with one of appropriate solvents.

As principles regarding light emission of the phosphorescent compound, two methods are cited. One method is an energy transfer type, wherein carriers rebind on a host compound to which the carriers are transferred so as to produce an excited state of the host compound, this energy is transferred to a phosphorescent compound, and hence light emission from the phosphorescent compound is carried out.

The other method is a carrier trap type, wherein a phosphorescent compound serves as a carrier trap, carriers rebind on the phosphorescent compound, and hence light emission from the phosphorescent compound is carried out.

In either case, the excited state energy of the phosphorescent compound is required to be lower than that of the host compound.

The phosphorescent compound to be used can be suitably selected from well-known phosphorescent compounds used for luminescent layers of general organic EL elements, preferably a complex compound containing a metal of Groups 8 to 10 in the element periodic table; far preferably an iridium compound, an osmium compound, a platinum compound (a platinum complex compound) or a rare-earth complex; and most preferably an iridium compound.

In the present invention, at least one luminescent layer 3c may contain two or more types of phosphorescent compounds, and a concentration ratio of the phosphorescent compounds in the luminescent layer 3c may be various in a direction of the thickness of the luminescent layer 3c.

It is preferable that the phosphorescent compound(s) in the total amount of the luminescent layer (s) 3c be within a range from 0.1 vol % to 30 vol %.

<Compound Represented by General Formula (A)>

It is preferable that the luminescent layer 3c of the present invention contain a compound represented by the following General Formula (A) as the phosphorescent compound.

It is preferable that the phosphorescent compound (also called a phosphorescent metal complex) represented by the following General Formula (A) be contained in the luminescent layer 3c of the organic EL element 100 as a luminescent dopant, but the compound may be contained in a layer of the light-emitting functional layer other than the luminescent layer 3c.

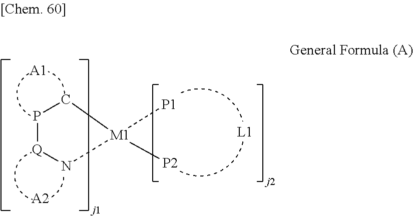

In the above General Formula (A), P and Q each represent a carbon atom or a nitrogen atom, and A₁ represents an atomic group which forms an aromatic hydrocarbon ring or an aromatic heterocyclic ring with P—C.

A₂ represents an atomic group which forms an aromatic heterocyclic ring with Q-N.

P₁-L₁-P₂ represents a bidentate ligand, and P₁ and P₂ each independently represent a carbon atom, a nitrogen atom or an oxygen atom.

L1 represents an atomic group which forms the bidentate ligand with P₁ and P₂.

j1 represents an integer of one to three, and j2 represents an integer of zero to two, provided that the sum of j1 and j2 is two or three.

M₁ represents a transition metal element of Groups 8 to 10 in the element periodic table.

In General Formula (A), P and Q each represent a carbon atom or a nitrogen atom.

Examples of the aromatic hydrocarbon ring which is formed by A₁ with P—C in General Formula (A) include a benzene ring, a biphenyl ring, a naphthalene ring, an azulene ring, an anthracene ring, a phenanthrene ring, a pyrene ring, a chrysene ring, a naphthacene ring, a triphenylene ring, an o-terphenyl ring, an m-terphenyl ring, a p-terphenyl ring, an acenaphthene ring, a coronene ring, a fluorene ring, a fluoranthrene ring, a naphthacene ring, a pentacene ring, a perylene ring, a pentaphene ring, a picene ring, a pyrene ring, a pyranthrene ring and an anthranthrene ring.

These rings may each have a substituent, and examples of the substituent include: an alkyl group (a methyl group, an ethyl group, a propyl group, an isopropyl group, a tert-butyl group, a pentyl group, a hexyl group, an octyl group, a dodecyl group, a tridecyl group, a tetradecyl group, a pentadecyl group, etc.); a cycloalkyl group (a cyclopentyl group, a cyclohexyl group, etc.); an alkenyl group (a vinyl group, an allyl group, etc); an alkynyl group (an ethynyl group, a propargyl group, etc.); an aromatic hydrocarbon group (also called an aromatic carbocyclic group, an aryl group or the like; a phenyl group, a p-chlorophenyl group, a mesityl group, a tolyl group, a xylyl group, a naphthyl group, an anthryl group, an azulenyl group, an acenaphthenyl group, a fluorenyl group, a phenanthryl group, an indenyl group, a pyrenyl group, a biphenyryl group, etc.); an aromatic heterocyclic group (a furyl group, a thienyl group, a pyridyl group, a pyridazinyl group, a pyrimidinyl group, a pyrazinyl group, a triazinyl group, an imidazolyl group, a pyrazolyl group, a thiazolyl group, a quinazolinyl group, a carbazolyl group, a carbolinyl group, a diazacarbazolyl group (indicating a group formed in such a way that one of carbon atoms constituting a carboline ring of a carbolinyl group is substituted by a nitrogen atom), a phtharazinyl group, etc.); a heterocyclic group (a pyrrolidyl group, an imidazolidyl group, a morpholyl group, an oxazolidyl group, etc.); an alkoxy group (a methoxy group, an ethoxy group, a propyloxy group, a pentyloxy group, a hexyloxy group, an octyloxy group, a dodecyloxy group, etc.); a cycloalkoxy group (a cyclopentyloxy group, a cyclohexyloxy group, etc.); an aryloxy group (a phenoxy group, a naphthyloxy group, etc.); an alkylthio group (a methylthio group, an ethylthio group, a propylthio group, a pentylthio group, a hexylthio group, an octylthio group, a dodecylthio group, etc.); a cycloalkylthio group (a cyclopentylthio group, a cyclohexylthio group, etc.); an arylthio group (a phenylthio group, a naphthylthio group, etc.); an alkoxycarbonyl group (a methyloxycarbonyl group, an ethyloxycarbonyl group, a butyloxycarbonyl group, an octyloxycarbonyl group, a dodecyloxycarbonyl group, etc.); an aryloxycarbonyl group (a phenyloxycarbonyl group, a naphthyloxycarbonyl group, etc.); a sulfamoyl group (an aminosulfonyl group, a methylaminosulfonyl group, a dimethylaminosulfonyl group, a butylaminosulfonyl group, a hexylaminosulfonyl group, a cyclohexylaminosulfonyl group, an octylaminosulfonyl group, a dodecylaminosulfonyl group, a phenylaminosulfonyl group, a naphthylaminosulfonyl group, a 2-pyridylaminosulfonyl group, etc.); an acyl group (an acetyl group, an ethylcarbonyl group, a propylcarbonyl group, a pentylcarbonyl group, a cyclohexylcarbonyl group, an octylcarbonyl group, a 2-ethylhexylcarbonyl group, a dodecylcarbonyl group, a phenylcarbonyl group, a naphthylcarbonyl group, a pyridylcarbonyl group, etc.); an acyloxy group (an acetyloxy group, an ethylcarbonyloxy group, a butylcarbonyloxy group, an octylcarbonyloxy group, a dodecylcarbonyloxy group, a phenylcarbonyloxy group, etc.); an amido group (a methylcarbonylamino group, an ethylcarbonylamino group, a dimethylcarbonylamino group, a propylcarbonylamino group, a pentylcarbonylamino group, a cyclohexylcarbonylamino group, a 2-ethylhexylcarbonylamino group, an octylcarbonylamino group, a dodecylcarbonylamino group, a phenylcarbonylamino group, a naphthylcarbonylamino group, etc.); a carbamoyl group (an aminocarbonyl group, a methylaminocarbonyl group, a dimethylaminocarbonyl group, a propylaminocarbonyl group, a pentylaminocarbonyl group, a cyclohexylaminocarbonyl group, an octylaminocarbonyl group, a 2-ethylhexylaminocarbonyl group, a dodecylaminocarbonyl group, a phenylaminocarbonyl group, a naphthylaminocarbonyl group, a 2-pyridylaminocarbonyl group, etc.); an ureido group (a methylureido group, an ethylureido group, a pentylureido group, a cyclohexylureido group, an octylureido group, a dodecylureido group, a phenylureido group naphthylureido group, a 2-pyridylaminoureido group, etc.); a sulfinyl group (a methylsulfinyl group, an ethylsulfinyl group, a butylsulfinyl group, a cyclohexylsulfinyl group, a 2-ethylhexylsulfinyl group, a dodecylsulfinyl group, a phenylsulfinyl group, a naphthylsulfinyl group, a 2-pyridylsulfinyl group, etc.); an alkylsulfonyl group (a methylsulfonyl group, an ethylsulfonyl group, a butylsulfonyl group, a cyclohexylsulfonyl group, a 2-ethylhexylsulfonyl group, a dodecylsulfonyl group, etc.); an arylsulfonyl group or a heteroarylsulfonyl group (a phenylsulfonyl group, a naphthylsulfonyl group, a 2-pyridylsulfonyl group, etc.); an amino group (an amino group, an ethylamino group, a dimethylamino group, a butylamino group, a cyclopentylamino group, a 2-ethylhexylamino group, a dodecylamino group, an anilino group, a naphthylamino group, a 2-pyridylamino group, a piperidyl group (also called a piperidinyl group), a 2,2,6,6-tetramethylpiperidinyl group, etc.); a halogen atom (a fluorine atom, a chlorine atom, a bromine atom, etc.); a fluorohydrocarbon group (a fluoromethyl group, a trifluoromethyl group, a pentafluoroethyl group, a pentafluorophenyl group, etc.); a cyano group; a nitro group; a hydroxy group; a mercapto group; a silyl group (a trimethylsilyl group, a triisopropylsilyl group, a triphenylsilyl group, a phenyldiethylsilyl group, etc.); a phosphate group (a dihexylphosphoryl group, etc.); a phosphite group (a diphenylphosphinyl group, etc.); and a phosphono group.

Examples of the aromatic heterocyclic ring which is formed by A₁ with P—C in the above General Formula (A) include a furan ring, a thiophene ring, an oxazole ring, a pyrrole ring, a pyridine ring, a pyridazine ring, a pyrimidine ring, a pyrazine ring, a triazine ring, a benzimidazole ring, an oxadiazole ring, a triazole ring, an imidazole ring, a pyrazole ring, a triazole ring, an indole ring, a benzimidazole ring, a benzothiazole ring, a benzoxazole ring, a quinoxaline ring, a quinazoline ring, a phthalazine ring, a carbazole ring and an azacarbazole ring.

The azacarbazole ring indicates a ring formed in such a way that at least one of carbon atoms of a benzene ring constituting a carbazole ring is substituted by a nitrogen atom.

These rings may each have the substituent mentioned above.

Examples of the aromatic heterocyclic ring which is formed by A₂ with Q-N in General Formula (A) include an oxazole ring, an oxadiazole ring, an oxatriazole ring, an isoxazole ring, a tetrazole ring, a thiadiazole ring, a thiatriazole ring, an isothiazole ring, a pyrrole ring, a pyridine ring, a pyridazine ring, a pyrimidine ring, a pyrazine ring, a triazine ring, an imidazole ring, a pyrazole ring and a triazole ring.

These rings may each have the substituent mentioned above.

In General Formula (A), P₁-L₁-P₂ represents a bidentate ligand, and P₁ and P_{z} each independently represent a carbon atom, a nitrogen atom or an oxygen atom.

L₁ represents an atomic group which forms the bidentate ligand with P₁ and P₂.

Examples of the bidentate ligand represented by P₁-L₁-P₂ include phenylpyridine, phenylpyrazole, phenylimidazole, phenyltriazole, phenyltetrazole, pyrazabole, acetylacetone and picolinic acid.

In General Formula (A), j1 represents an integer of one to three, and j2 represents an integer of zero to two, provided that the sum of j1 and j2 is two or three. In particular, j2 being zero is preferable.

In General Formula (A), M₁ represents a transition metal element (simply called a transition metal) of Groups 8 to 10 in the element periodic table. In particular, M₁ being iridium is preferable.

<Compound Represented by General Formula (B)>

Of the compounds represented by the above described General Formula (A), a compound represented by the following General Formula (B) is far preferable.

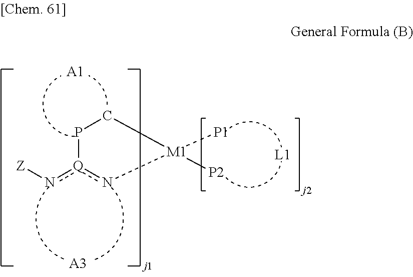

In the above General Formula (B), Z represents a hydrocarbon ring group or a heterocyclic group, P and Q each represent a carbon atom or a nitrogen atom, and A₁ represents an atomic group which forms an aromatic hydrocarbon ring or an aromatic heterocyclic ring with P—C.

A₃ represents —C(R₀₁)═C(R₀₂)—, —N═C(R₀₂)—, —C(R₀₁)═N— or —N═N—, and R₀₁ and R₀₂ each represent a hydrogen atom or a substituent.

P₁-L₁-P₂ represents a bidentate ligand, and P₁ and P₂ each independently represent a carbon atom, a nitrogen atom or an oxygen atom.

L₁ represents an atomic group which forms the bidentate ligand with P₁ and P₂.

j1 represents an integer of one to three, and j2 represents an integer of zero to two, provided that the sum of j1 and j2 is two or three.

M₁ represents a transition metal element of Groups 8 to 10 in the element periodic table.

Examples of the hydrocarbon ring group represented by Z in General Formula (B) include a non-aromatic hydrocarbon ring group and an aromatic hydrocarbon ring group. Examples of the non-aromatic hydrocarbon ring group include a cyclopropyl group, a cyclopentyl group and a cyclohexyl group. These groups may be each a non-substituted group or may each have a substituent described below.

Examples of the aromatic hydrocarbon ring group (also called an aromatic hydrocarbon group, an aryl group or the like) include a phenyl group, a p-chlorophenyl group, a mesityl group, a tolyl group, a xylyl group, a naphthyl group, an anthryl group, an azulenyl group, an acenaphthenyl group, a fluorenyl group, a phenanthryl group, an indenyl group, a pyrenyl group and a biphenyl group.

These groups may be each a non-substituted group or may each have a substituent. Examples of the substituent include those of the substituent which the ring represented by A₁ in General Formula (A) may have.

Examples of the heterocyclic group represented by Z in General Formula (B) include a non-aromatic heterocyclic group and an aromatic heterocyclic group.

Examples of the non-aromatic heterocyclic group include groups derived from, for example, an epoxy ring, an aziridine ring, a thiirane ring, an oxetane ring, an azetidine ring, a thietane ring, a tetrahydrofuran ring, a dioxorane ring, a pyrrolidine ring, a pyrazolidine ring, an imidazolidine ring, an oxazolidine ring, a tetrahydrothiophene ring, a sulforane ring, a thiazolidine ring, an ε-caprolactone ring, an ε-caprolactam ring, a piperidine ring, a hexahydropyridazine ring, a hexahydropyrimidine ring, a piperazine ring, a morpholine ring, a tetrahydropyrane ring, a 1,3-dioxane ring, a 1,4-dioxane ring, a trioxane ring, a tetrahydrothiopyrane ring, a thiomorpholine ring, a thiomorpholine-1,1-dioxide ring, a pyranose ring and a diazabicyclo[2,2,2]-octane ring.

These groups may be each a non-substituted group or may each have a substituent. Examples of the substituent include those of the substituent which the ring represented by A₁ in General Formula (A) may have.

Examples of the aromatic heterocyclic group include a pyridyl group, a pyrimidinyl group, a furyl group, a pyrrolyl group, an imidazolyl group, a benzimidazolyl group, a pyrrazolyl group, a pyradinyl group, a triazolyl group (a 1,2,4-triazole-1-yl group, a 1,2,3-triazole-1-yl group, etc.), an oxazolyl group, a benzoxazolyl group, a triazolyl group, an isoxazolyl group, an isothiazolyl group, a furazanyl group, a thienyl group, a quinolyl group, a benzofuryl group, a dibenzofuryl group, a benzothienyl group, a dibenzothienyl group, an indolyl group, a carbazolyl group, a carbolinyl group, a diazacarbazolyl group (indicating a group formed in such a way that one of carbon atoms constituting a carboline ring of a carbolinyl group is substituted by a nitrogen atom), a quinoxalinyl group, a pyridazinyl group, a triazinyl group, a quinazolinyl group and a phthalazinyl group.

These groups may be each a non-substituted group or may each have a substituent. Examples of the substituent include those of the substituent which the ring represented by A₁ in General Formula (A) may have.

The group represented by Z is preferably an aromatic hydrocarbon ring group or an aromatic heterocyclic group.

Examples of the aromatic hydrocarbon ring which is formed by A₁ with P—C in General Formula (B) include a benzene ring, a biphenyl ring, a naphthalene ring, an azulene ring, an anthracene ring, a phenanthrene ring, a pyrene ring, a chrysene ring, a naphthacene ring, a triphenylene ring, an o-terphenyl ring, an m-terphenyl ring, a p-terphenyl ring, an acenaphthene ring, a coronene ring, a fluorene ring, a fluoranthrene ring, a naphthacene ring, a pentacene ring, a perylene ring, a pentaphene ring, a picene ring, a pyrene ring, a pyranthrene ring and an anthranthrene ring.

These rings may each have a substituent. Examples of the substituent include those of the substituent which the ring represented by A₁ in General Formula (A) may have.

Examples of the aromatic heterocyclic ring which is formed by A₁ with P—C in General Formula (B) include a furan ring, a thiophene ring, an oxazole ring, a pyrrole ring, a pyridine ring, a pyridazine ring, a pyrimidine ring, a pyrazine ring, a triazine ring, a benzimidazole ring, an oxadiazole ring, a triazole ring, an imidazole ring, a pyrazole ring, a triazole ring, an indole ring, a benzimidazole ring, a benzothiazole ring, a benzoxazole ring, a quinoxaline ring, a quinazoline ring, a phthalazine ring, a carbazole ring, a carboline ring and an azacarbazole ring.

The azacarbazole ring indicates a ring formed in such a way that at least one of carbon atoms of a benzene ring constituting a carbazole ring is substituted by a nitrogen atom.

These rings may each have a substituent. Examples of the substituent include those of the substituent which the ring represented by A₁ in General Formula (A) may have.

The substituent represented by each of R₀₁ and R₀₂ in each of —C(R₀₁)═C(R₀₂)—, —N═C(R₀₂)— and —C(R₀₁)═N— represented by A₃ in General Formula (B) is synonymous with the substituent which the ring represented by A₁ in General Formula (A) may have.

Examples of the bidentate ligand represented by P₁-L₁-P₂ in General Formula (B) include phenylpyridine, phenylpyrazole, phenylimidazole, phenyltriazole, phenyltetrazole, pyrazabole, acetylacetone and picolinic acid.

j1 represents an integer of one to three, and j2 represents an integer of zero to two, provided that the sum of j1 and j2 is two or three. In particular, j2 being zero is preferable.

The transition metal element (simply called a transition metal) of Groups 8 to 10 in the element periodic table represented by M₁ in General Formula (B) is synonymous with the transition metal element of Groups 8 to 10 in the element periodic table represented by M₁ in General Formula (A).

<Compound Represented by General Formula (C)>

In the present invention, of the compounds represented by the above General Formula (B), a compound represented by the following General Formula (C) is one of preferable ones.

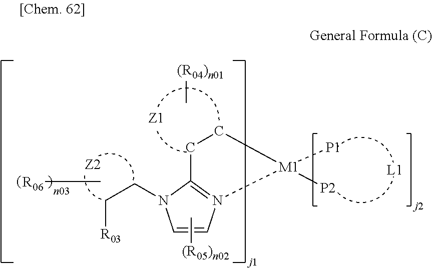

In the above General Formula (C), R₀₃ represents a substituent, R₀₄ represents a hydrogen atom or a substituent, and a plurality of R₀₄ may bind to each other to form a ring.

n01 represents an integer of one to four.

R₀₅ represents a hydrogen atom or a substituent, and a plurality of R₀₅ may bind to each other to form a ring. n02 represents an integer of one to two.

R₀₆ represents a hydrogen atom or a substituent, and a plurality of R₀₆ may bind to each other to form a ring.

n03 represents an integer of one to four.

Z₁ represents an atomic group required to form a six-membered aromatic hydrocarbon ring or a five-membered or six-membered aromatic heterocyclic ring with C—C.

Z₂ represents an atomic group required to form a hydrocarbon ring group or a heterocyclic group.

P₁-L₁-P₂ represents a bidentate ligand, and P₁ and P₂ each independently represent a carbon atom, a nitrogen atom or an oxygen atom.

L₁ represents an atomic group which forms the bidentate ligand with P₁ and P₂.

j1 represents an integer of one to three, and j2 represents an integer of zero to two, provided that the sum of j1 and j2 is two or three.

M₁ represents a transition metal element of Groups 8 to 10 in the element periodic table.

R₀₃ and R₀₆, R₀₄ and R₀₆, and R₀₅ and R₀₆ may each bind to each other to form a ring.

The substituent represented by each of R₀₃, R₀₄, R₀₅ and R₀₆ in General Formula (C) is synonymous with the substituent which the ring represented by A₁ in General Formula (A) may have.

Examples of the six-membered aromatic hydrocarbon ring which is formed by Z₁ with C—C in General Formula (C) include a benzene ring.

These rings may each have a substituent. Examples of the substituent include those of the substituent which the ring represented by A₁ in General Formula (A) may have.

Examples of the five-membered or six-membered aromatic heterocyclic ring which is formed by Z₁ with C—C in General Formula (C) include an oxazole ring, an oxadiazole ring, an oxatriazole ring, an isoxazole ring, a tetrazole ring, a thiadiazole ring, a thiatriazole ring, an isothiazole ring, a thiophene ring, a furan ring, a pyrrole ring, a pyridine ring, a pyridazine ring, a pyrimidine ring, a pyrazine ring, a triazine ring, an imidazole ring, a pyrazole ring and a triazole ring.

These rings may each have a substituent. Examples of the substituent include those of the substituent which the ring represented by A₁ in General Formula (A) may have.

Examples of the hydrocarbon ring group represented by Z₂ in General Formula (C) include a non-aromatic hydrocarbon ring group and an aromatic hydrocarbon ring group.

Examples of the non-aromatic hydrocarbon ring group include a cyclopropyl group, a cyclopentyl group and a cyclohexyl group. These groups may be each a non-substituted group or may each have a substituent. Examples of the substituent include those of the substituent which the ring represented by A₁ in General Formula (A) may have.

Examples of the aromatic hydrocarbon ring group (also called an aromatic hydrocarbon group, an aryl group or the like) include a phenyl group, a p-chlorophenyl group, a mesityl group, a tolyl group, a xylyl group, a naphthyl group, an anthryl group, an azulenyl group, an acenaphthenyl group, a fluorenyl group, a phenanthryl group, an indenyl group, a pyrenyl group and a biphenyl group. These groups may be each a non-substituted group or may each have a substituent. Examples of the substituent include those of the substituent which the ring represented by A₁ in General Formula (A) may have.

Examples of the heterocyclic group represented by Z₂ in General Formula (C) include a non-aromatic heterocyclic group and an aromatic heterocyclic group.

Examples of the non-aromatic heterocyclic group include groups derived from, for example, an epoxy ring, an aziridine ring, a thiirane ring, an oxetane ring, an azetidine ring, a thietane ring, a tetrahydrofuran ring, a dioxorane ring, a pyrrolidine ring, a pyrazolidine ring, an imidazolidine ring, an oxazolidine ring, a tetrahydrothiophene ring, a sulforane ring, a thiazolidine ring, an ε-caprolactone ring, an ε-caprolactam ring, a piperidine ring, a hexahydropyridazine ring, a hexahydropyrimidine ring, a piperazine ring, a morpholine ring, a tetrahydropyrane ring, a 1,3-dioxane ring, a 1,4-dioxane ring, a trioxane ring, a tetrahydrothiopyrane ring, a thiomorpholine ring, a thiomorpholine-1,1-dioxide ring, a pyranose ring and a diazabicyclo[2,2,2]-octane ring. These groups may be each a non-substituted group or may each have a substituent. Examples of the substituent include those of the substituent which the ring represented by A₁ in General Formula (A) may have.

Examples of the aromatic heterocyclic group include a pyridyl group, a pyrimidinyl group, a furyl group, a pyrrolyl group, an imidazolyl group, a benzimidazolyl group, a pyrrazolyl group, a pyradinyl group, a triazolyl group (a 1,2,4-triazole-1-yl group, a 1,2,3-triazole-1-yl group, etc.), an oxazolyl group, a benzoxazolyl group, a triazolyl group, an isoxazolyl group, an isothiazolyl group, a furazanyl group, a thienyl group, a quinolyl group, a benzofuryl group, a dibenzofuryl group, a benzothienyl group, a dibenzothienyl group, an indolyl group, a carbazolyl group, a carbolinyl group, a diazacarbazolyl group (indicating a group formed in such a way that one of carbon atoms constituting a carboline ring of a carbolinyl group is substituted by a nitrogen atom), a quinoxalinyl group, a pyridazinyl group, a triazinyl group, a quinazolinyl group and a phthalazinyl group.

These rings may be each a non-substituted ring or may each have a substituent. Examples of the substituent include those of the substituent which the ring represented by A₁ in General Formula (A) may have.

The group which is formed by each of Z₁ and Z₂ in General Formula (C) is preferably a benzene ring.

The bidentate ligand represented by P₁-L₁-P₂ in General Formula (C) is synonymous with the bidentate ligand represented by P₁-L₁-P₂ in General Formula (A).

The transition metal element of Groups 8 to 10 in the element periodic table represented by M₁ in General Formula (C) is synonymous with the transition metal element of Groups 8 to 10 in the element periodic table represented by M₁ in General Formula (A).

The phosphorescent compound to be used can be suitably selected from the well-known phosphorescent compounds, which are usable for the luminescent layer 3c of the organic EL element 100.

The phosphorescent compound of the present invention is preferably a complex compound containing a metal of Groups 8 to 10 in the element periodic table; far preferably an iridium compound, an osmium compound, a platinum compound (a platinum complex compound) or a rare-earth complex; and most preferably an iridium compound.

Specific examples (Pt-1 to Pt-3, A-1, and Ir-1 to Ir-45) of the phosphorescent compound of the present invention are shown below, but the present invention is not limited thereto. In these compounds, m and n each represent the number of repeats.

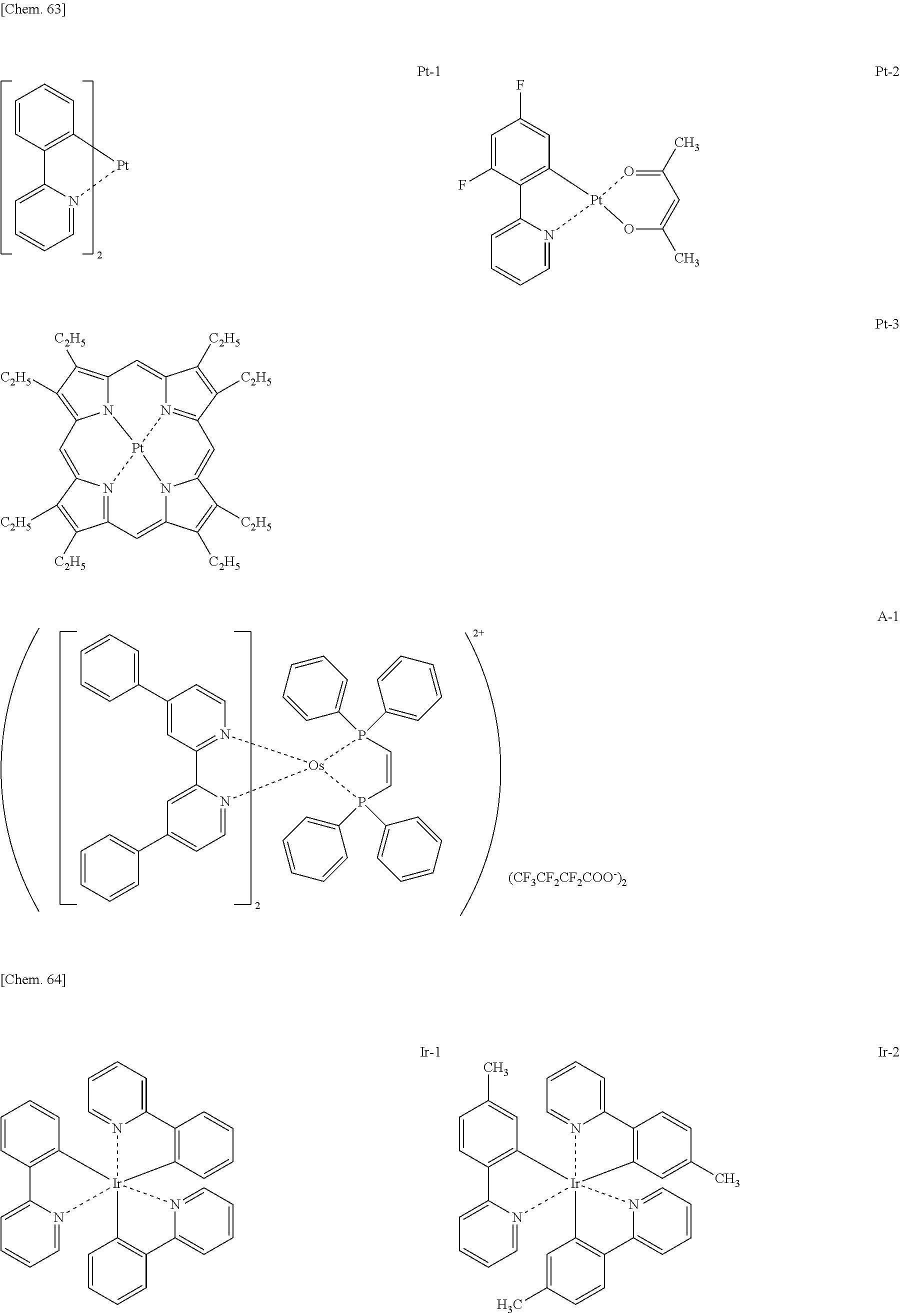

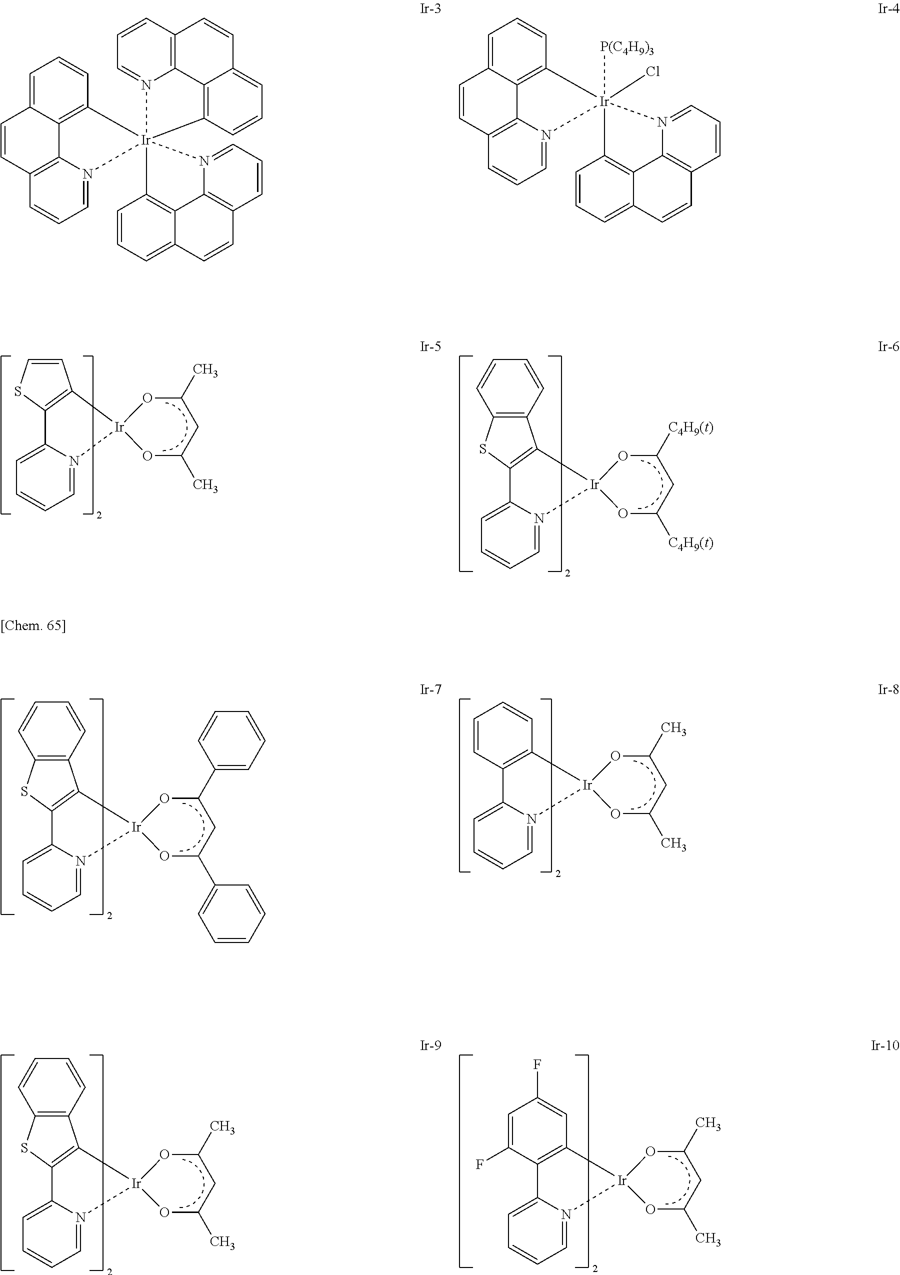

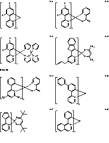

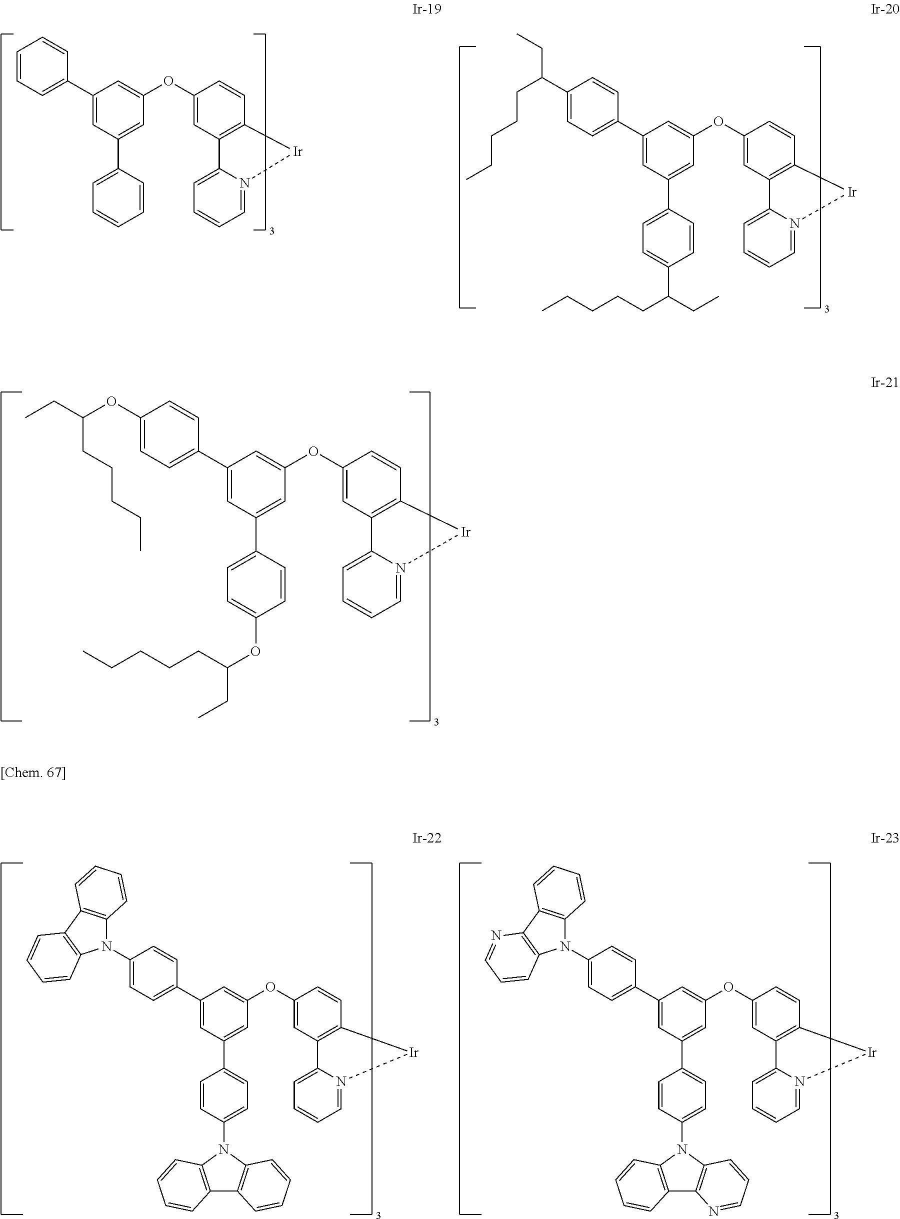

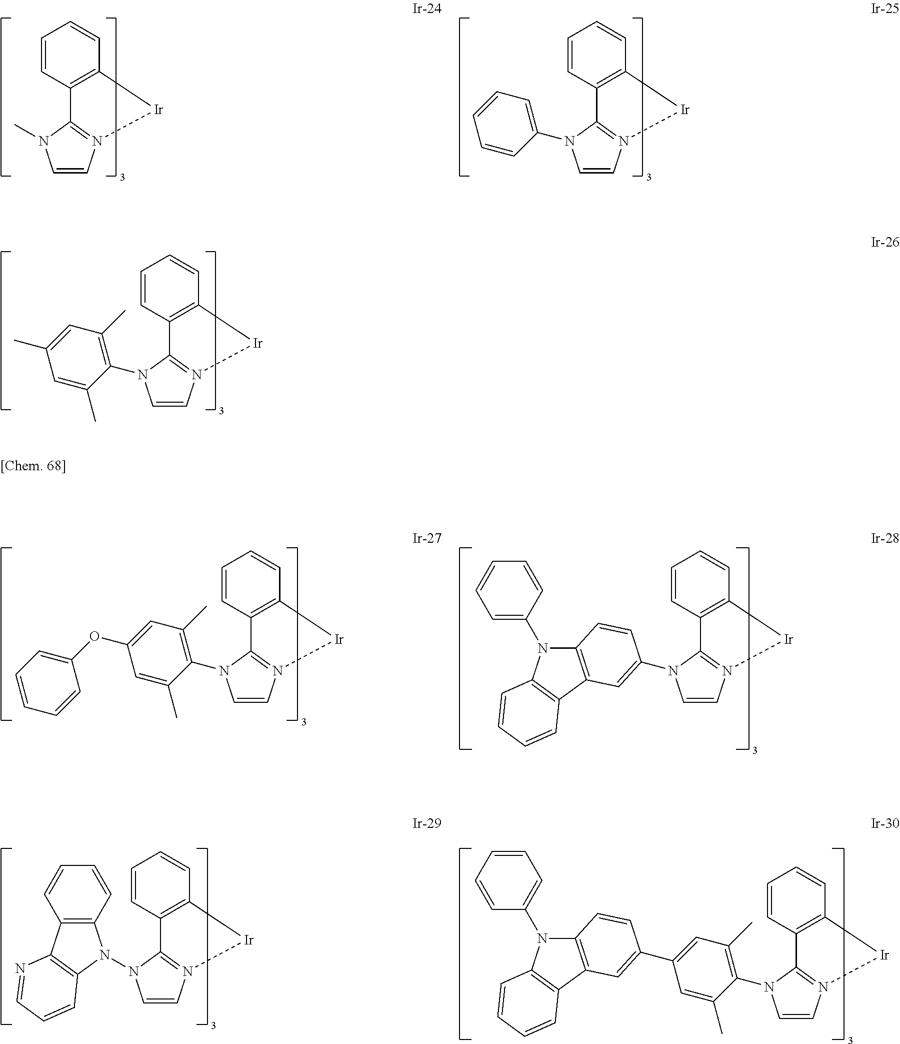

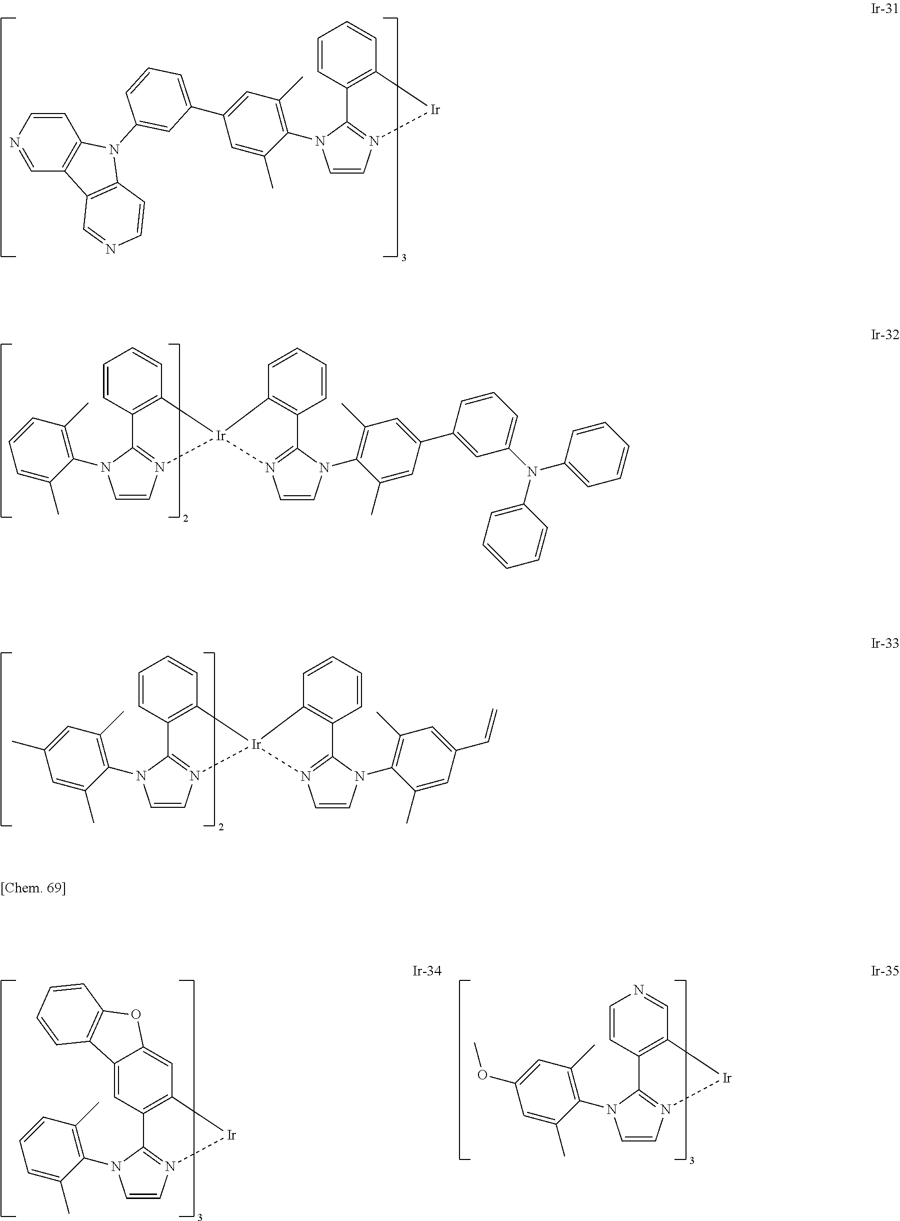

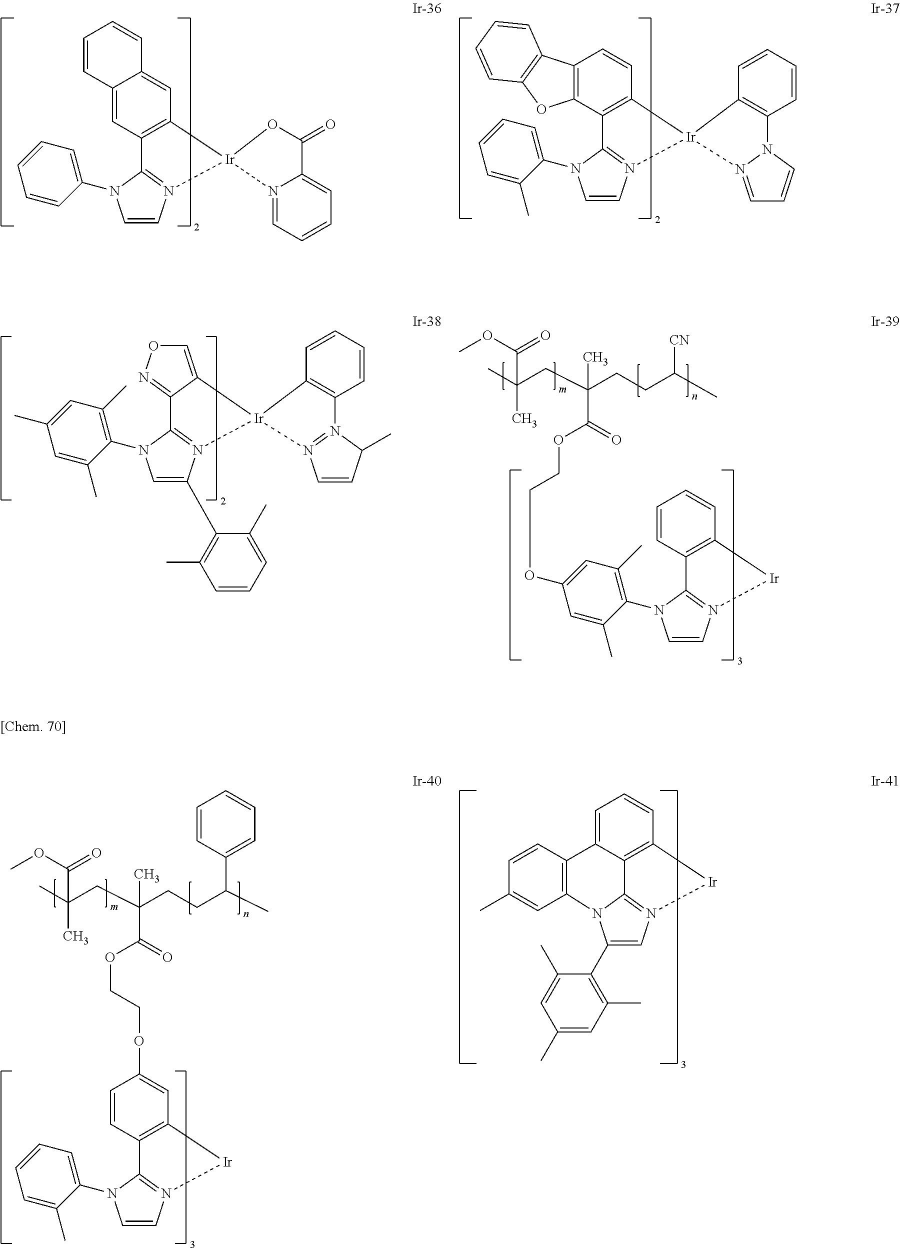

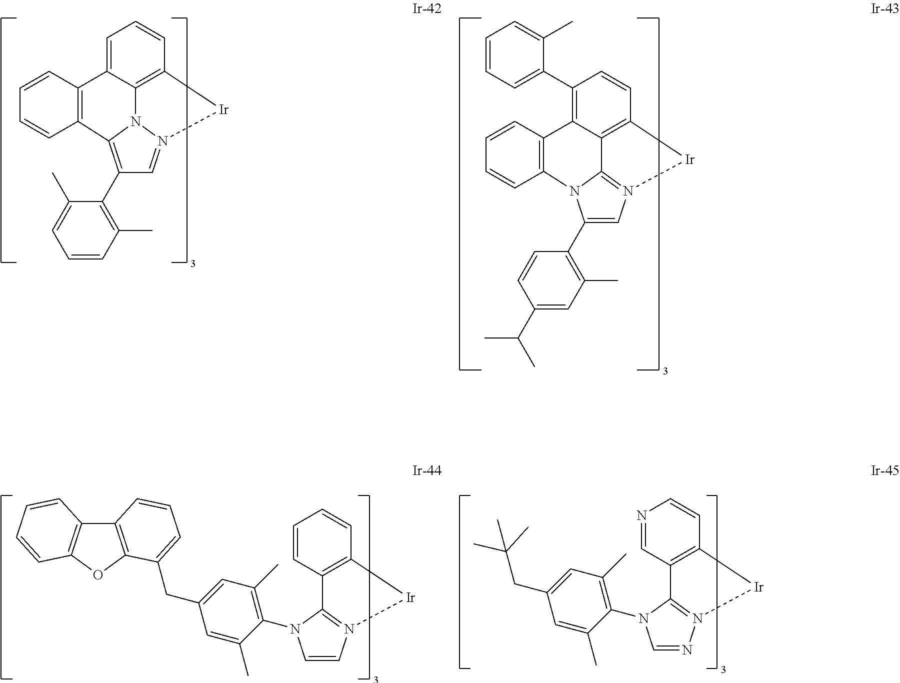

The above mentioned phosphorescent compounds (also called phosphorescent metal complexes) can be synthesized by employing methods mentioned in documents such as Organic Letter, vol. 3, No. 16, pp. 2579-2581 (2001); Inorganic Chemistry, vol. 30, No. 8, pp. 1685-1687 (1991); J. Am. Chem. Soc., vol. 123, p. 4304 (2001); Inorganic Chemistry, vol. 40, No. 7, pp. 1704-1711 (2001); Inorganic Chemistry, vol. 41, No. 12, pp. 3055-3066 (2002); New Journal of Chemistry, vol. 26, p. 1171 (2002); and European Journal of Organic Chemistry, vol. 4, pp. 695-709 (2004); and reference documents and the like mentioned in these documents.

<Fluorescent Material>

Examples of the fluorescent material include a coumarin dye, a pyran dye, a cyanine dye, a croconium dye, a squarium dye, an oxobenzanthracene dye, a fluorescein dye, a rhodamine dye, a pyrylium dye, a perylene dye, a stilbene dye, a polythiophene dye and a rare-earth complex phosphor.

(Injection Layer)

The injection layer (s) (the positive hole injection layer 3a and the electron injection layer 3e) is a layer disposed between an electrode and the luminescent layer 3c for reduction in driving voltage and increase in luminance of light emitted, which is detailed in Part 2, Chapter 2 “Denkyoku Zairyo (Electrode Material)” (pp. 123-166) of “Yuki EL Soshi To Sono Kogyoka Saizensen (Organic EL Element and Front of Industrialization thereof) (Nov. 30, 1998, published by N.T.S Co., Ltd.)”, and examples thereof include the positive hole injection layer 3a and the electron injection layer 3e.

The injection layer can be provided as needed. In the case of the positive hole injection layer 3a, it may be present between the anode and the luminescent layer 3c or the positive hole transport layer 3b. In the case of the electron injection layer 3e, it may be present between the cathode and the luminescent layer 3c or the electron transport layer 3d.

The positive hole injection layer 3a is detailed in documents such as Japanese Patent Application Publication Nos. 9-45479, 9-260062 and 8-288069, and examples thereof include: a phthalocyanine layer of, for example, copper phthalocyanine; an oxide layer of, for example, vanadium oxide; an amorphous carbon layer; and a high polymer layer using a conductive high polymer such as polyaniline (emeraldine) or polythiophene.

The electron injection layer 3e is detailed in documents such as Japanese Patent Application Publication Nos. 6-325871, 9-17574 and 10-74586, and examples thereof include: a metal layer of, for example, strontium or aluminum; an alkali metal halide layer of, for example, potassium fluoride; an alkali earth metal compound layer of, for example, magnesium fluoride; and an oxide layer of, for example, molybdenum oxide. It is preferable that the electron injection layer 3e of the present invention be a very thin film, and the thickness thereof be within a range from 1 nm to 10 μm although it depends on the material thereof.

(Positive Hole Transport Layer 3b)

The positive hole transport layer 3b is composed of a positive hole transport material having a function to transport positive holes, and, in a broad sense, the positive hole injection layer 3a and the electron block layer are of the positive hole transport layer 3b. The positive hole transport layer 3b may be composed of a single layer or a plurality of layers.

The positive hole transport material is a material having either the property to inject or transport positive holes or a barrier property against electrons and is either an organic matter or an inorganic matter. Examples thereof include a triazole derivative, an oxadiazole derivative, an imidazole derivative, a polyarylalkane derivative, a pyrazoline derivative, a pyrazolone derivative, a phenylenediamine derivative, an arylamine derivative, an amino-substituted chalcone derivative, an oxazole derivative, a styrylanthracene derivative, a fluorenone derivative, a hydrazone derivative, a stilbene derivative, a silazane derivative, an aniline copolymer and an oligomer of a conductive high polymer such as a thiophene oligomer.

As the positive hole transport material, those mentioned above can be used. However, it is preferable to use a porphyrin compound, an aromatic tertiary amine compound or a styrylamine compound, in particular an aromatic tertiary amine compound.

Representative examples of the aromatic tertiary amine compound and the styrylamine compound include: N,N,N′,N′-tetraphenyl-4,4′-diaminophenyl; N,N′-diphenyl-N,N′-bis(3-methylphenyl)-[1,1′-biphenyl]-4,4′-diamine (abbr.: TPD); 2,2-bis(4-di-p-tolylaminophenyl)propane; 1,1-bis(4-di-p-tolylaminophenyl)cyclohexane; N,N,N′,N′-tetra-p-tolyl-4,4′-diaminobiphenyl; 1,1-bis(4-di-p-tolylaminophenyl)-4-phenylcyclohexane; bis(4-dimethylamino-2-metylphenyl)phenylmethane; bis(4-di-p-tolylaminophenyl)phenylmethane; N,N′-diphenyl-N,N′-di(4-methoxyphenyl)-4,4′-diaminobiphenyl N,N,N′,N′-tetraphenyl-4,4′-diaminodiphenylether; 4,4′-bis(diphenylamino)quadriphenyl; N,N,N-trip-tolyl)amine; 4-(di-p-tolylamino)-4′-[4-(di-p-tolylamino)styryl]stilbene; 4-N, N-diphenylamino-(2-diphenylvinyl)benzene; 3-methoxy-4′-N,N-diphenylaminostilbezene; N-phenylcarbazole; those having two condensed aromatic rings in a molecule mentioned in U.S. Pat. No. 5,061,569, such as 4,4′-bis[N-(1-naphthyl)-N-phenylamino]biphenyl (abbr.: NDP); and 4,4′,4″-tris[N-(3-methylphenyl)-N-phenylamino]triphenylamine (abbr.: MTDATA) in which three triphenylamine units are bonded in a star burst form mentioned in Japanese Patent Application Publication No. 4-308688.

High polymer materials in each of which any of the above mentioned materials is introduced into a high polymer chain or constitutes a main chain of a high polymer can also be used. Inorganic compounds such as a p type-Si and a p type-SiC can also be used as the positive hole injection material and the positive hole transport material.

It is also possible to use so-called p type positive hole transport materials mentioned in documents such as Japanese Patent Application Publication No. 11-251067 and Applied Physics Letters, 80, p. 139 (2002) by J. Huang et al. In the present invention, it is preferable to use these materials in order to produce a light emitting element having higher efficiency.

The positive hole transport layer 3b can be formed by forming a thin film of any of the above mentioned positive hole transport materials by a well-known method such as vacuum deposition, spin coating, casting, printing including the inkjet method, or the LB method.

The thickness of the positive hole transport layer 3b is not particularly limited, but it is generally within a range from 5 nm to 5 μm, preferably within a range from 5 nm to 200 nm. The positive hole transport layer 3b may have a single-layer structure composed of one type or two or more types of the above mentioned materials.

The material of the positive hole transport layer 3b may be doped with impurities so that p property increases. Examples thereof include those mentioned in documents such as Japanese Patent Application Publication Nos. 4-297076, 2000-196140 and 2001-102175 and J. Appl. Phys., 95, 5773 (2004).

Increase in p property of the positive hole transport layer 3b is preferable because it enables production of an element which consumes lower electric power.

[Electron Transport Layer 3d]

The electron transport layer 3d is composed of a material having a function to transport electrons, and, in a broad sense, the electron injection layer 3e and the positive hole block layer (not shown) are of the electron transport layer 3d. The electron transport layer 3d may have a single-layer structure or a multilayer structure of a plurality of layers.

The electron transport material (which doubles as a positive hole block material) which constitutes a layer portion adjacent to the luminescent layer 3c in the electron transport layer 3d having a single-layer structure or in the electron transport layer 3d having a multilayer structure should have a function to transport electrons injected from the cathode to the luminescent layer 3c.

The material to be used can be suitably selected from well-known compounds. Examples thereof include a nitro-substituted fluorene derivative, a diphenylquinone derivative, a thiopyrandioxide derivative, carbodiimide, a fluorenylidenemethane derivative, anthraquinodimethane, an anthrone derivative and an oxadiazole derivative.

A thiadiazole derivative formed in such a way that an oxygen atom of an oxadiazole ring of an oxadiazole derivative is substituted by a sulfur atom and a quinoxaline derivative having a quinoxaline ring which is well known as an electron withdrawing group can also be used as the material for the electron transport layer 3d.

Further, high polymer materials in each of which any of the above mentioned materials is introduced into a high polymer chain or constitutes a main chain of a high polymer can also be used.

Still further, metal complexes of 8-quinolinol derivatives such as: tris(8-quinolinol)aluminum (abbr.: Alq₃), tris(5,7-dichloro-8-quinolinol)aluminum, tris(5,7-dibromo-8-quinolinol)aluminum, tris(2-methyl-8-quinolinol)aluminum, tris(5-methyl-8-quinolinol)aluminum and bis(8-quinolinol)zinc (abbr.: Znq); and metal complexes each formed in such a way that central metal of each of the above mentioned metal complexes is substituted by In, Mg, Cu, Ca, Sn, Ga or Pb can also be used as the material for the electron transport layer 3d.

Yet further, metal-free phthalocyanine and metal phthalocyanine and ones each formed in such a way that an end of each of these is substituted by an alkyl group, a sulfonic acid group or the like can also be used as the material for the electron transport layer 3d by preference.

Still further, the distyrylpyrazine derivative mentioned as an example of the material for the luminescent layer 3c can also be used as the material for the electron transport layer 3d. Yet further, inorganic semiconductors such as an n type-Si and an n type-SiC can also be used as the material for the electron transport layer 3d, as with the positive hole injection layer 3a and the positive hole transport layer 3b.

The electron transport layer 3d can be formed by forming a thin film of any of the above mentioned materials by a well-known method such as vacuum deposition, spin coating, casting, printing including the inkjet method, or the LB method.

The thickness of the electron transport layer 3d is not particularly limited, but it is generally within a range from 5 nm to 5 μm, preferably within a range from 5 nm to 200 nm. The electron transport layer 3d may have a single-layer structure composed of one type or two or more types of the above mentioned materials.

The electron transport layer 3d may be doped with impurities so that n property increases. Examples thereof include those mentioned in documents such as Japanese Patent Application Publication Nos. 4-297076, 10-270172, 2000-196140 and 2001-102175 and J. Appl. Phys., 95, 5773 (2004).

It is preferable that the electron transport layer 3d contain potassium, a potassium compound or the like. As the potassium compound, for example, potassium fluoride can be used. Increase in n property of the electron transport layer 3d enables production of an organic EL element which consumes lower electric power.

As the material (electron transportable compound) of the electron transport layer 3d, materials which are the same as the above mentioned materials for the intermediate layer 1a may be used. The same applies to the electron transport layer 3d which doubles as the electron injection layer 3e. Accordingly, materials which are the same as the above mentioned materials for the intermediate layer 1a may be used therefor.

(Block Layer)

The block layer (s) (the positive hole block layer and the electron block layer) is provided as needed in addition to the basic constituent layers of the thin film composed of an organic compound(s) as described above. Examples thereof include positive hole block layers mentioned in documents such as Japanese Patent Application Publication Nos. 11-204258 and 11-204359 and p. 273 of “Yuki EL Soshi To Sono Kogyoka Saizensen (Organic EL Element and Front of Industrialization thereof) (Nov. 30, 1998, published by N.T.S Co., Ltd.)”.

The positive hole block layer has a function of the electron transport layer 3d in a broad sense. The positive hole block layer is composed of a positive hole block material having a function to transport electrons with a significantly low property to transport positive holes and can increase rebinding probability of electrons and positive holes by blocking positive holes while transporting electrons. The structure of the electron transport layer 3d described below can be used for the positive hole block layer as needed. It is preferable that the positive hole block layer be disposed adjacent to the luminescent layer 3c.

On the other hand, the electron block layer has a function of the positive hole transport layer 3b in a broad sense. The electron block layer is composed of a material having a function to transport positive holes with a significantly low property to transport electrons and can increase rebinding probability of electrons and positive holes by blocking electrons while transporting positive holes.

The structure of the positive hole transport layer 3b described below can be used for the electron block layer as needed.

The thickness of the positive hole block layer used in the present invention is preferably within a range from 3 nm to 100 nm and far preferably within a range from 5 nm to 30 nm.

(Auxiliary Electrode 15)

The auxiliary electrode 15 is provided in order to reduce resistance of the transparent electrode 1 and disposed in contact with the conductive layer 1b of the transparent electrode 1. As a material which forms the auxiliary electrode 15, a metal having low resistance is preferable. Examples thereof include gold, platinum, silver, copper and aluminum. Because these metals have low optical transparency, the auxiliary electrode 15 is formed by patterning within an area not to be affected by extraction of emission light h from a light extraction face 13a.

Examples of a forming method of the auxiliary electrode 15 include vapor deposition, sputtering, printing, the inkjet method and the aerosol-jet method.

It is preferable that the line width of the auxiliary electrode 15 be 50 μm or less in view of an open area ratio of a region to extract light, and the thickness of the auxiliary electrode 15 be 1 μm or more in view of conductivity.

(Sealing Member 17)

The sealing member 17 covers the organic EL element 100, and may be a plate-type (film-type) sealing member and fixed to the transparent substrate 13 side with the adhesive 19 or may be a sealing layer.

The sealing member 17 is disposed in such a way as to cover at least the light-emitting functional layer 3 while exposing the terminal portions of the transparent electrode 1 and the counter electrode 5a of the organic EL element 100. The sealing member 17 may be provided with an electrode, and the terminal portions of the transparent electrode 1 and the counter electrode 5a of the organic EL element 100 may be conductive with this electrode.

Examples of the plate-type (film-type) sealing member 17 include a glass substrate, a polymer substrate and a metal substrate. These substrate materials may be made to be thinner films to use.

Examples of the glass substrate include, in particular, soda-lime glass, glass containing barium and strontium, lead glass, aluminosilicate glass, borosilicate glass, barium borosilicate glass and quartz.

Examples of the polymer substrate include polycarbonate, acrylic, polyethylene terephthalate, polyether sulfide and polysulfone.

Examples of the metal substrate include ones composed of at least one type of metals or alloys selected from the group consisting of stainless steel, iron, copper, aluminum, magnesium, nickel, zinc, chromium, titanium, molybdenum, silicon, germanium and tantalum.

Among these, a polymer substrate or a metal substrate in the shape of a thin film can be preferably used as the sealing member in order to make an organic EL element thin.

It is preferable that the film-type polymer substrate have an oxygen permeability of 1×10⁻³ ml/(m²·24 h·atm) or less determined by a method in conformity with JIS K 7126-1987 and a water vapor permeability (25±0.5° C. and a relative humidity of 90±2% RH) of 1×10⁻³ g/(m²·24 h) or less determined by a method in conformity with JIS K 7129-1992.

The above mentioned substrate materials may be each processed to be in the shape of a concave plate to be used as the sealing member 17. In this case, the above mentioned substrate materials are processed by sandblasting, chemical etching or the like to be concave.

The adhesive 19 for fixing the plate-type sealing member 17 to the transparent substrate 13 side is used as a sealing agent for sealing the organic EL element 100 which is interposed between the sealing member 17 and the transparent substrate 13.

Examples of the adhesive 19 include: photo-curable and thermosetting adhesives each having a reactive vinyl group of an acrylic acid oligomer or a methacrylic acid oligomer; and moisture-curable adhesives such as 2-cyanoacrylate.

Examples of the adhesive 19 further include thermosetting and chemical curing (two-liquid-mixed) ones such as an epoxy-based one, still further include hot-melt ones such as polyamide, polyester and polyolefin and yet further include cationic curing ones such as a UV-curable epoxy resin adhesive.

The organic material of the organic EL element 100 is occasionally deteriorated by heat treatment. Therefore, the adhesive 19 is preferably one which adheres and cures at from room temperature to 80° C. In addition, a desiccating agent may be dispersed into the adhesive 19.

The adhesive 19 may be applied to an adhesion portion of the sealing member 17 and the transparent substrate 13 with a commercial dispenser or may be printed in the same way as screen printing.

In the case where spaces are formed between the plate-type sealing member 17, the transparent substrate 13 and the adhesive 19, it is preferable, in a gas phase and a liquid phase, to inject an inert gas, such as nitrogen or argon, and an inert liquid, such as fluorohydrocarbon or silicone oil, respectively, into the spaces. The spaces may be made to be vacuum, or a hygroscopic compound may be enclosed therein.

Examples of the hygroscopic compound include: metal oxide (sodium oxide, potassium oxide, calcium oxide, barium oxide, magnesium oxide, aluminum oxide, etc.); sulfate (sodium sulfate, calcium sulfate, magnesium sulfate, cobalt sulfate, etc.); metal halide (calcium chloride, magnesium chloride, cesium fluoride, tantalum fluoride, cerium bromide, magnesium bromide, barium iodide, magnesium iodide, etc.); and perchlorate (barium perchlorate, magnesium perchlorate, etc.). With respect to sulfate, metal halide and perchlorate, anhydrous ones are used by preference.

On the other hand, in the case where the sealing layer is used as the sealing member 17, the sealing layer is disposed on the transparent substrate 13 in such a way as to completely cover the light-emitting functional layer 3 of the organic EL element 100 and also expose the terminal portions of the transparent electrode 1 and the counter electrode 5a of the organic EL element 100.

The sealing layer is made with an inorganic material or an organic material, in particular a material impermeable to matters such as moisture and oxygen which cause deterioration of the light-emitting functional layer 3 of the organic EL element 100. Examples of the material to be used include inorganic materials such as silicon oxide, silicon dioxide and silicon nitride.

In order to reduce fragility of the sealing layer, the sealing layer may have a multilayer structure of a layer composed of any of these inorganic materials and a layer composed of an organic material.

A forming method of these layers includes but is not particularly limited to: vacuum deposition, sputtering, reactive sputtering, molecular beam epitaxy, cluster ion beam, ion plating, plasma polymerization, atmospheric pressure plasma polymerization, plasma CVD, laser CVD, thermal CVD and coating.

(Protective Layer/Protective Plate)

Although not shown in the figure described above, a protective layer or protective plate may be disposed in such a way that the organic EL element 100 and the sealing member 17 are interposed between the protective layer or protective plate and the transparent substrate 13. The protective layer or protective plate is for mechanical protection of the organic EL element 100. In the case where the sealing member 17 is a sealing layer in particular, it is preferable to provide the protective layer or protective plate because mechanical protection of the organic EL element 100 is not enough.

Examples used as the protective layer or protective plate include: a glass plate; a polymer plate and a polymer film thinner than that; a metal plate and a metal film thinner than that; a polymer material layer; and a metal material layer. In particular, it is preferable to use a polymer film because it is light and thin.

[Production Method of Organic EL Element]

A production method of the organic EL element 100, which is shown in FIG. 3, is described herein as an example.

First, an intermediate layer 1a composed of an organic compound containing a sulfur atom(s) having an unshared electron pair is formed on a transparent substrate 13 by a suitably selected method such as vapor deposition in such away as to have a thickness of 1 μm or less, preferably 10 nm to 100 nm.

Next, a conductive layer 1b composed of silver (or an alloy containing silver as a main component) is formed on the intermediate layer 1a by a suitably selected method such as vapor deposition in such a way as to have a thickness of 5 nm to 20 nm, preferably 5 nm to 8 nm. Thus, a transparent electrode 1 as an anode is produced.

Next, a positive hole injection layer 3a, a positive hole transport layer 3b, a luminescent layer 3c, an electron transport layer 3d and an electron injection layer 3e are formed on the transparent electrode 1 in the order named, thereby forming a light-emitting functional layer 3. These layers may be formed by spin coating, casting, the inkjet method, vapor deposition, printing or the like, but vacuum deposition or spin coating is particularly preferable because, for example, they tend to produce homogeneous layers and hardly generate pinholes. Further, different forming methods may be used to form the respective layers.

In the case where vapor deposition is employed to form these layers, although vapor deposition conditions differ depending on, for example, the type of compounds to use, it is generally preferable that the conditions be suitably selected from their respective ranges of: 50° C. to 450° C. for a boat heating temperature; 1×10⁻⁶ Pa to 1×10⁻² Pa for degree of vacuum; 0.01 nm/sec to 50 nm/sec for a deposition rate; −50° C. to 300° C. for a substrate temperature; and 0.1 μm to 5 μm for thickness.

After the light-emitting functional layer 3 is formed in the above described manner, a counter electrode 5a as a cathode is formed on the upper side thereof by a suitably selected forming method such as vapor deposition or sputtering. At the time, the counter electrode 5a is formed by patterning to be a shape of leading from the upper side of the light-emitting functional layer 3 to the periphery of the transparent substrate 13, the terminal portion of the counter electrode 5a being on the periphery of the transparent substrate 13, while being insulated from the transparent electrode 1 by the light-emitting functional layer 3. Thus, the organic EL element 100 is obtained.

After that, a sealing member 17 is disposed in such away as to cover at least the light-emitting functional layer 3 while exposing the terminal portions of the transparent electrode 1 and the counter electrode 5a of the organic EL element 100.

Thus, a desired organic EL element can be produced on a transparent substrate 13. In production of an organic EL element 100, it is preferable to produce layers from a light-emitting functional layer 3 to a counter electrode 5a altogether by one vacuum drawing. However, the transparent substrate 13 may be taken out from the vacuum atmosphere halfway and another forming method may be carried out. In this case, consideration should be given, for example, to doing works under a dry inert gas atmosphere.

In the case where a DC voltage is applied to the organic EL element 100 thus obtained, light emission can be observed by application of a voltage of 2 V to 40 V with the transparent electrode 1 as an anode being the positive polarity and the counter electrode 5a as a cathode being the negative polarity. Alternatively, an AC voltage may be applied thereto. The waveform of the AC voltage to be applied is arbitrary.

[Effects of Organic EL Element Shown as First Embodiment]

The above described organic EL element 100 uses the transparent electrode 1 of the present invention having both conductivity and optical transparency as an anode and is provided with the light-emitting functional layer 3 and the counter electrode 5a as a cathode on the upper side of the transparent electrode 1. Hence, the organic EL element 100 can emit light with high luminance by application of a sufficient voltage to between the transparent electrode 1 and the counter electrode 5a, have the luminesce increased by increase in extraction efficiency of emission light h from the transparent electrode 1 side and have emission lifetime extended by reduction in driving voltage for obtaining a desired luminance.

<<4. Second Embodiment of Organic EL Element>>

[Structure of Organic EL Element]

FIG. 4 is a cross sectional view showing the structure of a second embodiment of an organic EL element using the above described transparent electrode as an example of an electronic device of the present invention.

Difference between an organic EL element 200 of the second embodiment shown in FIG. 4 and the organic EL element 100 of the first embodiment shown in FIG. 3 is that the organic EL element 200 uses a transparent electrode 1 as a cathode. Detailed description about components which are the same as those of the first embodiment is not repeated, and components specific to the organic EL element 200 of the second embodiment are described below.

The organic EL element 200 shown in FIG. 4 is disposed on a transparent substrate 13, and as with the first embodiment, uses the above described transparent electrode 1 of the present invention as a transparent electrode 1 disposed on the transparent substrate 13. Hence, the organic EL element 200 is configured to extract emission light h at least from the transparent substrate 13 side. Note that the transparent electrode 1 is used as a cathode (negative pole), and a counter electrode 5b is used as an anode (positive pole).

The layer structure of the organic EL element 200 thus configured is not limited to the below described example and hence may be a general layer structure, which is the same as the first embodiment.

As an example of the layer structure for the second embodiment, there is shown a layer structure of an electron injection layer 3e, an electron transport layer 3d, a luminescent layer 3c, a positive hole transport layer 3b and a positive hole injection layer 3a stacked on the upper side of the transparent electrode 1, which functions as a cathode, in the order named. It is essential to have, among them, at least the luminescent layer 3c composed of an organic material.

In addition to these layers, as described in the first embodiment, in the light-emitting functional layer 3, various functional layers can be incorporated as needed. In the structure described above, only the portion where the light-emitting functional layer 3 is interposed between the transparent electrode 1 and the counter electrode 5b is a luminescent region in the organic EL element 200, which is also the same as the first embodiment.

Further, in the above described layer structure, in order to reduce resistance of the transparent electrode 1, an auxiliary electrode 15 may be disposed in contact with the conductive layer 1b of the transparent electrode 1, which is also the same as the first embodiment.

The counter electrode 5b used as an anode is composed of, for example, a metal, an alloy, an organic conductive compound, an inorganic conductive compound or a mixture of any of these. Examples thereof include: metals, such as gold (Au); copper iodide (CuI); and oxide semiconductors, such as ITO, ZnO, TiO₂ and SnO₂.

The counter electrode 5b composed of any of the above mentioned conductive materials can be produced by forming a thin film thereof by vapor deposition, sputtering or another method.

It is preferable that the sheet resistance of the counter electrode 5b be several hundred Ω/□ or less. The thickness is selected from normally a range of 5 nm to 5 μm, preferably a range of 5 nm to 200 nm.

In the case where the organic EL element 200 is configured to extract emission light h from the counter electrode 5b side too, as the material for the counter electrode 5b, a conductive material having excellent optical transparency to be used is selected from the above mentioned conductive materials.

The organic EL element 200 thus configured is, as with the first embodiment, sealed by a sealing member 17 in order to prevent deterioration of the light-emitting functional layer 3.

Detailed structures of the main layers constituting the above described organic EL element 200 except for the counter electrode 5b used as an anode and a production method of the organic EL element 200 are the same as those of the first embodiment. Hence, detailed description thereof is not repeated here.

[Effects of Organic EL Element Shown as Second Embodiment]

The above described organic EL element 200 shown in FIG. 4 uses the transparent electrode 1 of the present invention having both conductivity and optical transparency as a cathode and is provided with the light-emitting functional layer 3 and the counter electrode 5b as an anode on the upper side of the transparent electrode 1. Hence, as with the first embodiment, the organic EL element 200 can emit light with high luminance by application of a sufficient voltage to between the transparent electrode 1 and the counter electrode 5b, have the luminance increased by increase in extraction efficiency of emission light h from the transparent electrode 1 side and have emission lifetime extended by reduction in driving voltage for obtaining a predetermined luminance.

<<5. Third Embodiment of Organic EL Element>>

[Structure of Organic EL Element]

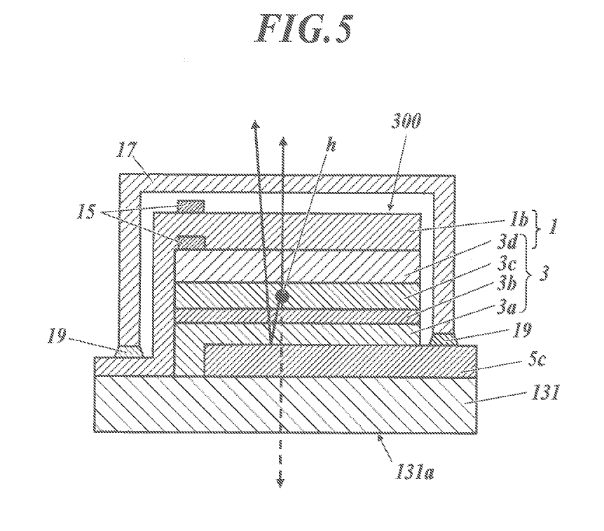

FIG. 5 is a cross sectional view showing the structure of a third embodiment of an organic EL element using the above described transparent electrode as an example of an electronic device of the present invention.

Difference between an organic EL element 300 of the third embodiment shown in FIG. 5 and the organic EL element 100 of the first embodiment described with reference to FIG. 3 is that the organic EL element 300 is provided with a counter electrode 5c disposed on a substrate 131 and also provided with a light-emitting functional layer 3 and a transparent electrode 1 which are stacked on the upper side of the counter electrode 5c in the order named. Detailed description about components which are the same as those of the first embodiment is not repeated, and components specific to the organic EL element 300 of the third embodiment are described below.

The organic EL element 300 shown in FIG. 5 is disposed on the substrate 131, and the counter electrode 5c as an anode, the light-emitting functional layer 3 and the transparent electrode 1 as a cathode are stacked on the substrate 131 in the order named. As the transparent electrode 1, the above described transparent electrode 1 of the present invention is used. Hence, the organic EL element 300 is configured to extract emission light h at least from the transparent electrode 1 side which is opposite to the substrate 131 side.

The layer structure of the organic EL element 300 thus configured is not limited to the below described example and hence may be a general layer structure, which is the same as the first embodiment. As an example thereof for the third embodiment, there is shown in FIG. 5 a layer structure of a positive hole injection layer 3a, a positive hole transport layer 3b, a luminescent layer 3c and an electron transport layer 3d stacked on the upper side of the counter electrode 5c, which functions as an anode, in the order named. It is essential to have, among them, at least the luminescent layer 3c made with an organic material. The electron transport layer 3d doubles as an electron injection layer 3e and accordingly is provided as an electron transport layer 3d having an electron injection property.

A component specific to the organic EL element 300 of the third embodiment is the electron transport layer 3d having the electron injection property being provided as an intermediate layer 1a of the transparent electrode 1. That is, in the third embodiment, the transparent electrode 1 used as a cathode is composed of the intermediate layer 1a, which doubles as the electron transport layer 3d having the electron injection property, and a conductive layer 1b disposed on the upper side thereof.

This electron transport layer 3d is made with any of the above mentioned materials for the intermediate layer 1a of the transparent electrode 1.

In addition to these layers, as described in the first embodiment, the light-emitting functional layer 3 can employ various functional layers as needed. However, there is no occasion where an electron injection layer or a positive hole block layer is disposed between the electron transport layer 3d, which doubles as the intermediate layer 1a of the transparent electrode 1, and the conductive layer 1b of the transparent electrode 1. In the structure described above, only the portion where the light-emitting functional layer 3 is interposed between the transparent electrode 1 and the counter electrode 5c is a luminescent region in the organic EL element 300, which is also the same as the first embodiment.

Further, in the above described layer structure, in order to reduce resistance of the transparent electrode 1, an auxiliary electrode 15 may be disposed in contact with the conductive layer 1b of the transparent electrode 1, which is also the same as the first embodiment.

The counter electrode 5c used as an anode is composed of, for example, a metal, an alloy, an organic conductive compound, an inorganic conductive compound or a mixture of any of these. Examples thereof include: metals, such as gold (Au); copper iodide (CuI); and oxide semiconductors, such as ITO, ZnO, TiO₂ and SnO₂.

The counter electrode 5c composed of any of the above mentioned conductive materials can be produced by forming a thin film thereof by vapor deposition, sputtering or another method.

It is preferable that the sheet resistance of the counter electrode 5c be several hundred Ω/□ or less. The thickness is selected from normally a range of 5 nm to 5 μm, preferably a range of 5 nm to 200 nm.

In the case where the organic EL element 300 is configured to extract emission light h from the counter electrode 5c side too, as the material for the counter electrode 5c, a conductive material having excellent optical transparency to be used is selected from the above mentioned conductive materials. Further, in this case, as the substrate 131, one which is the same as the transparent substrate 13 described in the first embodiment is used, and a face of the substrate 131 facing outside is a light extraction face 131a.

[Effects of Organic EL Element Shown as Third Embodiment]

The above described organic EL element 300 shown as the third embodiment is provided with: as the intermediate layer 1a, the electron transport layer 3d having the electron injection property and constituting the top portion of the light-emitting functional layer 3; and the conductive layer 1b on the upper side thereof, thereby being provided with, as a cathode, the transparent electrode 1 composed of the intermediate layer 1a and the conductive layer 1b on the upper side thereof. Hence, as with the first and second embodiments, the organic EL element 300 can emit light with high luminance by application of a sufficient voltage to between the transparent electrode 1 and the counter electrode 5c, have the luminance increased by increase in extraction efficiency of emission light h from the transparent electrode 1 side and have emission lifetime extended by reduction in driving voltage for obtaining a predetermined luminance. In the case where the counter electrode 5c is composed of an electrode material having optical transparency, emission light h can be extracted from the counter electrode 5c side too.

In the third embodiment, the intermediate layer 1a of the transparent electrode 1 doubles as the electron transport layer 3d having the electron injection property. However, the present invention is not limited to these illustrated components, and hence the intermediate layer 1a may double as an electron transport layer 3d not having the electron injection property or double not as an electron transport layer but as an electron injection layer. The intermediate layer 1a may be formed as a very thin film to the extent of not affecting the light emission function of an organic EL element. In this case, the intermediate layer 1a has neither the electron transport property nor the electron injection property.

In the case where the intermediate layer 1a of the transparent electrode 1 is formed as a very thin film to the extent of not affecting the light emission function of an organic EL element, a counter electrode on the substrate 131 and the transparent electrode 1 on the light-emitting functional layer 3 may be a cathode and an anode, respectively. In this case, the light-emitting functional layer 3 is composed of, for example, an electron injection layer 3e, an electron transport layer 3d, a luminescent layer 3c, a positive hole transport layer 3b and a positive hole injection layer 3a stacked on the counter electrode 5c (cathode) on the substrate 131 in the order named. Then, on the upper side thereof, the transparent electrode 1 having a multilayer structure of the very thin intermediate layer 1a and the conductive layer 1b is disposed as an anode.

<<6. Uses of Organic EL Elements>>

Each of the organic EL elements having the structures described above with reference to the figures is a surface emitting body as described above and hence can be used for various light sources. Examples thereof are not limited to but include illumination devices such as a household light and an interior light, backlights of a timepiece and a liquid crystal display device, a light of a billboard, a light source of a signal, a light source of an optical storage medium, a light source of an electrophotographic copier, a light source of a device for optical communication processing and a light source of an optical sensor. The organic EL element can be effectively used for, in particular, a backlight of a crystal liquid display device which is combined with a color filter or a light source of a light.

The organic EL element of the present invention may be used for a sort of lamp, such as a light source of a light or a light source for exposure, or may be used for a projection device which projects images or a direct-view display device (display) of still images and moving images. In this case, with recent increase in size of illumination devices and displays, a luminescent face may be enlarged by two-dimensionally connecting, namely, tiling, luminescent panels provided with organic EL elements thereof.

A driving system thereof used for a display device for moving image playback may be a simple matrix (passive matrix) system or an active matrix system. Further, use of two or more types of organic EL elements of the present invention having different luminescent colors enables production of a color or full-color display device.

Hereinafter, as examples of the uses, an illumination device and then an illumination device having a luminescent face enlarged by tiling are described.

<<7. Illumination Device—1>>

An illumination device of the present invention has the above described organic EL element of the present invention.

The organic EL element used for an illumination device of the present invention may be designed as an organic EL element having any one of the above described structures and a resonator structure. Although not limited thereto, the organic EL element configured to have a resonator structure is intended to be used for a light source of an optical storage medium, a light source of an electrophotographic copier, a light source of a device for optical communication processing and a light source of an optical sensor. The organic EL element may be used for the above mentioned uses by being configured to carry out laser oscillation.

The materials used for the organic EL element of the present invention are applicable to an organic EL element which emits substantially white light (also called a white organic EL element). For example, white light can be emitted by simultaneously emitting light of different luminescent colors with luminescent materials and mixing the luminescent colors. A combination of luminescent colors may be one containing three maximum emission wavelengths of three primary colors of red, green and blue or one containing two maximum emission wavelengths utilizing a relationship of complementary colors, such as blue and yellow or blue-green and orange.

A combination of luminescent materials to obtain a plurality of luminescent colors may be a combination of a plurality of phosphorescent or fluorescent materials or a combination of a phosphorescent or fluorescent material and a pigment material which emits light with light from the phosphorescent or fluorescent material as excitation light. In a white organic EL element, a plurality of luminescent dopants may be combined and mixed.

This kind of white organic EL element has a structure different from a structure to emit white light by apposing organic EL elements which emit light of different colors in an array form, and the white organic EL element itself emits white light. Hence, most of all the layers constituting the element do not require masks when formed. Consequently, for example, an electrode layer can be formed on the entire surface by vapor deposition, casting, spin coating, the inkjet method, printing or the like, and accordingly productivity increases.

The luminescent materials used for a luminescent layer(s) of this kind of white organic EL element are not particularly limited. For example, in the case of a backlight of a liquid crystal display element, materials therefor are suitably selected from the metal complexes of the present invention and the well-known luminescent materials to match a wavelength range corresponding to CF (color filter) characteristics and combined, thereby emitting white light.

Use of the above described white organic EL element enables production of an illumination device which emits substantially white light.

<<8. Illumination Device—2>>

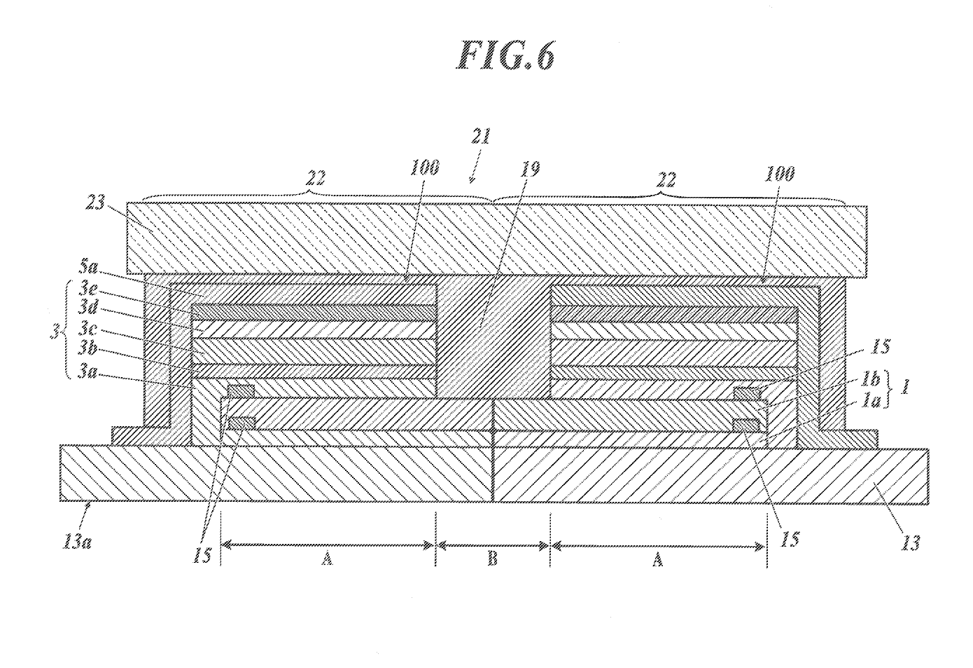

FIG. 6 is a cross sectional view showing the structure of an illumination device having a luminescent face enlarged by using a plurality of organic EL elements having any one of the above described structures.

An illumination device 21 shown in FIG. 6 has a luminescent face enlarged, for example, by arranging (i.e., tiling), on a support substrate 23, a plurality of luminescent panels 22 provided with organic EL elements 100 on transparent substrates 13. The support substrate 23 may double as a sealing member. The luminescent panels 22 are tiled in such a way that the organic EL elements 100 are interposed between the support substrate 23 and the transparent substrates 13 of the luminescent panels 22. The space between the support substrate 23 and the transparent substrates 13 is filled with an adhesive 19, whereby the organic EL elements 100 may be sealed.

The terminal portions of transparent electrodes 1 as anodes and counter electrodes 5a as cathodes are exposed on the peripheries of the luminescent panels 22. In the figure, only the exposed portions of the counter electrodes 5a are shown.

FIG. 6 shows, as an example of the structure of the light-emitting functional layer 3 which constitutes the organic EL element 100, a structure of a positive hole injection layer 3a, a positive hole transport layer 3b, a luminescent layer 3c, an electron transport layer 3d and an electron injection layer 3e stacked on the transparent electrode 1 in the order named.

In the illumination device 21 having the structure shown in FIG. 6, the center of each of the luminescent panels 22 is a luminescent region A, and a non-luminescent region B is generated between the luminescent panels 22. Hence, a light extraction member for increasing a light extraction amount from the non-luminescent region B may be disposed in the non-luminescent region B of a light extraction face 13a. As the light extraction member, a light condensing sheet or a light diffusing sheet can be used.

### EXAMPLES

Hereinafter, the present invention is detailed with Examples. However, the present invention is not limited thereto. Note that “%” used in Examples stands for “mass % (percent by mass)” unless otherwise specified.

<<Production of Transparent Electrodes>>

By the method described below, transparent electrodes 1 to 63 were each produced in such a way that the area of a conductive region was 5 cm×5 cm. The transparent electrodes 1 to 4 were each produced as a transparent electrode having a single-layer structure, and the transparent electrodes 5 to 63 were each produced as a transparent electrode having a multilayer structure of an intermediate layer(s) and a conductive layer.

[Production of Transparent Electrode 1]

By the method described below, the transparent electrode 1 having a single-layer structure was produced as a comparative example.

A base composed of transparent alkali-free glass was fixed to a base holder of a commercial vacuum deposition device, and the base holder was mounted in a vacuum tank of the vacuum deposition device. Meanwhile, a tungsten resistive heating boat was filled with silver (Ag), and the heating boat was mounted in the vacuum tank. Next, after the pressure of the vacuum tank was reduced to 4×10⁻⁴ Pa, the resistive heating boat was electrically heated, and a conductive layer composed of silver having a thickness of 5 μm of a single layer was formed on the base by vapor deposition at a deposition rate of 0.1 nm/sec to 0.2 nm/sec. Thus, the transparent electrode 1 was produced.

[Production of Transparent Electrodes 2 to 4]

The transparent electrodes 2 to 4 were produced in the same way as the transparent electrode 1, except that the thickness of the conductive layer was changed to 8 nm, 10 nm and 15 nm, respectively.

[Production of Transparent Electrode 5]

On a base composed of transparent alkali-free glass, Alq₃ the structure of which is shown below was deposited by sputtering to form an intermediate layer having a thickness of 25 nm, and on the upper side thereof, a conductive layer composed of silver (Ag) having a thickness of 8 nm was formed by the same method (vacuum deposition) as that used for forming the conductive layer in producing the transparent electrode 1. Thus, the transparent electrode 5 was produced.

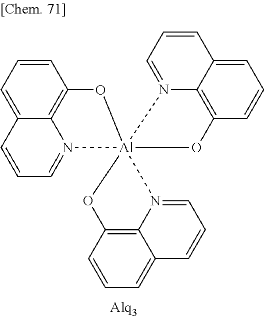

[Production of Transparent Electrode 6]

A base composed of transparent alkali-free glass was fixed to a base holder of the commercial vacuum deposition device, a tantalum resistive heating boat was filled with ET-1 the structure of which is shown below, and the base holder and the heating boat were mounted in a first vacuum tank of the vacuum deposition device. In addition, silver (Ag) was placed in a tungsten resistive heating boat, and the heating boat was mounted in a second vacuum tank.

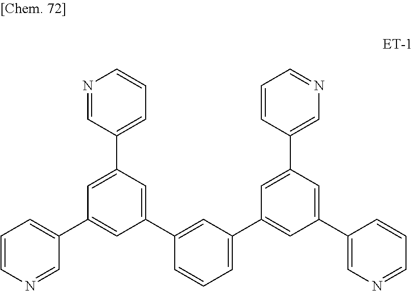 [SMILES: c1cncc(-c2cc(-c3cccnc3)cc(-c3cccc(-c4cc(-c5cccnc5)cc(-c5cccnc5)c4)c3)c2)c1]

Next, after the pressure of the first vacuum tank was reduced to 4×10⁻⁴ Pa, the heating boat having ET-1 therein was electrically heated, and an intermediate layer composed of ET-1 having a thickness of 25 nm was formed on the base at a deposition rate of 0.1 nm/sec to 0.2 nm/sec.

Next, the base on which the intermediate layer had been formed was transferred to the second vacuum tank, keeping its vacuum state. After the pressure of the second vacuum tank was reduced to 4×10⁻⁴ Pa, the heating boat having silver therein was electrically heated, and a conductive layer composed of silver having a thickness of 8 nm was formed at a deposition rate of 0.1 nm/sec to 0.2 nm/sec. Thus, the transparent electrode 6 having a multilayer structure of the intermediate layer and the conductive layer, which was composed of silver, on the upper side thereof was obtained.

[Production of Transparent Electrodes 7 and 8]

The transparent electrodes 7 and 8 were produced in the same way as the transparent electrode 6, except that the type of the material for forming the intermediate layer was changed from ET-1 to ET-2 and ET-3, respectively, the structures of which are shown below.

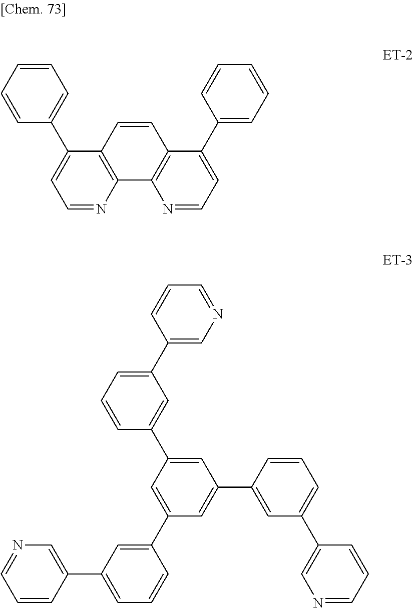 [SMILES: c1ccc(-c2ccnc3c2ccc2c(-c4ccccc4)ccnc23)cc1 ; c1cncc(-c2cccc(-c3cc(-c4cccc(-c5cccnc5)c4)cc(-c4cccc(-c5cccnc5)c4)c3)c2)c1]

[Production of Transparent Electrodes 9 to 55]

The transparent electrodes 9 to 55 were produced in the same way as the transparent electrode 6, except that the type of the material for forming the intermediate layer and the thickness of the silver layer of the conductive layer were changed to those shown in TABLE 1 and TABLE 2.

[Production of Transparent Electrodes 56 to 58]

The transparent electrodes 56 to 58 were produced in the same way as the transparent electrodes 50, 28 and 29, respectively, except that the type of the base was changed from alkali-free glass to PET (polyethylene terephthalate).

[Production of Transparent Electrode 59]

A base composed of transparent alkali-free glass was fixed to a base holder of the commercial vacuum deposition device, a tantalum resistive heating boat was filled with the compound S-1, and the base holder and the heating boat were mounted in the first vacuum tank of the vacuum deposition device. In addition, silver (Ag) was placed in a tungsten resistive heating boat, and the heating boat was mounted in the second vacuum tank.

Next, after the pressure of the first vacuum tank was reduced to 4×10⁻⁴ Pa, the heating boat having the compound S-1 therein was electrically heated, and an intermediate layer 1a composed of the compound S-1 having a thickness of 25 nm was formed on the base at a deposition rate of 0.1 nm/sec to 0.2 nm/sec.

Next, the base on which the intermediate layer 1a had been formed was transferred to the second vacuum tank, keeping its vacuum state. After the pressure of the second vacuum tank was reduced to 4×10⁻⁴ Pa, the heating boat having silver therein was electrically heated, and a conductive layer 1b composed of silver having a thickness of 8 nm was formed at a deposition rate of 0.1 nm/sec to 0.2 nm/sec.

Next, the base over which the conductive layer 1b had been formed was transferred to the first vacuum tank, keeping its vacuum state. After the pressure of the first vacuum tank was reduced to 44×10⁻⁴ Pa, the heating boat having the compound S-1 therein was electrically heated, and a second intermediate layer 1c composed of the compound S-1 having a thickness of 15 nm was formed over the base at a deposition rate of 0.1 nm/sec to 0.2 nm/sec.

Thus, the transparent electrode 59 having a multilayer structure in which the conductive layer 1b composed of silver was disposed on the upper side of the intermediate layer 1a composed of the compound S-1, and the second intermediate layer 1c composed of the compound S-1 was disposed on the upper side of the conductive layer 1b was obtained.

[Production of Transparent Electrodes 60 to 63]

The transparent electrodes 60 to 63 were produced in the same way as the transparent electrode 59, except that the material for forming the intermediate layers 1a and 1c was changed to the compounds shown in TABLE 2.

<<Evaluation of Transparent Electrodes>>

With respect to each of the produced transparent electrodes 1 to 63, light transmittance, sheet resistance and sheet resistance variation in high temperature storage were measured by the methods described below.

[Light Transmittance Measurement]

With respect to each of the produced transparent electrodes, light transmittance (%) at a wavelength of 550 nm was measured with a spectrophotometer (U-3300 manufactured by Hitachi, Ltd.) with the base which was used for producing each of the transparent electrodes as a reference.

[Sheet Resistance Measurement]

With respect to each of the produced transparent electrodes, sheet resistance (Ω/□) was measured with a resistivity meter (MCP-T610 manufactured by Mitsubishi Chemical Corporation) by the 4-terminal method, 4-pin probe method and constant-current method.

[Sheet Resistance Variation (Sheet Resistance Variation Rate) in High Temperature Storage]

With respect to each of the produced transparent electrodes, a sheet resistance variation rate was measured as follows; each transparent electrode was kept at 120° C. in the air for 300 hours.

Sheet Resistance Variation Rate=(Initial Sheet Resistance−After-300-Hours Sheet Resistance)/Initial Sheet Resistance×100

The sheet resistance variation rate of each transparent electrode is shown as a relative value with the variation rate of the transparent electrode 8 as 100.

The obtained result is shown in TABLE 1 and TABLE 2.

TABLE 1-1

| | STRUCTURE OF TRANSPARENT ELECTRODE (FIG. 1 OR FIG. 2) | | | | | | | | | | |
|---|---|---|---|---|---|---|---|---|---|---|---|
| | | INTERMEDIATE | | CONDUCTIVE | | INTERMEDIATE | | EVALUATION RESULT | | | |
| | | LAYER 1a | | LAYER 1b | | LAYER 1c | | | | SHEET RESISTANCE | |
| | | | THICK- | | THICK- | | THICK- | | SHEET | VARIATION RATE IN | |
| | | | NESS | | NESS | | NESS | | RESISTANCE | HIGH TEMPERATURE | |
| *1 | BASE | MATERIAL | [nm] | MATERIAL | [nm] | MATERIAL | [nm] | *3 | [Ω/□] | STORAGE | REMARK |
| 1 | *2 | — | — | Ag | 5 | — | — | 30 | UNMEASURABLE | UNMEASURABLE | *4 |
| 2 | *2 | — | — | Ag | 8 | — | — | 45 | 512 | UNMEASURABLE | *4 |
| 3 | *2 | — | — | Ag | 10 | — | — | 38 | 41 | UNMEASURABLE | *4 |
| 4 | *2 | — | — | Ag | 15 | — | — | 22 | 10 | UNMEASURABLE | *4 |
| 5 | *2 | Alq₃ | 25 | Ag | 8 | — | — | 46 | 212 | 127 | *4 |
| 6 | *2 | ET-1 | 25 | Ag | 8 | — | — | 47 | 45 | 153 | *4 |
| 7 | *2 | ET-2 | 25 | Ag | 8 | — | — | 49 | 35 | 145 | *4 |
| 8 | *2 | ET-3 | 25 | Ag | 8 | — | — | 49 | 25 | 100 | *4 |
| 9 | *2 | S-1 | 25 | Ag | 5 | — | — | 66 | 10.2 | 78 | *5 |
| 10 | *2 | S-1 | 25 | Ag | 8 | — | — | 68 | 7.3 | 65 | *5 |
| 11 | *2 | S-1 | 25 | Ag | 10 | — | — | 58 | 8.2 | 87 | *5 |
| 12 | *2 | S-1 | 25 | Ag | 20 | — | — | 52 | 8.2 | 80 | *5 |
| 13 | *2 | 1-1 | 25 | Ag | 8 | — | — | 72 | 7.1 | 50 | *5 |
| 14 | *2 | 1-4 | 25 | Ag | 8 | — | — | 71 | 7.0 | 50 | *5 |
| 15 | *2 | 1-8 | 25 | Ag | 8 | — | — | 70 | 6.9 | 51 | *5 |

*1: TRANSPARENT ELECTRODE NO.
*2: ALKALI-FREE GLASS
*3: LIGHT TRANSMITTANCE[550 nm][%]
*4: COMPARATIVE EXAMPLE
*5: PRESENT INVENTION

TABLE 1-2

| | STRUCTURE OF TRANSPARENT ELECTRODE (FIG. 1 OR FIG. 2) | | | | | | | | | | |
|---|---|---|---|---|---|---|---|---|---|---|---|
| | | INTERMEDIATE | | CONDUCTIVE | | INTERMEDIATE | | EVALUATION RESULT | | | |
| | | LAYER 1a | | LAYER 1b | | LAYER 1c | | | | SHEET RESISTANCE | |
| | | | THICK- | | THICK- | | THICK- | | SHEET | VARIATION RATE IN | |
| | | | NESS | | NESS | | NESS | | RESISTANCE | HIGH TEMPERATURE | |
| *1 | BASE | MATERIAL | [nm] | MATERIAL | [nm] | MATERIAL | [nm] | *3 | [Ω/□] | STORAGE | REMARK |
| 16 | *2 | 1-9 | 25 | Ag | 8 | — | — | 71 | 7.2 | 50 | *4 |
| 17 | *2 | 2-1 | 25 | Ag | 8 | — | — | 79 | 6.9 | 41 | *4 |
| 18 | *2 | 2-3 | 25 | Ag | 8 | — | — | 78 | 6.9 | 40 | *4 |
| 19 | *2 | 2-4 | 25 | Ag | 8 | — | — | 77 | 6.8 | 41 | *4 |
| 20 | *2 | 2-14 | 25 | Ag | 8 | — | — | 79 | 6.9 | 41 | *4 |
| 21 | *2 | 2-27 | 25 | Ag | 8 | — | — | 78 | 6.9 | 42 | *4 |
| 22 | *2 | 2-36 | 25 | Ag | 8 | — | — | 79 | 7.0 | 42 | *4 |
| 23 | *2 | 2-48 | 25 | Ag | 8 | — | — | 78 | 6.9 | 41 | *4 |
| 24 | *2 | 2-64 | 25 | Ag | 8 | — | — | 79 | 6.8 | 40 | *4 |
| 25 | *2 | 2-73 | 25 | Ag | 8 | — | — | 78 | 6.9 | 40 | *4 |
| 26 | *2 | 2-79 | 25 | Ag | 8 | — | — | 79 | 7.0 | 41 | *4 |
| 27 | *2 | 3-1 | 25 | Ag | 8 | — | — | 80 | 6.5 | 35 | *4 |
| 28 | *2 | 3-2 | 25 | Ag | 8 | — | — | 82 | 4.5 | 22 | *4 |
| 29 | *2 | 3-3 | 25 | Ag | 8 | — | — | 83 | 3.3 | 12 | *4 |
| 30 | *2 | 3-5 | 25 | Ag | 8 | — | — | 82 | 4.8 | 30 | *4 |
| 31 | *2 | 3-37 | 25 | Ag | 8 | — | — | 83 | 5.2 | 28 | *4 |

*1: TRANSPARENT ELECTRODE NO.
*2: ALKALI-FREE GLASS
*3: LIGHT TRANSMITTANCE[550 nm][%]
*4: PRESENT INVENTION

TABLE 2-1

| | STRUCTURE OF TRANSPARENT ELECTRODE (FIG. 1 OR FIG. 2) | | | | | | | | | | |
|---|---|---|---|---|---|---|---|---|---|---|---|
| | | INTERMEDIATE | | CONDUCTIVE | | INTERMEDIATE | | EVALUATION RESULT | | | |
| | | LAYER 1a | | LAYER 1b | | LAYER 1c | | | | SHEET RESISTANCE | |
| | | | THICK- | | THICK- | | THICK- | | SHEET | VARIATION RATE IN | |
| | | | NESS | | NESS | | NESS | | RESISTANCE | HIGH TEMPERATURE | |
| #1 | BASE | MATERIAL | [nm] | MATERIAL | [nm] | MATERIAL | [nm] | *3 | [Ω/□] | STORAGE | REMARK |
| 32 | *2 | 3-43 | 25 | Ag | 8 | — | — | 81 | 3.8 | 16 | *4 |
| 33 | *2 | 3-67 | 25 | Ag | 8 | — | — | 82 | 6.0 | 20 | *4 |
| 34 | *2 | 3-86 | 25 | Ag | 8 | — | — | 81 | 5.5 | 22 | *4 |
| 35 | *2 | 3-87 | 25 | Ag | 8 | — | — | 82 | 4.5 | 34 | *4 |
| 36 | *2 | 3-105 | 25 | Ag | 8 | — | — | 83 | 3.8 | 28 | *4 |
| 37 | *2 | 3-127 | 25 | Ag | 8 | — | — | 81 | 6.2 | 18 | *4 |
| 38 | *2 | 3-143 | 25 | Ag | 8 | — | — | 81 | 5.3 | 16 | *4 |
| 39 | *2 | 3-154 | 25 | Ag | 8 | — | — | 82 | 6.4 | 20 | *4 |
| 40 | *2 | 3-173 | 25 | Ag | 8 | — | — | 83 | 4.4 | 25 | *4 |
| 41 | *2 | 3-183 | 25 | Ag | 8 | — | — | 83 | 4.2 | 19 | *4 |
| 42 | *2 | 3-200 | 25 | Ag | 8 | — | — | 82 | 3.9 | 34 | *4 |
| 43 | *2 | 3-204 | 25 | Ag | 8 | — | — | 81 | 3.5 | 32 | *4 |
| 44 | *2 | 3-214 | 25 | Ag | 8 | — | — | 83 | 5.5 | 26 | *4 |
| 45 | *2 | 3-254 | 25 | Ag | 8 | — | — | 82 | 5.5 | 35 | *4 |
| 46 | *2 | 3-255 | 25 | Ag | 8 | — | — | 80 | 4.4 | 28 | *4 |

*1: TRANSPARENT ELECTRODE NO.
*2: ALKALI-FREE GLASS
*3: LIGHT TRANSMITTANCE[550 nm][%]
*4: PRESENT INVENTION

TABLE 2-2

| | STRUCTURE OF TRANSPARENT ELECTRODE (FIG. 1 OR FIG. 2) | | | | | | | | | | |
|---|---|---|---|---|---|---|---|---|---|---|---|
| | | INTERMEDIATE | | CONDUCTIVE | | INTERMEDIATE | | EVALUATION RESULT | | | |
| | | LAYER 1a | | LAYER 1b | | LAYER 1c | | | | SHEET RESISTANCE | |
| | | | THICK- | | THICK- | | THICK- | | SHEET | VARIATION RATE IN | |
| | | | NESS | | NESS | | NESS | | RESISTANCE | HIGH TEMPERATURE | |
| *1 | BASE | MATERIAL | [nm] | MATERIAL | [nm] | MATERIAL | [nm] | *3 | [Ω/□] | STORAGE | REMARK |
| 47 | *2 | 3-256 | 25 | Ag | 8 | — | — | 82 | 3.8 | 30 | *4 |
| 48 | *2 | 3-258 | 25 | Ag | 8 | — | — | 81 | 6.0 | 27 | *4 |
| 49 | *2 | 3-264 | 25 | Ag | 8 | — | — | 81 | 4.6 | 34 | *4 |
| 50 | *2 | 4-1 | 25 | Ag | 8 | — | — | 81 | 5.5 | 30 | *4 |
| 51 | *2 | 4-3 | 25 | Ag | 8 | — | — | 80 | 5.4 | 29 | *4 |
| 52 | *2 | 4-8 | 25 | Ag | 8 | — | — | 81 | 5.2 | 31 | *4 |
| 53 | *2 | 4-16 | 25 | Ag | 8 | — | — | 81 | 5.7 | 32 | *4 |
| 54 | *2 | 4-18 | 25 | Ag | 8 | — | — | 79 | 6.0 | 28 | *4 |
| 55 | PET | 4-22 | 25 | Ag | 8 | — | — | 79 | 5.6 | 29 | *4 |
| 56 | PET | 4-1 | 25 | Ag | 8 | — | — | 79 | 5.6 | 32 | *4 |
| 57 | PET | 3-2 | 25 | Ag | 8 | — | — | 80 | 4.6 | 24 | *4 |
| 58 | PET | 3-3 | 25 | Ag | 8 | — | — | 81 | 3.5 | 14 | *4 |
| 59 | *2 | S-1 | 25 | Ag | 8 | S-1 | 15 | 85 | 4.0 | 14 | *4 |
| 60 | *2 | 1-1 | 25 | Ag | 8 | 1-1 | 15 | 84 | 3.5 | 15 | *4 |
| 61 | *2 | 2-1 | 25 | Ag | 8 | 2-1 | 15 | 86 | 3.3 | 16 | *4 |
| 62 | *2 | 3-1 | 25 | Ag | 8 | 3-1 | 15 | 87 | 3.5 | 16 | *4 |
| 63 | *2 | 4-1 | 25 | Ag | 8 | 4-1 | 15 | 85 | 3.5 | 17 | *4 |

*1: TRANSPARENT ELECTRODE NO.
*2: ALKALI-FREE GLASS
*3: LIGHT TRANSMITTANCE[550 nm][%]
*4: PRESENT INVENTION

As it is obvious from the result shown in TABLE 1 and TABLE 2, all the transparent electrodes 9 to 58 of the present invention, the transparent electrodes 9 to 58 in each of which the conductive layer composed of silver (Ag) as a main component was disposed on the intermediate layer formed with the organic compound containing a sulfur atom(s) having an unshared electron pair, had a light transmittance of 52% or more and a sheet resistance of 10.2Ω/□ or less. Further, the sheet resistance variation rate in high temperature storage was 80.

This is considered that the intermediate layer formed with the organic compound containing a sulfur atom(s) having an unshared electron pair kept the silver layer formed thereon from cohering and mottles from being generated, and consequently even when the silver layer having a thickness of certain degree was formed, silver was kept from cohering, and high optical transparency, low sheet resistance and small sheet resistance variation in high temperature storage were achieved.

Further, it was confirmed that the transparent electrodes 59 to 63 each having the structure in which the conductive layer was interposed between two intermediate layers achieved more favorite result.

On the other hand, with respect to the transparent electrodes 1 to 4 as comparative examples having no intermediate layer, although the sheet resistance decreased as the conductive layer being the silver layer was thicker, the light transmittance significantly decreased by silver cohesion (mottles) which occurred when the conductive layer was formed, and consequently the optical transparency and the sheet resistance were not achieved together. Further, the sheet resistance variation rate in high temperature storage was unmeasurable.

The transparent electrodes 5 to 8 respectively using Alq₃, ET-1, ET-2 and ET-3 for their intermediate layers also had low light transmittance and sheet resistance which was not as low as a desired condition. Further, the sheet resistance variation rate in high temperature storage was 100 or more, which is large.

### Second Example

### Production of Luminescent Panels

[Production of Luminescent Panel 1]

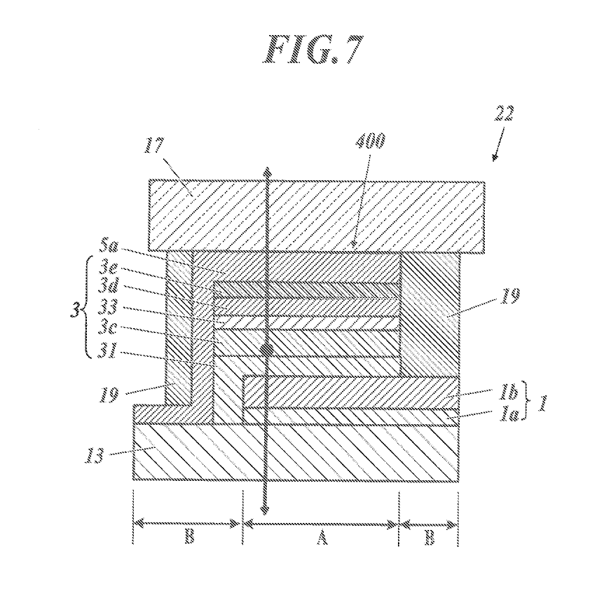

A top-and-bottom emission type luminescent panel 1 having the structure (but having no intermediate layer 1a) shown in FIG. 7 was produced through the procedure described below by using, as an anode, the transparent electrode 1 produced in First Example.

First, a transparent substrate 13 having the transparent electrode 1 formed of only the conductive layer 1b produced in First Example was fixed to a substrate holder of a commercial vacuum deposition device, and a vapor deposition mask was disposed in such a way as to face a formation face of the transparent electrode 1 (conductive layer 1b only). Further, heating boats in the vacuum deposition device were filled with materials for respective layers constituting a light-emitting functional layer 3 at their respective amounts optimal to form the layers. The heating boats used were composed of a tungsten material for resistance heating.

Next, the pressure of a vapor deposition room of the vacuum deposition device was reduced to 4×10⁻⁴ Pa, and the heating boats having the respective materials therein were electrically heated successively so that the layers, described below, constituting the light-emitting functional layer 3 were formed.

First, the heating boat having therein α-NPD shown below as a positive hole transport/injection material was electrically heated, and a positive hole transport•injection layer 31 composed of α-NPD and functioning as both a positive hole injection layer and a positive hole transport layer was formed on the conductive layer 1b of the transparent electrode 1. At the time, the deposition rate was within a range from 0.1 nm/sec to 0.2 nm/sec, and vapor deposition was carried out under a condition that the thickness became 20 nm.

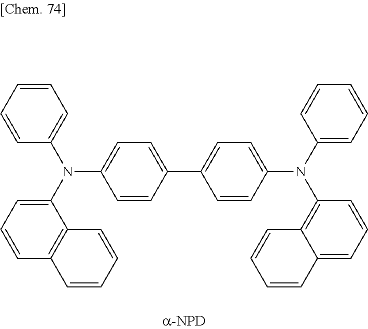 [SMILES: c1ccc(N(c2ccc(-c3ccc(N(c4ccccc4)c4cccc5ccccc45)cc3)cc2)c2cccc3ccccc23)cc1]

Next, the heating boat having therein the illustrated compound H4 as a host compound and the heating boat having therein the illustrated compound Ir-4 as a phosphorescent compound were independently electrified, and a luminescent layer 3c composed of the illustrated compound H4 as a host compound and the illustrated compound Ir-4 as a phosphorescent compound was formed on the positive hole transport•injection layer 31. At the time, under a condition that the deposition rate (nm/sec) of the illustrated compound H4:the deposition rate (nm/sec) of the illustrated compound Ir-4=100:6 held, electrification conditions of the heating boats were suitably adjusted so that the thickness of the luminescent layer became 30 nm.

Next, the heating boat having therein BAlq shown below as a positive hole block material was electrically heated, and a positive hole block layer 33 composed of BAlq was formed on the luminescent layer 3c. At the time, the deposition rate was within a range from 0.1 nm/sec to 0.2 nm/sec, and vapor deposition was carried out under a condition that the thickness became 10 nm.

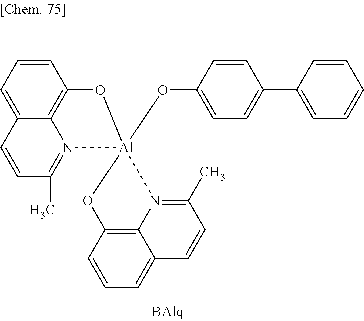

After that, the heating boats having therein ET-4 shown below and potassium fluoride, respectively, as electron transport materials were independently electrified, and an electron transport layer 3d composed of ET-4 and potassium fluoride was formed on the positive hole block layer 33. At the time, under a condition that the deposition rate (nm/sec) of ET-4:the deposition rate (nm/sec) of potassium fluoride=75:25 held, electrification conditions of the heating boats were suitably adjusted so that vapor deposition was carried out in such a way that the thickness of the electron transport layer 3d became 30 nm.

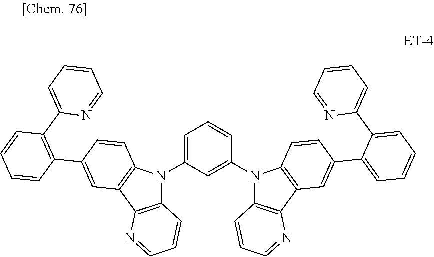 [SMILES: c1ccc(-c2ccccc2-c2ccc3c(c2)c2ncccc2n3-c2cccc(-n3c4ccc(-c5ccccc5-c5ccccn5)cc4c4ncccc43)c2)nc1]

Next, the heating boat having therein potassium fluoride as an electron injection material was electrically heated, and an electron injection layer 3e composed of potassium fluoride was formed on the electron transport layer 3d. At the time, the deposition rate was within a range from 0.01 nm/sec to 0.02 nm/sec, and vapor deposition was carried out in such a way that the thickness became 1 nm.

After that, the transparent substrate 13 on which the layers up to the electron injection layer 3e had been formed was transferred from the vapor deposition room of the vacuum deposition device into a treatment room of a sputtering device, the treatment room in which an ITO target as a counter electrode material had been placed, keeping its vacuum state. Next, in the treatment room, an optically transparent counter electrode 5a composed of ITO having a thickness of 150 nm was formed at a deposition rate of 0.3 nm/sec to 0.5 nm/sec as a cathode.

Thus, an organic EL element 400 was formed on the transparent substrate 13.

Next, the organic EL element 400 was covered with a sealing member 17 composed of a glass substrate having a thickness of 300 μm, and the space between the sealing member 17 and the transparent substrate 13 was filled with an adhesive 19 (a seal material) in such a way that the organic EL element 400 was enclosed. As the adhesive 19, an epoxy-based photo-curable adhesive (LUXTRAK LC0629B produced by Toagosei Co., Ltd.) was used. The adhesive 19, with which the space between the sealing member 17 and the transparent substrate 13 was filled, was irradiated with UV light from the glass substrate (sealing member 17) side, thereby being cured, so that the organic EL element 400 was sealed.

In forming the organic EL element 400, a vapor deposition mask was used for forming each layer so that the center having an area of 4.5 cm×4.5 cm of the transparent substrate 13 having an area of 5 cm×5 cm became a luminescent region A, and a non-luminescent region B having a width of 0.25 cm was provided all around the luminescent region A. Further, the transparent electrode 1 as an anode and the counter electrode 5a as a cathode were formed in shapes of leading to the periphery of the transparent substrate 13, their terminal portions being on the periphery of the transparent substrate 13, while being insulated from each other by the light-emitting functional layer 3 composed of the layers from the positive hole transport injection layer 31 to the electron injection layer 35.

Thus, the luminescent panel 1, in which the organic EL element 400 was disposed on the transparent substrate 13 and sealed by the sealing member 17 and with the adhesive 19, was produced. The luminescent panel 1 was configured to extract emission light h of colors generated in the luminescent layer 3c from both the transparent electrode 1 side, namely, the transparent substrate 13 side, and the counter electrode 5a side, namely, the sealing member 17 side.

[Production of Luminescent Panels 2 to 63]

Luminescent panels 2 to 63 were produced in the same way as the luminescent panel 1, except that, instead of the transparent electrode 1, the transparent electrodes 2 to 63 produced in First Example were used, respectively.

<<Evaluation of Luminescent Panels>>

With respect to each of the produced luminescent panels 1 to 63, light transmittance and driving voltage were measured by the methods described below.

[Light Transmittance Measurement]

With respect to each of the produced luminescent panels, light transmittance (%) at a wavelength of 550 nm was measured with a spectrophotometer (U-3300 manufactured by Hitachi, Ltd.) with the base which was used for producing each of the transparent electrodes as a reference.

[Driving Voltage Measurement]

Front luminance was measured on both the transparent electrode 1 side (i.e., transparent substrate 13 side) and the counter electrode 5a side (i.e., sealing member 17 side) of each of the produced luminescent panels, and a voltage of the time when the sum thereof was 1000 cd/m² was determined as the driving voltage (V). The luminance was measured with a spectroradiometer CS-1000 (manufactured by Konica Minolta Inc.). The smaller the obtained value of the driving voltage is, the more favorable result it means.

[Voltage Variation Under Constant Current]

Each of the produced luminescent panels performed continuous light emission at room temperature under a constant current condition of 2.5 mA/cm². A voltage of the time when a time (τ½) required for luminance to be a half of the initial luminance was reached was compared with the initial voltage. The variation amount (increased value) is shown as a relative value with the measured value of the luminescent panel 8 as 100.

The obtained result is shown in TABLE 3 and TABLE 4.

TABLE 3

| LUMINESCENT | TRANSPARENT | LIGHT TRANSMITTANCE | DRIVING | | |
|---|---|---|---|---|---|
| PANEL NO. | ELECTRODE NO. | [550 nm][%] | VOLTAGE[V] | *1 | REMARK |
| 1 | 1 | 24 | *2 | — | *3 |
| 2 | 2 | 36 | *2 | — | *3 |
| 3 | 3 | 30 | 5.0 | 455 | *3 |
| 4 | 4 | 18 | 3.5 | 334 | *3 |
| 5 | 5 | 43 | 4.4 | 135 | *3 |
| 6 | 6 | 45 | 4.2 | 155 | *3 |
| 7 | 7 | 46 | 4.2 | 125 | *3 |
| 8 | 8 | 48 | 4.1 | 100 | *3 |
| 9 | 9 | 60 | 3.5 | 73 | *4 |
| 10 | 10 | 63 | 3.4 | 67 | *4 |
| 11 | 11 | 54 | 3.3 | 69 | *4 |
| 12 | 12 | 51 | 3.2 | 75 | *4 |
| 13 | 13 | 68 | 3.2 | 55 | *4 |
| 14 | 14 | 69 | 3.2 | 54 | *4 |
| 15 | 15 | 68 | 3.3 | 56 | *4 |
| 16 | 16 | 68 | 3.1 | 55 | *4 |
| 17 | 17 | 75 | 3.2 | 51 | *4 |
| 18 | 18 | 76 | 3.2 | 50 | *4 |
| 19 | 19 | 74 | 3.1 | 51 | *4 |
| 20 | 20 | 76 | 3.2 | 52 | *4 |
| 21 | 21 | 75 | 3.2 | 50 | *4 |
| 22 | 22 | 75 | 3.2 | 50 | *4 |
| 23 | 23 | 74 | 3.1 | 51 | *4 |
| 24 | 24 | 73 | 3.1 | 51 | *4 |
| 25 | 25 | 74 | 3.1 | 52 | *4 |
| 26 | 26 | 75 | 3.2 | 51 | *4 |
| 27 | 27 | 77 | 3.1 | 45 | *4 |
| 28 | 28 | 79 | 3.1 | 33 | *4 |
| 29 | 29 | 80 | 3.0 | 22 | *4 |
| 30 | 30 | 77 | 3.1 | 40 | *4 |
| 31 | 31 | 79 | 3.0 | 38 | *4 |

*1: VOLTAGE VARIATION UNDER CONSTANT CURRENT
*2: NO LIGHT EMITTED
*3: COMPARATIVE EXAMPLE
*4: PRESENT INVENTION

TABLE 4

| LUMINESCENT | TRANSPARENT | LIGHT TRANSMITTANCE | DRIVING | | |
|---|---|---|---|---|---|
| PANEL NO. | ELECTRODE NO. | [550 nm][%] | VOLTAGE[V] | *1 | REMARK |
| 32 | 32 | 78 | 3.0 | 28 | *2 |
| 33 | 33 | 79 | 3.0 | 35 | *2 |
| 34 | 34 | 79 | 3.0 | 35 | *2 |
| 35 | 35 | 78 | 3.0 | 34 | *2 |
| 36 | 36 | 78 | 3.0 | 36 | *2 |
| 37 | 37 | 79 | 3.1 | 29 | *2 |
| 38 | 38 | 79 | 3.1 | 29 | *2 |
| 39 | 39 | 77 | 3.1 | 28 | *2 |
| 40 | 40 | 78 | 3.0 | 30 | *2 |
| 41 | 41 | 78 | 3.1 | 32 | *2 |
| 42 | 42 | 78 | 3.2 | 34 | *2 |
| 43 | 43 | 79 | 3.1 | 35 | *2 |
| 44 | 44 | 79 | 3.1 | 30 | *2 |
| 45 | 45 | 77 | 3.2 | 35 | *2 |
| 46 | 46 | 79 | 3.1 | 30 | *2 |
| 47 | 47 | 79 | 3.2 | 36 | *2 |
| 48 | 48 | 80 | 3.2 | 29 | *2 |
| 49 | 49 | 81 | 3.2 | 34 | *2 |
| 50 | 50 | 81 | 3.1 | 39 | *2 |
| 51 | 51 | 79 | 3.0 | 38 | *2 |
| 52 | 52 | 77 | 3.1 | 40 | *2 |
| 53 | 53 | 78 | 3.0 | 40 | *2 |
| 54 | 54 | 78 | 3.1 | 39 | *2 |
| 55 | 55 | 79 | 3.1 | 39 | *2 |
| 56 | 56 | 75 | 3.1 | 40 | *2 |
| 57 | 57 | 76 | 3.1 | 35 | *2 |
| 58 | 58 | 77 | 3.0 | 25 | *2 |
| 59 | 59 | 85 | 3.0 | 25 | *2 |
| 60 | 60 | 84 | 2.9 | 24 | *2 |
| 61 | 61 | 86 | 2.9 | 24 | *2 |
| 62 | 62 | 87 | 3.0 | 25 | *2 |
| 63 | 63 | 87 | 3.0 | 25 | *2 |

*1: VOLTAGE VARIATION UNDER CONSTANT CURRENT
*2: PRESENT INVENTION

As it is obvious from the result shown in TABLE 3 and TABLE 4, all the luminescent panels 9 to 63 of the present invention each using the transparent electrode 1 of the present invention as an anode of the organic EL element had a light transmittance of 51% or more and a driving voltage of 3.5 V or less. Further, the voltage variation under constant current was 75 or less.

On the other hand, all the luminescent panels 1 to 8 each using the transparent electrode of the comparative example as an anode of the organic EL element had a light transmittance of less than 48%, and some of them did not emit light even when a voltage was applied or emitted light with a high driving voltage of 5.0 V. Further, the voltage variation under constant current was very large.

Thus, it was confirmed that the organic EL elements each using the transparent electrode having the structure defined by the present invention had excellent optical transparency, low driving voltage and small voltage variation under constant current.

### INDUSTRIAL APPLICABILITY

As described above, the present invention is suitable to provide: a transparent electrode having high optical transparency, low sheet resistance and small sheet resistance variation in high temperature storage; and an electronic device and an organic electroluminescent element each provided with the transparent electrode and having excellent optical transparency, low driving voltage and small voltage variation under constant current.

### DESCRIPTION OF REFERENCE NUMERALS

1 Transparent Electrode
1a Intermediate Layer
1b Conductive Layer
3 Light-Emitting Functional Layer
3a Positive Hole Injection Layer
3b Positive Hole Transport Layer
3c Luminescent Layer
3d Electron Transport Layer
3e Electron Injection Layer
5a, 5b, 5c Counter Electrode
11 Base
13 Transparent Substrate (Base)
13a Light Extraction Face
15 Auxiliary Electrode
17 Sealing Agent
19 Adhesive
22 Luminescent Panel
23 Support Substrate
100, 200, 300, 400 Organic EL Element
131 Substrate
131a Light Extraction Face
A Luminescent Region
B Non-Luminescent Region
h Emission Light

1. A transparent electrode comprising:
a conductive layer; and
an intermediate layer disposed adjacent to the conductive layer, wherein
the transparent electrode has a light transmittance of 50% or more at a wavelength of 550 nm and a sheet resistance of 20Ω/□ or less,
the intermediate layer contains an organic compound containing a sulfur atom having an unshared electron pair, and
the conductive layer is composed of silver as a main component.

2. The transparent electrode according to claim 1, wherein the organic compound is represented by the following general formula (1) having a divalent sulfur atom:
[Chem. 1]
R₁—S—R₂ General Formula (1)
wherein R₁ and R₂ each represent a substituent.

3. The transparent electrode according to claim 1, wherein the organic compound is represented by the following general formula (2):
[Chem. 2]
R₃—S—S—R₄ General Formula (2)
wherein R₃ and R₄ each represent a substituent.

4. The transparent electrode according to claim 1, wherein the organic compound is represented by the following general formula (3):
[Chem. 3]
R₅—S—H General Formula (3)
wherein R₅ represents a substituent, and the general formula (3) includes a structure ionized by separation of the hydrogen.

5. The transparent electrode according to claim 1, wherein the organic compound is represented by the following general formula (4): 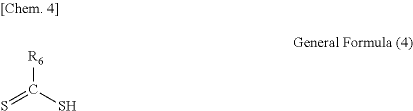
wherein R₆ represents a substituent.

6. The transparent electrode according to claim 1 further comprising a second intermediate layer on the conductive layer, wherein
the conductive layer is interposed between the two intermediate layers.

7. An electronic device comprising the transparent electrode according to claim 1.

8. An organic electroluminescent element comprising the transparent electrode according to claim 1.
